(19) United States
(12) Patent Application Publication
(10) Pub. No.: US 2011/0248355 A1
(43) Pub. Date: Oct. 13, 2011

(54) SEMICONDUCTOR DEVICE AND MANUFACTURING METHOD THEREOF

(75) Inventor: Takuya FUTASE, Kanagawa (JP)

(73) Assignee: RENESAS ELECTRONICS CORPORATION

(21) Appl. No.: 13/085,478

(22) Filed: Apr. 13, 2011

(30) Foreign Application Priority Data
Apr. 13, 2010 (JP) 2010-092284

(51) Int. Cl. H01L 27/088; H01L 21/8234

(52) U.S. Cl. 257/383; 438/303; 257/E27.06; 257/E21.616

(57) ABSTRACT

An improvement is achieved in the performance of a semiconductor device in which a metal silicide layer is formed by a salicide process. In a main surface of a semiconductor substrate, a plurality of MISFETs are formed, each having a gate electrode, and source/drain regions over each of which the metal silicide layer is formed. The metal silicide layer is formed of a silicide of nickel and a first metal element including at least one selected from the group consisting of Pt, Pd, V, Er, and Yb. A grain size in the metal silicide layer is smaller than the width in a gate length direction of the source/drain region included in the source/drain regions of the plurality of MISFETs formed in the main surface of the semiconductor substrate, and disposed between the gate electrodes adjacent in closest proximity to each other in the gate length direction.

### CROSS-REFERENCE TO RELATED APPLICATIONS

The disclosure of Japanese Patent Application No. 2010-92284 filed on Apr. 13, 2010 including the specification, drawings and abstract is incorporated herein by reference in its entirety.

### BACKGROUND

The present invention relates to a semiconductor device and a manufacturing method thereof, and particularly to a technology which is effective when applied to a semiconductor device including a semiconductor element having a metal silicide layer and a manufacturing technique thereof.

With the increasing integration of semiconductor devices, a field effect transistor (MISFET: Metal Insulator Semiconductor Field Effect Transistor) has been scaled down according to a scaling rule. However, gate and source/drain resistances increase to result in a problem that, even when the field effect transistor is scaled down, a high-speed operation cannot be obtained. To solve the problem, a salicide technique has been studied in which a low-resistance metal silicide layer such as, e.g., nickel silicide layer or cobalt silicide layer is formed by self-alignment over a surface of each of a conductive film forming the gate and a semiconductor region forming the source/drain to thereby reduce the gate and source/drain resistances.

In Japanese Unexamined Patent Publications Nos. 2009-283780 (Patent Document 1), 2008-78559 (Patent Document 2), and 2006-261635 (Patent Document 3), techniques each concerning the formation of a silicide layer are described.

### RELATED ART DOCUMENTS

### Patent Documents

### [Patent Document 1]

Japanese Unexamined Patent Publication No. 2009-283780

### [Patent Document 2]

Japanese Unexamined Patent Publication No. 2008-78559

### [Patent Document 3]

Japanese Unexamined Patent Publication No. 2006-261635

### SUMMARY

As a result of the study, the present inventors have made the following findings.

The metal silicide layer formed by a Salicide (Self Aligned Silicide) process over the surface of each of the conductive film forming the gate and the semiconductor region forming the source/drain is preferably formed of nickel silicide, rather than cobalt silicide, to satisfy a request for a reduction in the resistance thereof resulting from scaling-down. By forming the metal silicide layer not of cobalt silicide, but of nickel silicide, it is possible to further reduce the resistance of the metal silicide layer, and further reduce a source/drain diffusion resistance, contact resistance, and the like. Also, by forming the metal silicide layer not of cobalt silicide, but of nickel silicide, it is possible to form a thin metal silicide layer, and achieve a shallow source/drain junction depth, which is advantageous for scaling down the field effect transistor.

In the case of using the nickel silicide layer as the metal silicide layer, when Pt or the like is added into the nickel silicide layer, such advantages can be obtained that the formed metal silicide layer has small agglomeration, and abnormal growth of a high-resistance NiSi₂ phase can be suppressed in the formed metal silicide layer. As a result, the reliability of a semiconductor device can be improved. Therefore, after the formation of a MISFET in a semiconductor device, it is preferable to form a Ni—Pt alloy film obtained by adding Pt to Ni over the semiconductor substrate to cause the alloy film to react with the semiconductor region forming the source/drain and with the conductive film forming the gate electrode, and thereby form a metal silicide layer made of Ni—Pt silicide.

However, mere addition of Pt or the like into the nickel silicide layer cannot completely prevent the abnormal growth of the NiSi₂ phase. If the abnormal growth occurs in the MISFET, a leakage current may increase therein. Therefore, to improve the performance of the semiconductor device, it is desired to minimize the abnormal growth of the NiSi₂ phase in the metal silicide layer.

An object of the present invention is to provide a technique which allows an improvement in the performance of a semiconductor device.

The above and other objects and novel features of the present invention will become apparent from a statement in the present specification and the accompanying drawings.

The following is a brief description of the outline of a representative aspect of the invention disclosed in the present application.

A semiconductor device according to a representative embodiment is a semiconductor device including a plurality of MISFETs formed in a main surface of a semiconductor substrate, and each having a gate electrode, and source/drain regions over each of which a metal silicide layer is formed. The metal silicide layer is formed of a silicide of nickel and a first metal element including at least one selected from the group consisting of Pt, Pd, V, Er, and Yb. A grain size in the metal silicide layer is smaller than a first width in a gate length direction of a first source/drain region included in the source/drain regions of the MISFETs, and having the smallest width in the gate length direction.

A semiconductor device according to another representative embodiment is a semiconductor device including a plurality of MISFETs formed in a main surface of a semiconductor substrate, and each having a gate electrode, and source/drain regions over each of which a metal silicide layer is formed. The metal silicide layer is formed of a silicide of nickel and a first metal element including at least one selected from the group consisting of Pt, Pd, V, Er, and Yb. The MISFETs include a plurality of first MISFETs forming a memory cell array, and a grain size in the metal silicide layer is smaller than a first width in a gate length direction of a first source/drain region included in the source/drain regions of the MISFETs, and disposed between the gate electrodes of the first MISFETs adjacent to each other in the gate length direction.

A method of manufacturing the semiconductor device according to the representative embodiment is a method of manufacturing a semiconductor device having a plurality of MISFETs each having source/drain regions over each of which a metal silicide layer is formed, and a metal film for forming the metal silicide layer is formed of an alloy film of Ni and the first metal element including at least one selected from the group consisting of Pt, Pd, V, Er, and Yb. A heat treatment for forming the metal silicide layer is performed such that a grain size in the metal silicide layer is smaller than a first width in a gate length direction of a first source/drain region included in the source/drain regions of the MISFETs, and having the smallest width in the gate length direction.

A method of manufacturing the semiconductor device according to the other representative embodiment is a method of manufacturing a semiconductor device having a plurality of MISFETs each having source/drain regions over each of which a metal silicide layer is formed, and a metal film for forming the metal silicide layer is formed of an alloy film of Ni and a first metal element including at least one selected from the group consisting of Pt, Pd, V, Er, and Yb. The MISFETs include a plurality of first MISFETs forming a memory cell array, and a heat treatment for forming the metal silicide layer is performed such that a grain size in the metal silicide layer is smaller than a first width in a gate length direction of a first source/drain region included in the source/drain regions of the MISFETs, and disposed between the gate electrodes of the first MISFETs adjacent to each other in the gate length direction.

The following is a brief description of effects achievable by the representative aspect of the invention disclosed in the present application.

According to the representative embodiments, the performance of the semiconductor device can be improved.

### BRIEF DESCRIPTION OF THE DRAWINGS

FIG. 1 is a main-portion cross-sectional view of a semiconductor device as an embodiment of the present invention;

FIG. 2 is a main-portion cross-sectional view of the semiconductor device as the embodiment of the present invention during a manufacturing step;

FIG. 3 is a main-portion cross-sectional view of the semiconductor device during a manufacturing step subsequent to that of FIG. 2;

FIG. 4 is a main-portion cross-sectional view of the semiconductor device during a manufacturing step subsequent to that of FIG. 3;

FIG. 5 is a main-portion cross-sectional view of the semiconductor device during a manufacturing step subsequent to that of FIG. 4;

FIG. 6 is a main-portion cross-sectional view of the semiconductor device during a manufacturing step subsequent to that of FIG. 5;

FIG. 7 is a manufacturing process flow chart showing a part of the manufacturing steps of the semiconductor device as the embodiment of the present invention;

FIG. 8 is a main-portion cross-sectional view of the semiconductor device during a manufacturing step subsequent to that of FIG. 6;

FIG. 9 is a main-portion cross-sectional view of the semiconductor device during a manufacturing step subsequent to that of FIG. 8;

FIG. 10 is a main-portion cross-sectional view of the semiconductor device during a manufacturing step subsequent to that of FIG. 9;

FIG. 11 is a main-portion cross-sectional view of the semiconductor device during a manufacturing step subsequent to that of FIG. 10;

FIG. 12 is a main-portion cross-sectional view of the semiconductor device during a manufacturing step subsequent to that of FIG. 11;

FIG. 13 is a main-portion cross-sectional view of the semiconductor device during a manufacturing step subsequent to that of FIG. 12;

FIG. 14 is a main-portion cross-sectional view of the semiconductor device as the embodiment of the present invention during a manufacturing step (at a stage prior to the formation of an alloy film);

FIG. 15 is a main-portion plan view of the semiconductor device during the same manufacturing step as that of FIG. 14;

FIG. 16 is a main-portion cross-sectional view of the semiconductor device as the embodiment of the present invention during a manufacturing step (at a stage where a second heat treatment has been performed);

FIG. 17 is a main-portion plan view of the semiconductor device during the same manufacturing step as that of FIG. 16;

FIG. 18 is a graph showing the number of occurrence (frequency of occurrence) of leakage current defects when a grain size in each of metal silicide layers is varied;

FIGS. 19(a), 19(b), and 19(c) are illustrative views each showing a schematic cross section of the metal silicide layer;

FIGS. 20(a), 20(b), and 20(c) are illustrative views each schematically showing a state where abnormal growth of Ni_{1-y}M_{y}Si₂ has occurred in the metal silicide layer;

FIGS. 21(a), 21(b), and 21(c) are main-portion cross-sectional views of the semiconductor device of the embodiment of the present invention during the manufacturing step (at the stage prior to the formation of the alloy film;

FIGS. 22(a), 22(b), and 22(c) are main-portion cross-sectional views of the semiconductor device of the embodiment of the present invention during the manufacturing step (at the stage where the second heat treatment has been performed);

FIG. 23 is a main-portion cross-sectional view of the semiconductor device of the embodiment of the present invention during the manufacturing step (at the stage prior to the formation of the alloy film;

FIG. 24 is a main-portion cross-sectional view of the semiconductor device of the embodiment of the present invention during the manufacturing step (at the stage where the alloy film has been formed);

FIG. 25 is a main-portion cross-sectional view of the semiconductor device of the embodiment of the present invention during the manufacturing step (at the stage where a barrier film has been formed);

FIG. 26 is a main-portion cross-sectional view of the semiconductor device of the embodiment of the present invention during the manufacturing step (at the stage where a first heat treatment has been performed);

FIG. 27 is a main-portion cross-sectional view of the semiconductor device of the embodiment of the present invention during the manufacturing step (at the stage where the step of removing the barrier film and the unreacted alloy film has been performed);

FIG. 28 is a main-portion cross-sectional view of the semiconductor device of the embodiment of the present invention during the manufacturing step (at the stage where the second heat treatment has been performed);

FIG. 29 is a graph showing respective diffusion coefficients of Ni and Pt in a Si region;

FIG. 30 is a graph showing the specific resistances of the metal silicide layers;

FIG. 31 is a graph showing a correlation between an alloy film consumption ratio in the first heat treatment and a Pt concentration in a Ni_{1-y}Pt_{y}Si layer;

FIG. 32 is a graph showing a correlation between the alloy film consumption ratio in the first heat treatment and a grain size in the Ni_{1-y}Pt_{y}Si layer;

FIG. 33 is a graph showing a correlation between the Pt concentration in the Ni_{1-y}Pt_{y}Si layer and the resistivity of the Ni_{1-y}Pt_{y}Si layer;

FIG. 34 is a main-portion cross-sectional view of the semiconductor device of the embodiment of the present invention during the manufacturing step (at the stage where the alloy film has been formed);

FIG. 35 is another main-portion cross-sectional view of the semiconductor device during the same manufacturing step as that of FIG. 34;

FIG. 36 is a main-portion cross-sectional view of the semiconductor device of the embodiment of the present invention during the manufacturing step (at the stage where the second heat treatment has been performed);

FIG. 37 is another main-portion cross-sectional view of the semiconductor device during the same manufacturing step as that of FIG. 36;

FIGS. 38(a) and 38(b) are illustrative views each showing an example of a heat treatment apparatus used in the manufacturing steps of the semiconductor device of the embodiment of the present invention;

FIGS. 39(a) and 39(b) are illustrative views of a susceptor provided in the heat treatment apparatus of FIGS. 38(a) and 38(b);

FIG. 40 is a main-portion cross-sectional view of a semiconductor device as another embodiment of the present invention during the manufacturing step;

FIG. 41 is a main-portion cross-sectional view of the semiconductor device during the manufacturing step subsequent to that of FIG. 40;

FIG. 42 is a main-portion cross-sectional view of the semiconductor device during the manufacturing step subsequent to that of FIG. 41;

FIG. 43 is a main-portion cross-sectional view of the semiconductor device during the manufacturing step subsequent to that of FIG. 42;

FIG. 44 is a main-portion cross-sectional view of the semiconductor device during the manufacturing step subsequent to that of FIG. 43;

FIG. 45 is a plan view showing an example of the semiconductor device as still another embodiment of the present invention;

FIGS. 46(a), 46(b), and 46(c) are main-portion cross-sectional views of the semiconductor device as the still other embodiment of the present invention during the manufacturing step (at the stage prior to the formation of the alloy film); and

FIGS. 47(a), 47(b), and 47(c) are main-portion cross-sectional views of the semiconductor device as the still other embodiment of the present invention during the manufacturing step (at the stage where the second heat treatment has been performed).

### DETAILED DESCRIPTION

In each of the following embodiments, if necessary for the sake of convenience, the embodiment will be described by being divided into a plurality of sections or embodiments. However, they are by no means irrelevant to each other unless particularly explicitly described otherwise, and one of the sections or embodiments is variations, details, supplementary explanation, and so forth of part or the whole of the others. When the number and the like (including the number, numerical value, amount, range, and the like thereof) of elements are referred to in the following embodiments, they are not limited to specific numbers unless particularly explicitly described otherwise or unless they are obviously limited to specific numbers in principle. The number and the like of the elements may be not less than or not more than specific numbers. It will be appreciated that, in the following embodiments, the components thereof (including also elements, steps, and the like) are not necessarily indispensable unless particularly explicitly described otherwise or unless the components are considered to be obviously indispensable in principle. Likewise, if the shapes, positional relationships, and the like of the components and the like are referred to in the following embodiments, the shapes and the like are assumed to include those substantially proximate or similar thereto and the like unless particularly explicitly described otherwise or unless it can be considered that they obviously do not in principle. The same shall apply in regard to the foregoing numerical value and range.

Hereinbelow, the embodiments of the present invention will be described with reference to the drawings. Note that, throughout all the drawings for illustrating the embodiments, members having the same functions are designated by the same reference numerals, and a repeated description thereof is omitted. In the following embodiments, a description of the same or like parts will not be repeated in principle unless particularly necessary.

In the drawings used in the embodiments, hatching may be omitted even in a cross section for clarity of illustration, while even a plan view may be hatched for clarity of illustration.

### First Embodiment

A semiconductor device as an embodiment of the present invention will be described with reference to the drawings.

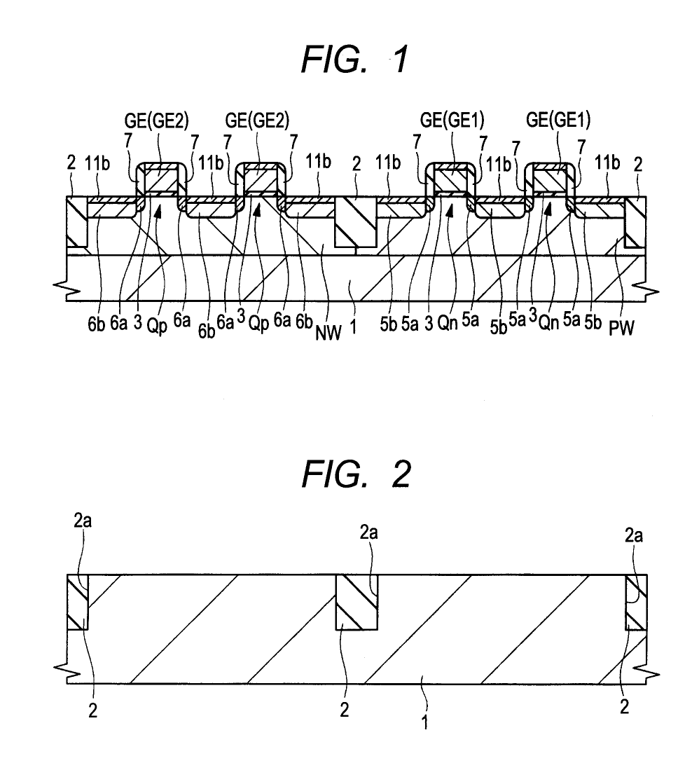

FIG. 1 is a main-portion cross-sectional view of the semiconductor device as the embodiment of the present invention, which is a semiconductor device having a CMISFET (Complementary Metal Insulator Semiconductor Field Effect Transistor) herein.

As shown in FIG. 1, the semiconductor device of the present embodiment has a plurality of n-channel MISFETs (Metal Insulator Semiconductor Field Effect Transistors) Qn and a plurality of p-channel MISFETs Qp, which are formed in a semiconductor substrate 1. In the semiconductor substrate 1 forming the semiconductor device, a larger number of the re-channel MISFETs and p-channel MISFETs are actually formed. However, in FIG. 1, the two n-channel MISFETs Qn and the two p-channel MISFETs Qp are shown as representatives thereof.

That is, the semiconductor substrate 1 made of p-type single-crystal silicon having a specific resistance of, e.g., about 1 to 10 Ωcm has active regions defined by isolation regions 2 to be electrically isolated from each other. In the active regions of the semiconductor substrate 1, a p-type well PW and an n-type well NW are formed. Over the surface of the p-type well PW, gate electrodes GE of the n-channel MISFETs Qn are formed via gate insulating films 3 of the n-channel MISFETs Qn. On the other hand, over the surface of the n-type well NW, the gate electrodes GE of the p-channel MISFETs Qp are formed via the gate insulating films 3 of the p-channel MISFETs Qp.

Here, it is assumed that, of the plurality of gate electrodes GE formed over the main surface of the semiconductor substrate 1 via the gate insulating films 3, those forming the n-channel MISFETs Qn are designated by the mark “GE1” and referred to as gate electrodes GE1, and those forming the p-channel MISFETs Qp are designated by the mark “GE2” and referred to as gate electrodes GE2.

The gate electrodes GE are each formed of a conductive film. Specifically, the gate electrodes GE1 for the n-channel MISFETs Qn are formed of polysilicon (an n-type semiconductor film or doped polysilicon film) into which an n-type impurity has been introduced, and the gate electrodes GE2 for the p-channel MISFETs Qp are formed of polysilicon (a p-type semiconductor film or doped polysilicon film) into which a p-type impurity has been introduced.

In the p-type well PW, as the source and drain regions of the n-channel MISFETs Qn each having an LDD (Lightly doped Drain) structure, n⁻-type semiconductor regions (extension regions or LDD regions) 5a and n⁺-type semiconductor regions (source/drain regions) 5b having impurity concentrations higher than those of the n⁻-type semiconductor regions 5a are formed. On the other hand, in the n-type well NW, as the source and drain regions of the p-channel MISFETs Qp each having the LDD structure, p⁻-type semiconductor regions (extension regions or LDD regions) 6a and p⁺-type semiconductor regions (source/drain regions) 6b having impurity concentrations higher than those of the p⁻-type semiconductor regions 6a are formed. The n⁺-type semiconductor regions 5b have junction depths deeper than those of the n⁻-type semiconductor regions 5a and the impurity concentrations higher than those of the n⁻-type semiconductor regions 5a. On the other hand, the p⁺-type semiconductor regions 6b have junction depths deeper than those of the p⁻-type semiconductor regions 6a and the impurity concentrations higher than those of the p⁻-type semiconductor regions 6a.

Over the side walls of the gate electrodes GE (GE1 and GE2), as sidewall insulating films, sidewalls (sidewall spacers or sidewall insulating films) 7 each formed of an insulator (insulating film) are formed. In the p-type well PW, the n⁻-type semiconductor regions 5a are formed in alignment with respect to the gate electrodes GE1 of the n-channel MISFETs Qn, and the n⁺-type semiconductor regions 5b are formed in alignment with respect to the sidewalls 7 provided over the side walls of the gate electrodes GE1 of the n-channel MISFETs Qn. On the other hand, in the n-type well NW, the p⁻-type semiconductor regions 6a are formed in alignment with respect to the gate electrodes GE2 of the p-channel MISFETs Qp, and the p⁺-type semiconductor regions 6b are formed in alignment with respect to the sidewalls 7 provided over the side walls of the gate electrodes GE2 of the p-channel MISFETs Qp.

Over the respective surfaces (upper layer portions) of the gate electrodes GE (GE1 and GE2), the n⁺-type semiconductor regions 5b (source/drain regions), and the p⁺-type semiconductor regions 6b (source/drain regions), metal silicide layers 11b are formed. Each of the metal silicide layers 11b is in a Ni_{1-y}M_{y}Si phase (where 0<y<1 is satisfied), the details of which will be described later. Here, M in a chemical formula Ni_{1-y}M_{y}Si represents a first metal element M. The first metal element M includes at least one selected from the group consisting of Pt (platinum), Pd (palladium), V (vanadium), Er (erbium), and Yb (ytterbium), and is preferably Pt (platinum). When the first metal element M is Pt (platinum), the metal silicide layer 11b is in a Ni_{1-y}Pt_{y}Si phase (where 0<y<1 is satisfied).

The Ni_{1-y}Pt_{y}Si phase has a resistivity lower than those of a (Ni_{1-y}Pt_{y})₂Si phase and a Ni_{1-y}Pt_{y}Si₂ phase. Therefore, by forming each of the metal silicide layers 11b of the Ni_{1-y}Pt_{y}Si phase (where 0<y<1 is satisfied), the resistance of the metal silicide layer 11b can be reduced.

In addition, insulating films 21 and 22, contact holes 23, plugs PG, a stopper insulating film 25, an insulating film 26, interconnects M1 (see FIG. 13 described later), and an upper-layer multi-layer interconnect structure, which will be described later, are further formed, but the depiction and description thereof is omitted here.

Next, manufacturing steps of the semiconductor device as the first embodiment of the present invention will be described with reference to the drawings. FIGS. 2 to 6 are main-portion cross-sectional views of the semiconductor device as the embodiment of the present invention, e.g., a semiconductor device having a CMISFET during manufacturing steps. FIGS. 2 to 6 show cross-sectional regions corresponding to those of FIG. 1 described above.

First, as shown in FIG. 2, the semiconductor substrate (semiconductor wafer) 1 formed of p-type single-crystal silicon having a specific resistance of, e.g., 1 to 10 Ωcm or the like is prepared. Then, in the main surface of the semiconductor substrate 1, isolation regions 2 are formed. The isolation regions 2 are each formed of an insulator such as silicon oxide, and formed by, e.g., a STI (Shallow Trench Isolation) method, a LOCOS (Local Oxidation of Silicon) method, or the like. For example, the isolation regions 2 can be formed of insulating films buried in trenches (isolation trenches) 2a formed in the semiconductor substrate 1.

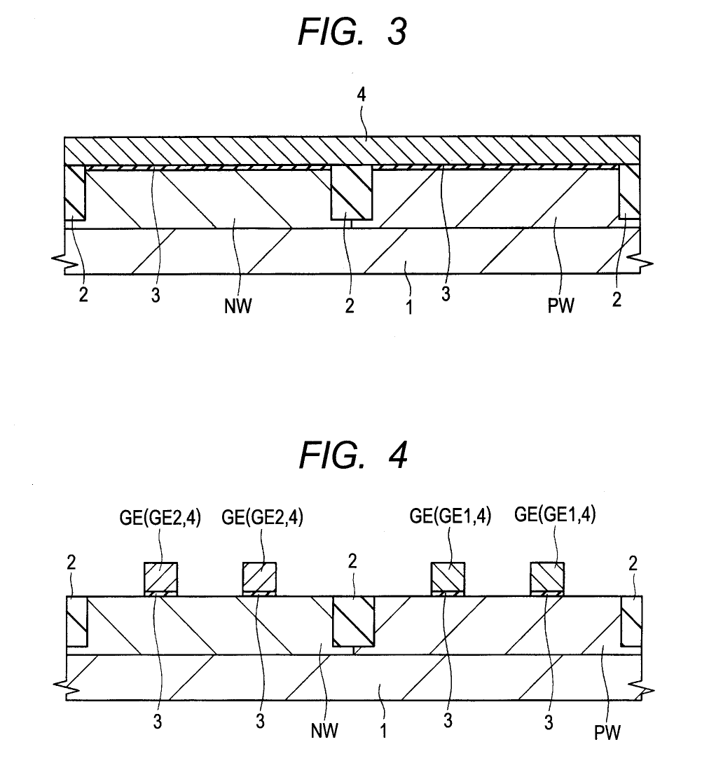

Next, as shown in FIG. 3, the p-type well PW and the n-type well NW are each formed at a predetermined depth from the main surface of the semiconductor substrate 1. The p-type well PW can be formed by, e.g., ion-implanting a p-type impurity such as boron (B) into the semiconductor substrate 1 in regions where the n-channel MISFETs are to be formed using a photoresist film (not shown) covering regions where the p-channel MISFETs are to be formed as an ion implantation stopping mask, and so forth. On the other hand, the n-type well NW can be formed by, e.g., ion-implanting an n-type impurity such as phosphorus (P) or arsenic (As) into the semiconductor substrate 1 in regions where the p-channel MISFETs are to be formed using another photoresist film (not shown) covering the regions where the n-channel MISFETs are to be formed as an ion implantation stopping mask, and so forth.

Next, by wet etching using, e.g., an aqueous hydrofluoric acid (HF) solution or the like, the surface of the semiconductor substrate 1 is purified (cleaned). Thereafter, over the surface (i.e., the surfaces of the p-type well PW and the n-type well NW) of the semiconductor substrate 1, the gate insulating film 3 is formed. The gate insulating film 3 is formed of, e.g., a thin silicon oxide film or the like, and can be formed by, e.g., a thermal oxidation method or the like.

Next, over the semiconductor substrate 1 (i.e., over the gate insulating film 3 over the p-type well PW and the n-type well NW), as a conductor film for forming the gate electrodes, a silicon film 4 such as a polysilicon film is formed.

Of the silicon film 4, the regions (regions which are to serve as the gate electrodes GE1 later) where the n-channel MISFETs are to be formed are changed to low-resistance n-type semiconductor films (doped polysilicon films) by ion-implanting an n-type impurity such as phosphorus (P) or arsenic (As) using a photoresist film (covering the regions where the p-channel MISFETs are to be formed, though not shown herein) as a mask, and so forth. Of the silicon film 4, the regions (regions which are to serve as the gate electrodes GE2 later) where the p-channel MISFETs are to be formed are changed to low-resistance p-type semiconductor films (doped polysilicon films) by ion-implanting a p-type impurity such as boron (B) using another photoresist film (covering the regions where the n-channel MISFETs are to be formed, though not shown herein) as a mask, and so forth. The silicon film 4 may also be formed by depositing an amorphous silicon film, and then changing the deposited amorphous silicon film into a polysilicon film by a heat treatment after film deposition (after ion implantation).

Next, as shown in FIG. 4, the silicon film 4 is patterned using a photolithographic method and a dry etching method to form the gate electrodes GE. In FIG. 4, as the gate electrodes GE, the gate electrodes GE1 for the n-channel MISFETs and the gate electrodes GE2 for the p-channel MISFETs are shown.

The gate electrodes GE1 serving as the gate electrodes of the n-channel MISFETs are each formed of polysilicon (an n-type semiconductor film or a doped polysilicon film) into which an n-type impurity has been introduced, and formed over the p-type well PW via the gate insulating films 3. On the other hand, the gate electrodes GE2 serving as the gate electrodes of the p-channel MISFETs are each formed of polysilicon (a p-type semiconductor film or a doped polysilicon film) into which a p-type impurity has been introduced, and formed over the n-type well NW via the gate insulating films 3. That is, the gate electrodes GE1 are formed over the gate insulating films 3 over the p-type well PW, and the gate electrodes GE2 are formed over the gate insulating films 3 over the n-type well NW. The gate length of each of the gate electrodes GE can be changed as necessary, and set to, e.g., about 50 nm.

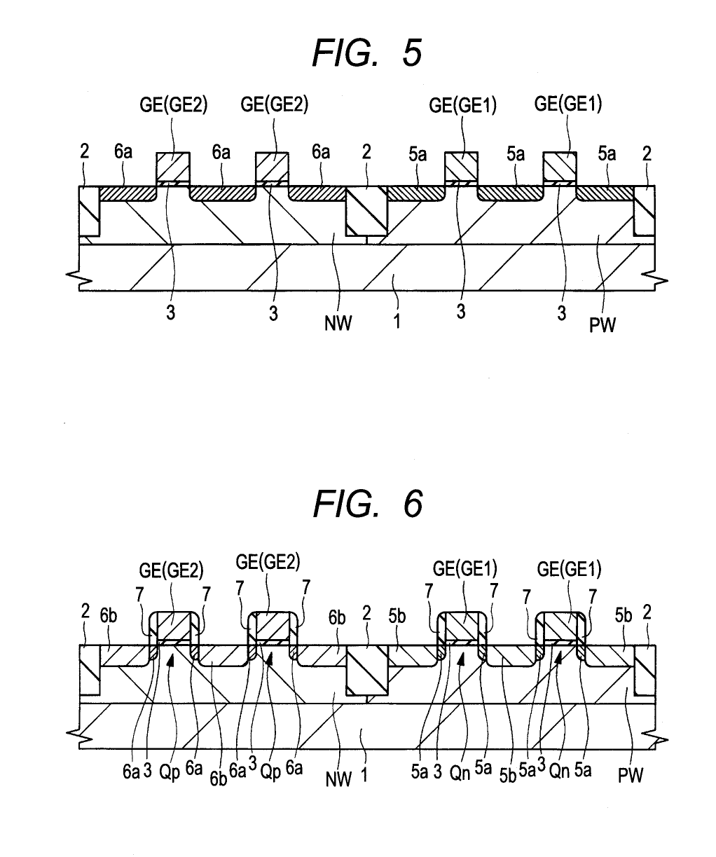

Next, as shown in FIG. 5, into the regions of the p-type well PW located on both sides of each of the gate electrodes GE1, an n-type impurity such as phosphorus (P) or arsenic (As) is ion-implanted to form the n⁻-type semiconductor regions 5a. Also, into the regions of the n type well NW located on both sides of each of the gate electrodes GE2, a p-type impurity such as boron (B) is ion implanted to form the p⁻-type semiconductor regions 6a. Either the n⁻-type semiconductor regions 5a or the p⁻-type semiconductor regions 6a may be formed first. The depths (junction depths) of the n⁻-type semiconductor regions 5a and the p⁻-type semiconductor regions 6a can be changed as necessary, and set to, e.g., about 30 nm. In the ion implantation for forming the n⁻-type semiconductor regions 5a and the ion implantation for forming the p⁻-type semiconductor regions 6a, the regions of the p-type well PW and the n-type well NW located immediately under the gate electrodes GE are shielded with the gate electrodes GE, and not subjected to the ion implantation.

Next, as shown in FIG. 6, over the side walls of each of the gate electrodes GE (i.e., each of the gate electrodes GE1 and GE2), the sidewalls (sidewall spacers or sidewall insulating films) 7 each formed of, e.g., silicon oxide, silicon nitride, or a laminate film of the insulating films thereof are formed. The sidewalls 7 can be formed by, e.g., depositing a silicon oxide film, a silicon nitride film, or a laminate film thereof over the semiconductor substrate 1, and performing anisotropic etching to the silicon oxide film, the silicon nitride film, or the laminate film thereof by a RIE (Reactive Ion Etching) method or the like.

After the formation of the sidewalls 7, the n⁺-type semiconductor regions 5b (sources or drains) are formed by ion-implanting an n-type impurity such as arsenic (As) or phosphorus (P) into the regions of the p-type well PW located on both sides of the gate electrodes GE1 and the sidewalls 7. For example, arsenic (As) is implanted at about 1×10¹⁵/cm² to 1×10¹⁶/cm² with an acceleration voltage of 10 to 30 keV, e.g., at 4×10¹⁵/cm² with 20 keV or phosphorus (P) is implanted at about 1×10¹⁴/cm² to 1×10¹⁵/cm² with an acceleration voltage of 5 to 20 keV, e.g., at 5×10¹⁴/cm² with 10 keV to form the n⁺-type semiconductor regions 5b. Also, the p⁺-type semiconductor regions 6b (sources or drains) are formed by ion-implanting a p-type impurity such as boron (B) into the regions of the n-type well NW located on both sides of the gate electrodes GE2 and the sidewalls 7. For example, boron (B) is implanted at about 1×10¹⁵/cm² to 1×10¹⁶/cm² with an acceleration voltage of 1 to 3 keV, e.g., at 4×10¹⁵/cm² with 2 keV to form the p⁺-type semiconductor regions 6b. Either the n⁺-type semiconductor regions 5b or the p⁺-type semiconductor regions 6b may be formed first. After the ion implantations, an anneal treatment for activating the introduced impurities can also be performed as a spike anneal treatment at, e.g., about 1050° C. The depths (junction depths) of the n⁺-type semiconductor regions 5b and the p⁺-type semiconductor regions 6b can be changed as necessary, and set to, e.g., about 80 nm. In the ion implantation for forming the n⁺-type semiconductor regions 5b and the ion implantation for forming the p⁺-type semiconductor regions 6b, the regions of the p-type well PW and the n-type well NW located immediately under the gate electrodes GE and the sidewalls 7 are shielded with the gate electrodes GE and the sidewalls 7, and not subjected to the ion implantation.

The n⁺-type semiconductor regions 5b have the junction depths deeper than those of the n⁻-type semiconductor regions 5a and the impurity concentrations higher than those of the n⁻-type semiconductor regions 5a. Also, the p⁺-type semiconductor regions 6b have the junction depths deeper than those of the p⁻-type semiconductor regions 6a and the impurity concentrations higher than those of the p⁻-type semiconductor regions 6a. In this manner, n-type semiconductor regions (impurity diffusion layers) functioning as the sources or drains of the n-channel MISFETs are formed of the n⁺-type semiconductor regions (impurity diffusion layers) 5b and the n⁻-type semiconductor regions 5a. Also, p-type semiconductor regions (impurity diffusion layers) functioning as the sources or drains of the p-channel MISFETs are formed of the p⁺-type semiconductor regions (impurity diffusion layers) 6b and the p⁻-type semiconductor regions. Therefore, the source and drain regions of the n-channel MISFETs and the P-channel MISFETs have the LDD (Lightly doped Drain) structures. The n⁻-type semiconductor regions 5a are formed by self-alignment with respect to the gate electrodes GE1 for the n-channel MISFETs, while the n⁺-type semiconductor regions 5b are formed by self-alignment with respect to the sidewalls 7 formed over the side walls of the gate electrodes GE1 for the n-channel MISFETs. The p⁻-type semiconductor regions 6a are formed by self-alignment with respect to the gate electrodes GE2 for the p-channel MISFETs, while the p⁺-type semiconductor regions 6b are formed by self-alignment with respect to the sidewalls 7 formed over the side walls of the gate electrodes GE2 for the p-channel MISFETs.

Thus, in the p-type well PW, the n-channel MISFETs Qn are formed as field effect transistors while, in the n-type well NW, the p-channel MISFETs Qp are formed as field effect transistors. In this manner, the structure of FIG. 6 is obtained. The n-channel MISFETs Qn can be regarded as n-channel field effect transistors, while the p-channel MISFETs Qp can be regarded as p-channel field effect transistors. Also, the n⁺-type semiconductor regions 5b can be regarded as the semiconductor regions (source/drain regions) for the sources or drains of the n-channel MISFETs Qn, while the p⁺-type semiconductor regions 6b can be regarded as the semiconductor regions (source/drain regions) for the sources or drains of the p-channel MISFETs Qp.

Next, using a salicide technique, over the surfaces of the gate electrodes GE (GE1) and the source/drain regions (n⁺-type semiconductor regions 5b) of the n-channel MISFETs (Qn) and over the surfaces of the gate electrodes GE (GE2) and the source/drain regions (p⁺-type semiconductor regions 6b) of the p-channel MISFETs (Qp), low-resistance metal silicide layers (corresponding to the metal silicide layers 11b described later) are formed. Hereinbelow, the step of forming the metal silicide layers will be described.

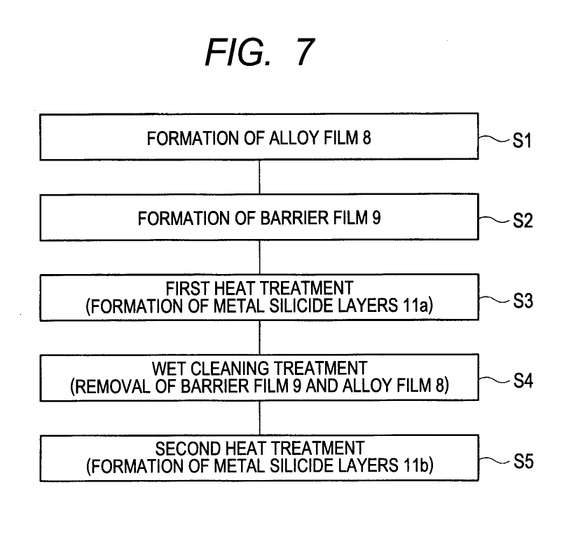

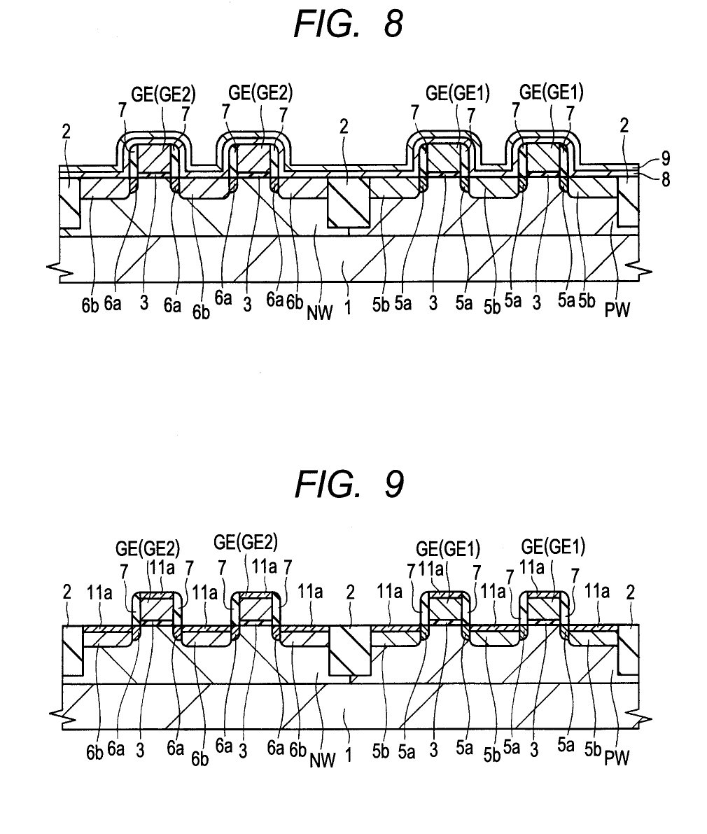

FIG. 7 is a manufacturing process flow chart showing a part of the manufacturing steps of the semiconductor device of the present embodiment. FIG. 7 shows a manufacturing process flow of the steps of, after the structure of FIG. 6 is obtained, forming the metal silicide layers (metal-semiconductor reaction layers) over the surfaces of the gate electrodes GE, the n⁺-type semiconductor regions 5b, and the p⁺-type semiconductor regions 6b by a salicide process. FIGS. 8 to 13 are main-portion cross-sectional views of the semiconductor device during manufacturing steps subsequent to that of FIG. 6. Note that FIG. 7 corresponds to the manufacturing process flow of the steps of FIGS. 8 to 10.

After the structure of FIG. 6 is obtained as described above, as shown in FIG. 8, the surfaces of the gate electrodes GE (GE1 and GE2), the n⁺-type semiconductor regions 5b, and the p⁺-type semiconductor regions 6b are exposed, and then an alloy film 8 is formed (deposited) over the main surface (entire surface) of the semiconductor substrate 1 including the gate electrodes GE (GE1 and GE2), the n⁺-type semiconductor regions 5b, and the p⁺-type semiconductor regions 6b using, e.g., a sputtering method (Step S1 of FIG. 7). That is, in Step S1, over the semiconductor substrate 1 including the n⁺-type semiconductor regions 5b and the p⁺-type semiconductor regions 6b, the alloy film 8 is formed so as to cover the gate electrodes GE (GE1 and GE2).

Then, over the alloy film 8, a barrier film (stress control film, antioxidant film, or cap film) 9 is formed (deposited) (Step S2 of FIG. 7).

More preferably, prior to Step S1 (step of depositing the alloy film 8), a dry cleaning treatment using at least any one of HF gas, NF₃ gas, NH₃ gas, and H₂ gas is performed to remove natural oxide films in the surfaces of the gate electrodes GE, the n⁺-type semiconductor regions 5b, and the p⁺-type semiconductor regions 6b, and then Steps S1 and S2 are performed without exposing the semiconductor substrate 1 into atmospheric air (oxygen-containing atmosphere).

The alloy film 8 is an alloy film (i.e., nickel alloy film) containing at least nickel (Ni), and specifically an alloy film of nickel (Ni) and the first metal element M, i.e., a Ni-M alloy film. The first metal element M includes at least one selected from the group consisting of Pt (platinum), Pd (palladium), V (vanadium), Er (erbium), and Yb (ytterbium), and is preferably Pt (platinum). When the first metal element M is Pt (platinum), the alloy film 8 is an alloy film of nickel (Ni) and Pt (platinum), i.e., a Ni—Pt alloy film. Therefore, the alloy film 8 is preferably the Ni—Pt alloy film (alloy film of Ni and Pt).

When the ratio (atomic ratio) between Ni and the first metal element M in the alloy film 8 is assumed to be 1−x:x, the alloy film 8 can be expressed as a Ni₁₋ₓMₓ alloy film. Here, M in Ni₁₋ₓMₓ is the first metal element M. The percentage (ratio) of Ni in the Ni₁₋ₓMₓ alloy film is (1−x)×100%. The percentage (ratio) of the first element M in the Ni₁₋ₓMₓ alloy film is x×100%. Note that, when the percentage (ratio or concentration) of an element is shown in % in the present application, at % is used. Examples of the alloy film 8 that can be used include a Ni_{0.963}Pt_{0.037} alloy film. When the alloy film 8 is the Ni_{0.963}Pt_{0.037} alloy film, the percentage (ratio) of Ni in the alloy film 8 is 96.3 at %, and the percentage (ratio) of Pt in the alloy film 8 is 3.7 at %.

The barrier film 9 is formed of, e.g., a titanium nitride (TiN) film or a titanium (Ti) film. The thickness (deposited film thickness) thereof can be set to, e.g., about 15 nm. The barrier film 9 functions as a stress control film (film which controls stress in the active regions of the semiconductor substrate) and a film which prevents permeation of oxygen, and is provided over the alloy film 8 to control a stress acting on the semiconductor substrate 1 and prevent the alloy film 8 from being oxidized.

After the alloy film 8 and the barrier film 9 are formed, the semiconductor substrate 1 is subjected to a first heat treatment (anneal treatment) (Step S3 of FIG. 7). The first heat treatment in Step S3 can be performed under ordinary pressure in an atmosphere of inert gas (e.g., argon (Ar) gas, neon (Ne) gas, or helium (He) gas), nitrogen (N₂) gas, or a mixed gas thereof. The first heat treatment in Step S3 can be performed using, e.g., a RTA (Rapid Thermal Anneal) method.

By the first heat treatment in Step S3, as shown in FIG. 9, the polysilicon films forming the gate electrodes GE (GE1 and GE2) and single-crystal silicon forming the n⁺-type semiconductor regions 5b and the p⁺-type semiconductor regions 6b are each caused to selectively react with the alloy film 8 to form metal silicide layers 11a as the metal-semiconductor reaction layers. By the reaction between of the upper portions (upper layer portions) of the gate electrodes GE (GE1 and GE2), the n⁺-type semiconductor regions 5b, and the p⁺-type semiconductor regions 6b and the alloy film 8, the metal silicide layers 11a are formed. Therefore, the metal silicide layers 11a are formed over the surfaces (upper layer portions) of the gate electrodes GE (GE1 and GE2), the n⁺-type semiconductor regions 5b, and the p⁺-type semiconductor regions 6b.

Thus, in the first heat treatment in Step S3, the gate electrodes GE, the n⁺-type semiconductor regions 5b, and the p⁺-type semiconductor regions 6b are (or Si forming the gate electrodes GE, the n⁺-type semiconductor regions 5b, and the p⁺-type semiconductor regions is) caused to selectively react with the alloy film 8 and form the metal silicide layers 11a formed of a silicide of nickel and the first metal element M. At the stage where the first heat treatment in Step S3 has been performed, each of the metal silicide layers 11a is preferably in a (Ni_{1-y}M_{y})₂Si phase (where 0<y<1 is satisfied). Note that M in a chemical formula (Ni_{1-y}M_{y})₂Si represents the foregoing first metal element M. When the alloy film 8 is the Ni—Pt alloy film (i.e., when the foregoing first metal element M is Pt), the metal silicide layer 11a is formed of a platinum-added nickel silicide layer in the (Ni_{1-y}Pt_{y})₂Si phase (where 0<y<1 is satisfied). Therefore, the first heat treatment in Step S3 is preferably performed at a heat treatment temperature at which the metal silicide layer 11a is in the (Ni_{1-y}M_{y})₂Si phase, not in the Ni_{1-y}M_{y}Si phase.

By the first heat treatment in Step S3, Ni and the first metal element M in the alloy film 8 are diffused into the n⁺-type semiconductor regions 5b, the p⁺-type semiconductor regions 6b, and the gate electrodes GE (GE1 and GE2) to form the metal silicide layers 11a. In Step S3, the first heat treatment is preferably performed such that an unreacted portion (corresponding to an unreacted portion 8a described later) of the alloy film 8 remains over each of the metal silicide layers 11a, which corresponds to a fourth condition described later. Also in Step S3, the first heat treatment is preferably performed at a heat treatment temperature at which the coefficient of diffusion of the first metal element M into the n⁺-type semiconductor regions 5b, the p⁺-type semiconductor regions 6b, and the gate electrodes GE is larger than the coefficient of diffusion of Ni into the n⁺-type semiconductor regions 5b, the p⁺-type semiconductor regions 6b, and the gate electrodes GE, which corresponds to a fifth condition described later. The fourth and fifth conditions will be described later in detail. By performing the first heat treatment under conditions as described above (the fourth and fifth conditions described later), the ratio of the first metal element M to the metal elements (Ni and the first metal element M) forming the formed metal silicide layers 11a becomes higher than the ratio of the first metal element M to the alloy film 8.

Preferably, the barrier film 9 is a film unlikely to react with the alloy film 8, and does not react with the alloy film 8 even when the first heat treatment in Step S3 is performed. From this viewpoint, as the barrier film 9, titanium nitride (TiN) film or a titanium (Ti) film is preferred. Note that, in the present embodiment, the alloy film 8 is formed to have a thickness sufficiently larger than the thickness (corresponding to a thickness tn3 of a reacted portion 8b described later) of an alloy film which reacts with the n⁺-type semiconductor regions 5b and the p⁺-type semiconductor regions 6b. Therefore, the barrier film 9 as the antioxidant film may also be omitted.

Next, by performing a wet cleaning treatment, the barrier film 9 and the unreacted alloy film 8 (i.e., the alloy film 8 which has not reacted with the gate electrodes GE, the n⁺-type semiconductor regions 5b, or the p⁺-type semiconductor regions 6b in the first heat treatment step in Step S3) are removed (Step S4 of FIG. 7). At this time, the unreacted alloy film 8 (i.e., the alloy film 8 which has not reacted with the gate electrodes GE, the n⁺-type semiconductor regions 5b, or the p⁺-type semiconductor regions 6b in the first heat treatment step in Step S3) is removed from over the metal silicide layers 11a, while the metal silicide layers 11a are left over the surfaces of the gate electrodes GE (GE1 and GE2), the n⁺-type semiconductor regions 5b, and the p⁺-type semiconductor regions 6b. The wet cleaning treatment in Step S4 can be performed by wet cleaning using a sulfuric acid, wet etching using a sulfuric acid and an aqueous hydrogen peroxide solution, or the like. FIG. 9 shows the stage at which the barrier film 9 and the unreacted alloy film 8 have been removed by the wet cleaning treatment in Step S4.

Next, the semiconductor substrate 1 is subjected to a second heat treatment (anneal treatment) (Step S5 of FIG. 7). The second heat treatment in Step S5 can be performed under ordinary pressure in an atmosphere of inert gas (e.g., argon (Ar) gas, neon (Ne) gas, or helium (He) gas), nitrogen (N₂) gas, or a mixed gas thereof. The second heat treatment in Step S5 can be performed using, e.g., the RTA method. Note that the second heat treatment in Step S5 is performed at a heat treatment temperature higher than the heat treatment temperature in the foregoing first heat treatment in Step S3.

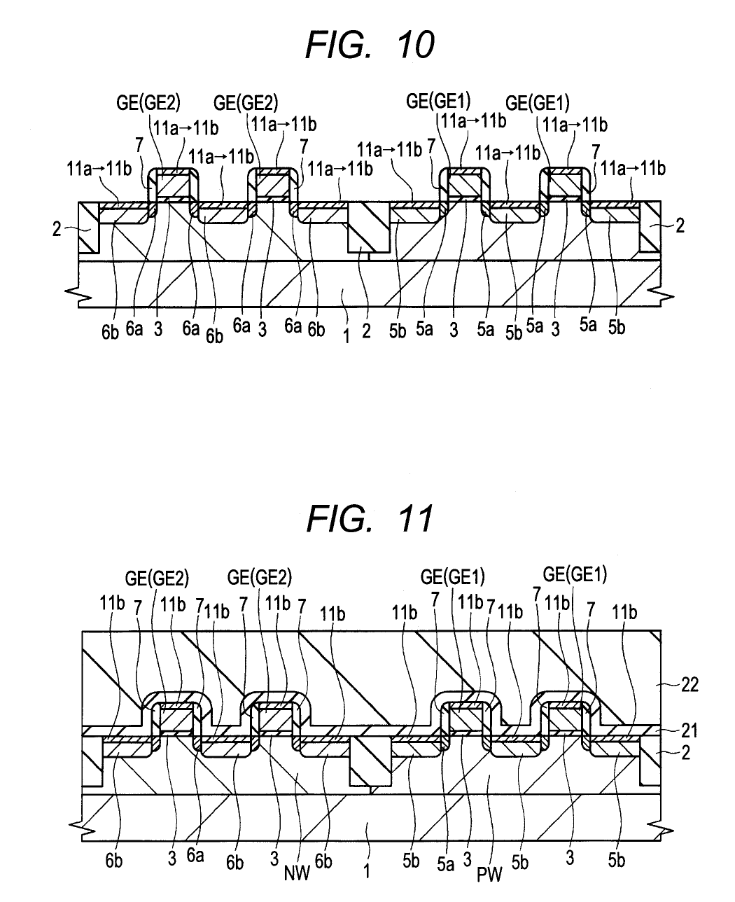

The second heat treatment in Step S5 is performed to reduce the resistance of each of the metal silicide layers 11a. By performing the second heat treatment in Step S5, the metal silicide layers 11a formed in the first heat treatment in Step S3 are changed to the metal silicide layers 11b in the Ni_{1-y}M_{y}Si phase, as shown in FIG. 10. As a result, the metal silicide layers 11b are formed in each of which the composition ratio between the metal elements (including Ni and the first metal element M) and Si is closer to a stoichiometric ratio of 1:1.

That is, the metal silicide layers 11a in the (Ni_{1-y}M_{y})₂Si phase are each caused to further react with silicon in the gate electrodes GE, the n⁺-type semiconductor regions 5b, and the p⁺-type semiconductor regions 6b by the second heat treatment in Step S5 to form the metal silicide layers 11b in the Ni_{1-y}M_{y}Si phase having a resistivity lower than that of the (Ni_{1-y}M_{y})₂Si phase over the surfaces (upper layer portions) of the gate electrodes GE, the n⁺-type semiconductor regions 5b, and the p⁺-type semiconductor regions 6b. The second heat treatment in Step S5 needs to be performed at a temperature which allows the metal silicide layers 11a in the (Ni_{1-y}M_{y})₂Si phase to be changed to the metal silicide layers 11b in the Ni_{1-y}M_{y}Si phase. Accordingly, the heat treatment temperature in the second heat treatment in Step S5 needs to be set higher than at least the heat treatment temperature in the first heat treatment in Step S3. To prevent the metal silicide layers 11b from being formed in a Ni_{1-y}M_{y}Si₂ phase having a resistivity higher than that of the Ni_{1-y}M_{y}Si phase, the second heat treatment in Step S5 is preferably performed at a heat treatment temperature at which the metal silicide layers 11b are in the Ni_{1-y}M_{y}Si phase but not in the Ni_{1-y}M_{y}Si₂ phase.

Note that the Ni_{1-y}M_{y}Si phase has a resistivity lower than those of the (Ni_{1-y}M_{y})₂Si phase and the Ni_{1-y}M_{y}Si₂ phase. In Step S5 and thereafter also (till the end of the manufacturing of the semiconductor device), the metal silicide layers 11b are maintained in the low-resistance Ni_{1-y}M_{y}Si phase and, in the manufactured semiconductor device (even in a state where, e.g., the semiconductor substrate 1 has been singulated into individual semiconductor chips), the metal silicide layers 11b are in the low-resistance phase.

Here, M in the foregoing chemical formulae (Ni_{1-y}M_{y})₂Si, and Ni_{1-y}M_{y}Si₂ is the foregoing first metal element M. When the alloy film 8 is the Ni—Pt alloy film (i.e., when the foregoing first metal element M is Pt), the metal silicide layers 11a formed in the first heat treatment in Step S3 are in the (Ni_{1-y}Pt_{y})₂Si phase, and changed to the metal silicide layers 11b in the Ni_{1-y}Pt_{y}Si phase by performing the second heat treatment in Step S5. In this case, the Ni_{1-y}Pt_{y}Si phase has a resistivity lower than those of the (Ni_{1-y}Pt_{y})₂Si phase and the Ni_{1-y}Pt_{y}Si₂ phase. In Step S5 and thereafter also (till the end of the manufacturing of the semiconductor device), the metal silicide layer 11b is maintained in the low-resistance Ni_{1-y}Pt_{y}Si phase and, in the manufactured semiconductor device (even in the state where, e.g., the semiconductor substrate 1 has been singulated into individual semiconductor chips), the metal silicide layers 11b are in the low-resistance Ni_{1-y}Pt_{y}Si phase.

In this manner, over the surfaces (upper layer portions) of the gate electrodes GE (GE1) and the source/drain regions (n⁺-type semiconductor regions 5b) of the n-channel MISFETs (Qn) and over the surfaces (upper layer portions) of the gate electrodes GE (GE2) and the source/drain regions (p⁺-type semiconductor regions 6b) of the p-channel MISFETs (Qp), the metal silicide layers 11b in the Ni_{1-y}M_{y}Si phase are formed.

Next, as shown in FIG. 11, over the main surface of the semiconductor substrate 1, the insulating film 21 is formed. That is, the insulating film 21 is formed over the semiconductor substrate 1 including the metal silicide layers 11b so as to cover the gate electrodes GE (GE1 and GE2) and the sidewalls 7. The insulating film 21 is formed of, e.g., a silicon nitride film, and can be formed by a plasma CVD method at a film deposition temperature (substrate temperature) of about 450° C. or the like. Then, over the insulating film 21, the insulating film 22 thicker than the insulating film 21 is formed. The insulating film 22 is formed of, e.g., a silicon oxide film, and can be formed by a plasma CVD method at a film deposition temperature of about 400° C. or the like using TEOS (Tetraethoxysilane, or also referred to as Tetra Ethyl Ortho Silicate). In this manner, the interlayer insulating film including the insulating films 21 and 22 is formed. Thereafter, by polishing the surface of the insulating film 22 by a CMP method, and so forth, the upper surface of the insulating film 22 is planarized. Even when the surface of the insulating film 21 is formed in a rough shape resulting from an underlying level difference, by polishing the surface of the insulating film 22 by the CMP method, an interlayer insulating film having a planarized surface can be obtained.

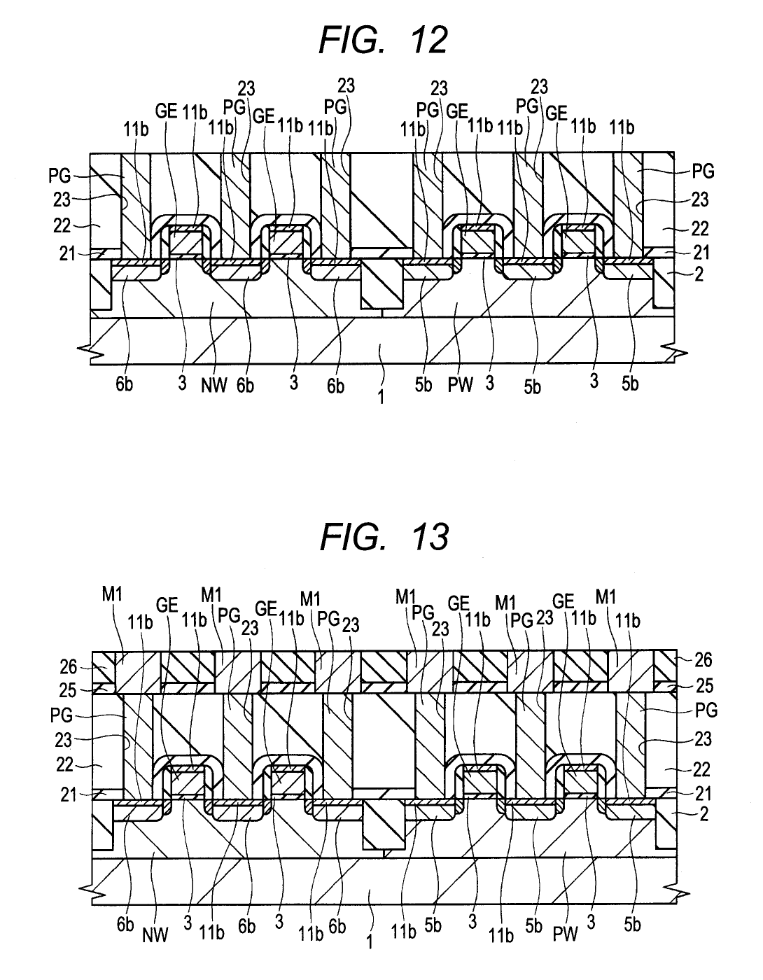

Next, as shown in FIG. 12, using a photoresist pattern (not shown) formed over the insulating film 22, the insulating films 22 and 21 are subjected to dry etching to be formed with the contact holes (through holes or holes) 23. At this time, the dry etching of the insulating film 22 is performed first under conditions under which the insulating film 22 is more likely to be etched than the insulating film 21 to cause the insulating film 21 to function as an etching stopper film, and thereby form the contact holes 23 in the insulating film 22. Then, the insulating film 21 at the bottom portions of the contact holes 23 is subjected to dry etching under conditions under which the insulating film 21 is more likely to be etched than the insulating film 22, and thereby removed. At the bottom portions of the contact holes 23, parts of the main surface of the semiconductor substrate 1, e.g., parts of the metal silicide layers 11b over the surfaces of the n⁺-type semiconductor regions 5b and the p⁺-type semiconductor regions 6b and parts of the metal silicide layers 11b over the surfaces of the gate electrodes GE are exposed.

Next, in the contact holes 23, the conductive plugs (connecting conductor portions) PG formed of tungsten (W) or the like are formed. To form the plugs PG, for example, over the insulating film 22 including the insides (over the bottom portions and the side walls) of the contact holes 23, a barrier conductor film (e.g., titanium film, titanium nitride film, or a laminate film thereof) is formed by a plasma CVD method at a film deposition temperature (substrate temperature) of about 450° C. Then, a main conductor film formed of a tungsten film or the like is formed over the foregoing barrier conductor film by a CVD method or the like so as to fill the contact holes 23. By removing the unneeded portions of the main conductor film and the barrier conductor film by a CMP method, an etch-back method, or the like, the plugs PG can be formed. For simpler illustration of the drawings, in FIGS. 12 and 13, the barrier conductor film and the main conductor film each forming the plugs PG are integrally shown. The plugs PG formed over the gate electrodes GE, the n⁺-type semiconductor regions 5b, and the p⁺-type semiconductor regions 6b have bottom portions thereof in contact with the metal silicide layers 11b over the surfaces of the gate electrodes GE, the n⁺-type semiconductor regions 5b, and the p⁺-type semiconductor regions 6b to be electrically coupled.

Next, as shown in FIG. 13, over the insulating film 22 in which the plugs PG are buried, the stopper insulating film (etching stopper insulating film) 25 and the insulating film for forming the interconnects are successively formed. The stopper insulating film 25 serves as an etching stopper during trenching of the insulating film 26, and uses a material having an etching selectivity to the insulating film 26. The stopper insulating film 25 can be formed of, e.g., a silicon nitride film formed by a plasma CVD method, and the insulating film 26 can be formed of, e.g., a silicon oxide film formed by a plasma CVD method. Note that, in the stopper insulating film 25 and the insulating film 26, first-layer interconnects subsequently described are formed.

Next, the first-layer interconnects M1 are formed by a single damascene method. First, by dry etching using a photoresist pattern (not shown) as a mask, interconnect trenches (trenches in which the interconnects M1 are to be buried) are formed in predetermined regions of the insulating film 26 and the stopper insulating film 25. Thereafter, over the main surface (i.e., over the insulating film 26 including the bottom portions and side walls of the interconnect trenches) of the semiconductor substrate 1, a barrier conductor film (barrier metal film) is formed. Examples of the barrier conductor film that can be used include titanium nitride film, tantalum film, and tantalum nitride film. Subsequently, by a CVD method, a sputtering method, or the like, a copper seed layer is formed over the barrier conductor film. Further, using an electrolytic plating method or the like, a copper plating film is formed over the seed layer. With the copper plating film, the insides of the interconnect trenches are filled. Then, the copper plating film, the seed layer, and the barrier conductor film in the regions other than the interconnect trenches are removed therefrom by a CMP method so that the first-layer interconnects M1 containing copper as a main conductive material are formed. Note that, for simpler illustration of the drawings, in FIG. 13, the copper plating film, the seed film, and the barrier conductor film each forming the interconnects M1 are integrally shown. The interconnects M1 are electrically coupled to the n⁺-type semiconductor regions 5b and the p⁺-type semiconductor regions 6b for the sources or drains of the n-channel MISFETs (Qn) and the p-channel MISFETs (Qp), the gate electrodes GE (GE1 and GE2) thereof, and the like via the plugs PG. Thereafter, second-layer and subsequent interconnects are formed by a dual damascene method, but the depiction and description thereof is omitted here.

Next, main characteristic features of the present embodiment will be described.

When each of the metal silicide layers formed by the salicide process is formed of nickel silicide, since a NiSi phase has a resistance lower than those of a Ni₂Si phase and the NiSi₂ phase, it is necessary to form a metal silicide layer (NiSi layer) formed of NiSi over each of the respective surfaces of the conductive films forming the gates and the semiconductor regions forming the sources/drains. In the case of forming nickel silicide, Ni (nickel) is a diffusion species and, by the movement of Ni (nickel) toward the silicon region, nickel silicide is formed.

As a result, during the heat treatment, Ni (nickel) may be excessively diffused to result in the formation of an unneeded NiSi₂ portion, and the electric resistance of the metal silicide layer may vary from MISFET to MISFET. In addition, during the heat treatment, abnormal growth of NiSi₂ from the NiSi layer to the channel portion may occur. The abnormal growth of NiSi₂ from the NiSi layer to the channel portion causes an increase in the leakage current between the source/drain of the MISFET and an increase in the diffusion resistance of the source/drain region.

Therefore, to improve the performance of the field effect transistor, it is desired to prevent the unneeded NiSi₂ portion from being formed in the NiSi layer, and prevent the abnormal growth of NiSi₂ from the NiSi layer to the channel portion.

Therefore, the present inventors have examined the use of the nickel silicide layer to which the foregoing first metal element M is added, not a simple nickel silicide layer, as the metal silicide layer. When the first metal element M (Pt is most effective) is added into the nickel silicide layer, such advantages are obtained that the formed metal silicide layer has small agglomeration, and the abnormal growth of the high-resistance NiSi₂ phase can be suppressed in the formed metal silicide layer. As a result, the performance and reliability of the semiconductor device can be improved.

However, with mere addition of Pt or the like into the nickel silicide layer, it is difficult to completely prevent the abnormal growth of the NiSi₂ phase. Therefore, to further improve the performance of the field effect transistor, it is desired to further suppress the abnormal growth of the NiSi₂ phase in the metal silicide layer to which the first metal element M (Pt is most effective) is added.

Therefore, the present inventors have examined which condition (requirement) enhances the effect of suppressing (preventing) the abnormal growth of the NiSi₂ phase when the first metal element M (Pt is most effective) is added into the nickel silicide layer (i.e., when a first condition described later is satisfied as a prior condition). As a result, it has been found that, if the following conditions are satisfied, the effect of suppressing (preventing) the abnormal growth of the NiSi₂ phase can be enhanced

To begin with, the first condition as the prior condition is that each of the metal silicide layers 11b is formed of nickel silicide to (in) which the first metal element M (preferably Pt) is added (contained). In other words, the first condition is that each of the metal silicide layers 11b is formed of a silicide of the first metal element M (preferably Pt) and nickel (Ni). The metal silicide layer 11b is mainly in the Ni_{1-y}M_{y}Si phase.

Next, a second condition is that a grain size (crystal grain size) in each of the metal silicide layers 11b is controlled. Specifically, as the second condition, a grain size (crystal grain size) G1 in each of the metal silicide layers 11b formed over the source/drain regions (n⁺-type semiconductor regions 5b or p⁺-type semiconductor regions 6b) is set smaller than a width W1 of each of the source/drain regions (n⁺-type semiconductor regions 5b or p⁺-type semiconductor regions 6b) over which the metal silicide layers 11b are formed (i.e., G1<W1).

Here, a description will be given of the width W1 of each of the source/drain regions (n⁺-type semiconductor regions 5b or p⁺-type semiconductor regions 6b) and the grain size G1 in each of the metal silicide layers 11b.

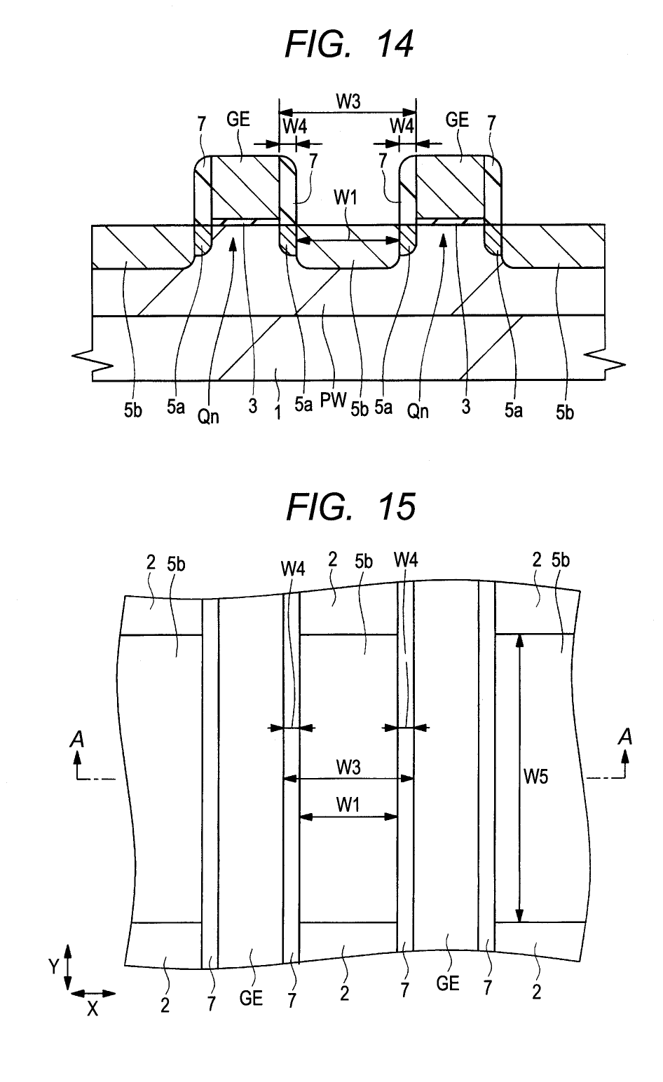

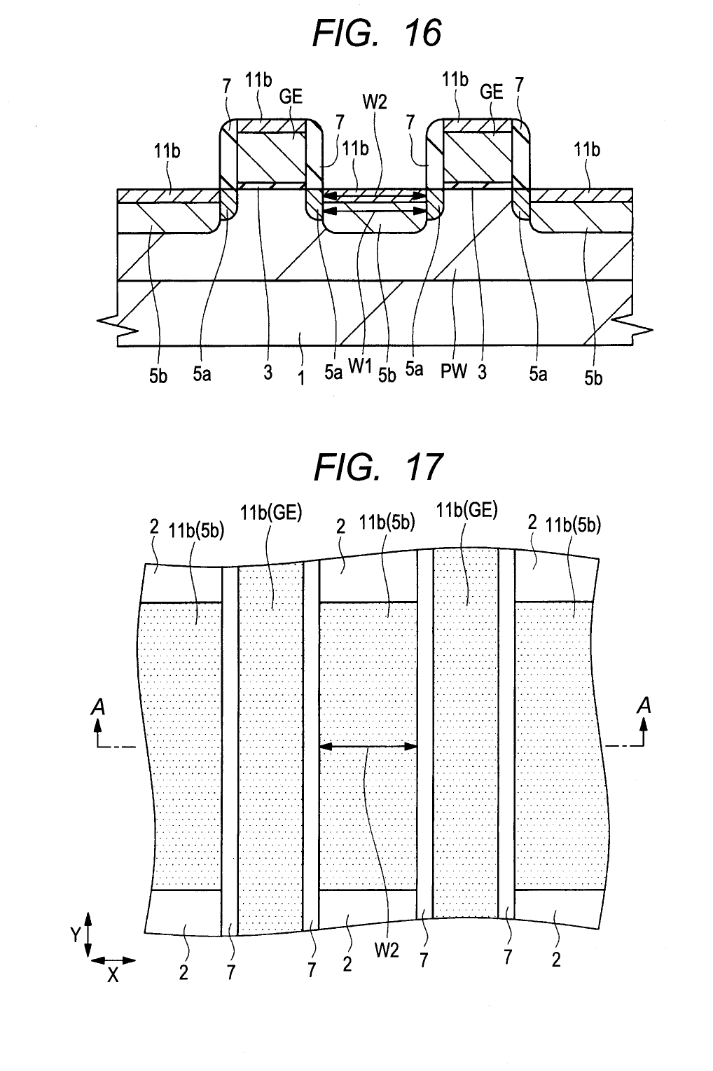

FIGS. 14 and 15 are a main-portion cross-sectional view (FIG. 14) and a main-portion plan view (FIG. 15) of the semiconductor device at the stage after the n⁺-type semiconductor regions 5b and the p⁺-type semiconductor regions 6b are formed and before the foregoing alloy film 8 is formed in Step S1 described above (i.e., the same process stage as in FIG. 6 described above), and a cross-sectional view along the line A-A of FIG. 15 corresponds to FIG. 14. FIGS. 16 and 17 are a main-portion cross-sectional view (FIG. 16) and a main-portion plan view (FIG. 17) of the semiconductor device at the stage after the metal silicide layers 11b are formed by performing Steps S1 to S5 described above and before the foregoing insulating film 21 is formed (i.e., the same process stage as in FIG. 10 described above), and a cross-sectional view along the line A-A of FIG. 17 corresponds to FIG. 16. Note that FIGS. 14 and 16 show the same cross-sectional region at the different process stages, and FIGS. 15 and 17 show the same plan region at the different process stages. In FIGS. 14 to 17, the region where the n-channel MISFETs are formed is shown. However, in the case where a region where the p-channel MISFETs are formed is shown, in each of FIGS. 14 to 17, the p-type well PW is replaced with the n-type well NW, the n⁻-type semiconductor regions 5a are replaced with the p⁻-type semiconductor regions 6a, the n⁺-type semiconductor regions 5b are replaced with the p⁺-type semiconductor regions 6b, and the n-channel MISFETs Qn are replaced with the p-channel MISFETs Qp. In this case, the gate electrodes GE are such that the gate electrodes GE1 are replaced with the gate electrodes GE2. FIG. 17 is a plan view but, for easier understanding, the regions where the metal silicide layers 11b are formed are shown with dot hatching.

The width W1 of each of the source/drain regions (n⁺-type semiconductor regions 5b or p⁺-type semiconductor regions 6b) described above corresponds to the dimension (width) in a gate length direction of each of the source/drain regions (n⁺-type semiconductor regions 5b or p⁺-type semiconductor regions 6b), and is shown in FIGS. 14 to 16. Here, the gate length direction corresponds to the gate length direction of the gate electrode GE of the MISFET to which the source/drain regions (n⁺-type semiconductor regions 5b or p⁺-type semiconductor regions 6b) belong. In FIGS. 15 and 17, the X-direction corresponds to the gate length direction. The gate length direction corresponds to a channel length direction. Note that the source/drain regions mentioned herein indicate semiconductor regions for the sources or drains over which the metal silicon layers 11b are formed at the stage after the metal silicide layers 11b are formed by the salicide process, and indicate semiconductor regions for the sources or drains over which the metal silicide layers 11b are to be formed later at the stage prior to the formation of the metal silicide layers 11b. Specifically, the foregoing n⁺-type semiconductor regions 5b and p⁺-type semiconductor regions 6b correspond to the source/drain regions.

On the other hand, the low-impurity-concentration extension regions (corresponding to the foregoing n⁻-type semiconductor regions 5a and the foregoing p⁻-type semiconductor regions 6a) in the LDD structure have the sidewall insulating films (corresponding to the foregoing sidewalls 7) thereover so that the metal silicide layers 11b are not formed thereover. Accordingly, in the present embodiment, it is assumed that the extension regions (n⁻-type semiconductor regions 5a or p⁻-type semiconductor regions 6a) are distinguished from the source/drain regions (n⁺-type semiconductor regions 5b or p⁺-type semiconductor regions 6b). Therefore, when the source/drain regions are mentioned in the present embodiment, it is assumed that, in principle, the source/drain regions do not include the low-concentration extension regions (n⁻-type semiconductor regions 5a or p⁻-type semiconductor regions 6a) located under the sidewall insulating films (sidewalls 7 in the present embodiment), and indicate the high-concentration regions (n⁺-type semiconductor regions 5b or p⁺-type semiconductor regions 6b) uncovered with the sidewall insulating films (sidewalls 7 in the present embodiment). Hence, it can also be said that the source/drain regions (n⁺-type semiconductor regions 5b or p⁺-type semiconductor regions 6b) are regions which are uncovered with the sidewall insulating films (sidewalls 7) and over which the metal silicide layers 11b are formed or to be formed.

Since the metal silicide layers 11b are formed over the source/drain regions (n⁺-type semiconductor regions 5b or p⁺-type semiconductor regions 6b), the width W1 of each of the source/drain regions (n⁺-type semiconductor regions 5b or p⁺-type semiconductor regions 6b) substantially equals (corresponds to) a width W2 (width in the gate length direction) of each of the metal silicide layers 11b formed over the source/drain regions (n⁺-type semiconductor regions 5b or p⁺-type semiconductor regions 6b) (i.e., W1=W2). Here, the width W2 of each of the metal silicide layers 11b formed over the source/drain regions (n⁺-type semiconductor regions 5b or p⁺-type semiconductor regions 6b) corresponds to the dimension (width) in the gate length direction, and is shown in FIGS. 16 and 17. Here, the gate length direction corresponds to the gate length direction of the gate electrode GE of the MISFET to which the source/drain regions (n⁺-type semiconductor regions 5b or p⁺-type semiconductor regions 6b) over which the metal silicide layers 11b are formed belong.

Here, in the case where the MISFETs (gate electrodes GE thereof) are adjacent to each other in the gate length direction, while sharing the source/drain region (n⁺-type semiconductor region 5b or p⁺-type semiconductor region 6b) as shown in FIGS. 14 and 15, the spacing between the gate electrodes GE adjacent to each other in the gate length direction, while having (sharing) the source/drain region (n⁺-type semiconductor region 5b or p⁺-type semiconductor region 6b) interposed therebetween, is defined as an adjacent spacing W3. The adjacent spacing W3 has a value obtained by adding up the width W1 of the source/drain region (n⁺-type semiconductor region 5b or p⁺-type semiconductor region 6b) between the gate electrodes GE adjacent to each other in the gate length direction with the adjacent spacing W3 therebetween and thicknesses W4 of the sidewalls 7 formed over the respective opposing side walls of the adjacent gate electrodes GE. That is, W3=W1+W4+W4 is satisfied. Here, the thickness W4 of each of the sidewalls 7 corresponds to the dimension in the gate length direction. The thicknesses W4 of the sidewalls 7 can be controlled with the formed film thicknesses (deposited film thicknesses) of the insulating films for forming the sidewalls 7.

Accordingly, in the case where the MISFETs (gate electrodes GE thereof) are adjacent to each other in the gate length direction, while sharing the source/drain region (n⁺-type semiconductor region 5b or p⁺-type semiconductor region 6b) as shown in FIGS. 14 and 15, the width W1 of the source/drain region can be determined according to the following expression: W1=W3−W4−W4. That is, the value obtained by subtracting the respective thicknesses W4 of the two sidewalls 7 from the adjacent spacing W3 between the gate electrodes GE becomes the width W1 of the source/drain region (n⁺-type semiconductor region 5b or p⁺-type semiconductor region 6b) between the adjacent gate electrodes GE.

On the other hand, the grain size G1 in each of the metal silicide layers 11b corresponds to the diameter of each of crystal grains forming the metal silicide layer 11b formed over the source/drain region (n⁺-type semiconductor region 5b or p⁺-type semiconductor region 6b), and indicates a grain size in the plane direction (direction parallel with the main surface of the semiconductor substrate 1) of the metal silicide layer 11b, not a grain size in the thickness direction (direction perpendicular to the main surface of the semiconductor substrate 1) of the metal silicide layer 11b. In the metal silicide layers 11b, the grain sizes of the crystal grains are preferably uniform but, even when the grain sizes are slightly non-uniform, the average grain size thereof can be regarded as the foregoing grain size G1. To easily measure the grain size G1, in a plane (plane generally parallel with the main surface of the semiconductor substrate 1) in the metal silicide layer 11b formed over the source/drain region (n⁺-type semiconductor region 5b or p⁺-type semiconductor region 6b), a line segment of predetermined length (line segment longer than the grain size) is assumed, and the number of grain boundaries traversing the line segment is determined. By dividing the length of the line segment by the number of the grain boundaries traversing the line segment, the value of the grain size G1 can be easily obtained.

If the grain size of the crystal grains in the metal silicide layer formed over the source/drain region is smaller than the planar dimensions (dimensions in both the gate length direction and a gate width direction) of the source/drain region, the grain size G1 in the metal silicide layer 11b can be defined (measured) with the crystal grain size in the metal silicide layer.

However, in a region where the dimension (width W1) in the gate length direction of the source/drain region is small, when the grain size of the crystal grains in the metal silicide layer formed over the source/drain region increases (specifically, increases to be larger than the width W1), state is achieved where the dimension in the gate length direction is occupied by substantially one crystal grain. In such a case, if the dimension (corresponding to the width W5 shown in FIG. 15) in the gate width direction (Y-direction in FIG. 15) of the source/drain region is larger than the dimension (width W1) in the gate length direction thereof, with the crystal grain size in the gate length direction, the grain size G1 in the metal silicide layer 11b can be defined (measured). Note that the gate width direction corresponds to the gate width direction of the gate electrode GE of the MISFET to which the source/drain regions over which the metal silicide layers 11b are formed belong. In FIGS. 15 and 17, the Y-direction corresponds to the gate width direction. The gate length direction (X-direction) and the gate width direction (Y-direction) are orthogonal to each other. The gate width direction corresponds to a channel width direction.

Also, in the region where the planar dimensions (dimensions in both the gate length direction and the gate width direction) of the source/drain region are small, when the grain size of the crystal grains in the metal silicide layer formed over the source/drain region increases (specifically, increases to be larger than the widths W1 and W5), a state is achieved in which the planar dimensions are entirely occupied by substantially one crystal grain. In such a case, in another source/drain region having relatively large dimension (in at least one of the gate length direction and the gate width direction), the grain size of the crystal grains in the metal silicide layer formed over the source/drain region is measured and, with the grain size, the grain size in the metal silicide layer over the source/drain region having small planar dimensions can be defined (replaced). This is because, in each of the metal silicide layers (11b) formed over the source/drain regions formed of the n-type semiconductor regions (the source/drain regions of the n-channel MISFETs), the crystal grains grow in the same manner, and therefore the crystal grain sizes thereof are substantially the same. This is also because, in each of the metal silicide layers (11b) formed over the source/drain regions formed of the p-type semiconductor regions (the source/drain regions of the p-channel MISFETs), the crystal grains grow in the same manner, and therefore the crystal grain sizes thereof are substantially the same.

Accordingly, if a predetermined number of the source/drain regions having relatively large dimensions (larger than the crystal grain sizes in the metal silicide layers formed thereover) are selected (extracted) from among the source/drain regions of the plurality of MISFETs formed in the main surface of the semiconductor substrate 1, and the average grain size of the crystal grains in the metal silicide layers formed over the selected source/drain regions is measured, the grain size can be regarded as the grain size G1 in each of the metal silicide layers 11b.

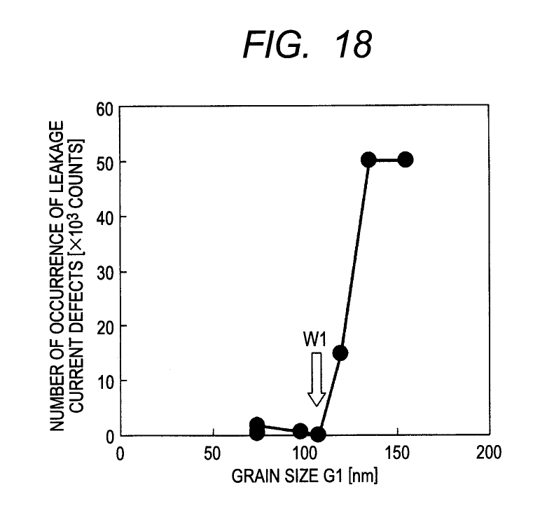

FIG. 18 is a graph obtained by plotting the number of occurrence (frequency of occurrence) of leakage current defects when the grain size G1 in each of the metal silicide layers 11b is varied. The abscissa axis in the graph of FIG. 18 corresponds to the grain size G1 in each of the metal silicide layers 11b, and the ordinate axis in the graph of FIG. 18 corresponds to the number of occurrence of the MISFETs in each of which a leakage current is larger than a predetermined reference value. FIG. 18 also shows the result of examining how the number of occurrence of the leakage current defects changes depending on the grain size G1 in a metal silicide layer corresponding to each of the metal silicide layers 11b when numerous MISFETs in which the width W1 of each of the source/drain regions (n⁺-type semiconductor regions 5b or p⁺-type semiconductor regions 6b) is set to 105 nm (i.e., W1=105 nm) are formed in the main surface of a semiconductor substrate (semiconductor wafer).

When the grain size G1 in each of the metal silicide layers 11b is set to be not less than the width W1 of each of the source/drain regions (n⁺-type semiconductor regions 5b or p⁺-type semiconductor regions 6b) (i.e., G1≧W1), as can also be seen from the graph of FIG. 18, the leakage current defect (defect in which the leakage current exceeds the predetermined reference value) in the MISFET tends to occur. On the other hand, when the grain size G1 in each of the metal silicide layers 11b is set smaller than the width W1 of each the source/drain regions (n⁺-type semiconductor regions 5b or p⁺-type semiconductor regions 6b) (i.e., G1<W1), as can also be seen from the graph of FIG. 18, the leakage current defect in the MISFET rarely occurs. The tendency (the tendency of the leakage current defect which is likely to occur when G1≧W1 is satisfied, and unlikely to occur when G1<W1 is satisfied) is maintained not only when the width W1 of each of the source/drain regions is set to 105 nm (i.e., W1=105 nm), but also when the width W1 is set to another value.

Accordingly, by setting the grain size G1 in each of the metal silicide layers 11b smaller than the width W1 of each of the source/drain regions (n⁺-type semiconductor regions 5b or p⁺-type semiconductor regions 6b) (i.e., G1<W1) as the foregoing second condition, as can also be seen from the graph of FIG. 18, the occurrence of the leakage current defect can be suppressed, i.e., the occurrence of the defect in which the leakage current increases in the MISFET can be suppressed or prevented.

The reason that the occurrence of the leakage current defect can be suppressed as can be seen from the graph of FIG. 18 by setting the grain size G1 in each of the metal silicide layers 11b smaller than the width W1 of each of the source/drain regions (n⁺-type semiconductor regions 5b or p⁺-type semiconductor regions 6b) (G1<W1) as the foregoing second condition is conceivably because the abnormal growth of Ni_{1-y}M_{y}Si₂ from the metal silicide layer 11b toward the channel portion can be suppressed. That is, when the foregoing second condition is not satisfied (when G1≧W1 is satisfied), the abnormal growth of Ni_{1-y}M_{y}Si₂ from the metal silicide layer 11b toward the channel portion is relatively likely to occur. By contrast, when the foregoing second condition is satisfied (G1<W1), the abnormal growth of Ni_{1-y}M_{y}Si₂ from the metal silicide layer 11b toward the channel portion is relatively unlikely to occur, and therefore the occurrence of the leakage current defect can be suppressed.

The following is a description of one of the reasons that the abnormal growth of Ni_{1-y}M_{y}Si₂ can be suppressed when the grain size G1 in each of the metal silicide layers 11b is set smaller than the width W1 of each of the source/drain regions (n⁺-type semiconductor regions 5b or p⁺-type semiconductor regions 6b) (when G1<W1 is satisfied) as the foregoing second condition.

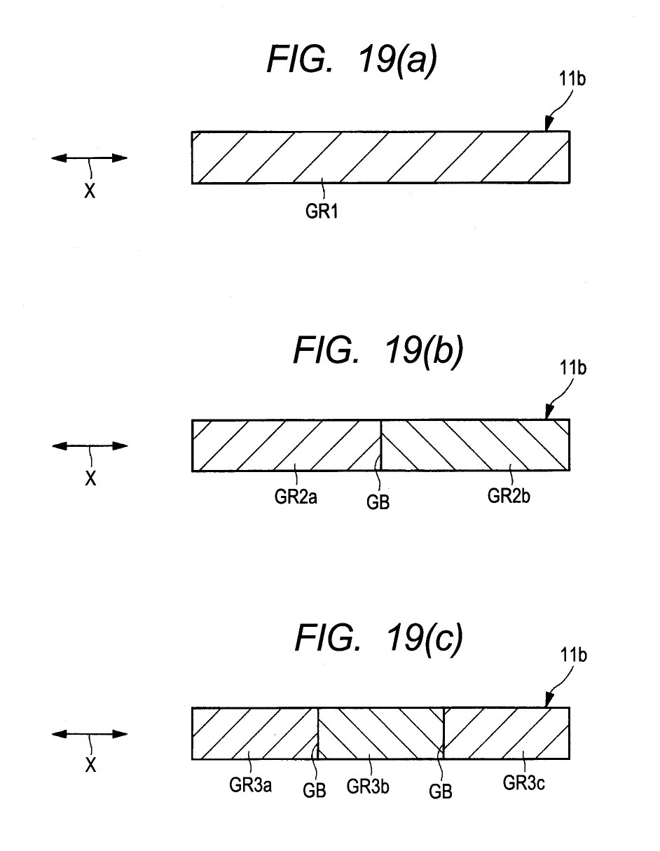

FIGS. 19(a), 19(b), and 19(c) are illustrative views each showing a schematic cross section of each of the metal silicide layers 11b. Each of FIGS. 19(a), 19(b), and 19(c) schematically shows a cross section of each of the metal silicide layers 11b formed over the source/drain regions (n⁺-type semiconductor regions 5b or p⁺-type semiconductor regions 6b), which is parallel with the gate length direction and perpendicular to the main surface of the semiconductor substrate 1. That is, each of FIGS. 19(a), 19(b), and 19(c) shows the same cross section as the cross section of the metal silicide layer 11b shown in FIG. 16 described above, and the X-direction shown in FIGS. 19(a) to 19(c) is the gate length direction. FIG. 19(a) corresponds to the case where the foregoing second condition is not satisfied (i.e., where the grain size G1 in the metal silicide layer 11b is not less than the width W1 of the source/drain region (G1≧W1)), while FIGS. 19(b) and 19(c) show the case where the foregoing second condition is satisfied (i.e., where the grain size G1 in the metal silicide layer 11b is smaller than the width W1 of the source/drain region (G1<W1)). In FIGS. 19(a), 19(b), and 19(c), under the metal silicide layers 11b, the source/drain regions (n⁺-type semiconductor regions 5b or p⁺-type semiconductor regions 6b) actually exist, but the depiction thereof is omitted for simpler illustration.

In the case where the foregoing second condition is not satisfied (where G1≧W1 is satisfied), when the metal silicide layer 11b formed over the source/drain region is viewed in the cross section shown in FIG. 19(a), a state is observed where the dimension in the gate length direction is occupied by substantially one crystal grain (crystal grain GR1 in the case of FIG. 19(a)), and grain boundaries traversing the gate length direction are rarely present.

By contrast, in the case where the foregoing second condition is satisfied (where G1<W1 is satisfied), when the metal silicide layer 11b formed over the source/drain region is viewed in each of the cross sections shown in FIGS. 19(b) and 19(c), a state is observed where the dimension in the gate length direction is occupied by the plurality of crystal grains (two crystal grains GR2a and GR2b in the case of FIG. 19(b) and three crystal grains GR3a, GR3b, and GR3c in the case of FIG. 19(c)), and grain boundaries GB traversing the gate length direction are present.

That is, whether or not the grain size G1 in the metal silicide layer 11b is smaller than the width W1 of the source/drain region (n⁺-type semiconductor region 5b or p⁺-type semiconductor region 6b) substantially determines whether or not the metal silicide layer 11b formed over the source/drain region has the grain boundary GB traversing the gate length direction.

Each of the crystal grains (to which the crystal grains GR1, GR2a, GR2b, GR3a, GR3b, and GR3c of FIGS. 19(a), 19(b), and 19(c) also correspond) forming each of the metal silicide layers 11b formed over the source/drain regions (n⁺-type semiconductor regions 5b or p⁺-type semiconductor regions 6b) of the MISFETs is substantially in a state of a single crystal (specifically a single crystal in the Ni_{1-y}M_{y}Si phase) but, when the crystal grains are compared with each other, the crystal orientations thereof are different. That is, when the crystal grain size (grain size G1) is small, the metal silicide layer 11b is formed of a plurality of crystal grains having different crystal orientations.

Each of the crystal grains forming the metal silicide layers 11b and the semiconductor substrate 1 (each of the regions of the semiconductor substrate 1 in which impurities are diffused can also be regarded as a part of the semiconductor substrate 1) is formed of a single crystal. However, depending on the combination of the crystal orientations of the crystal grains and the crystal orientation of the semiconductor substrate 1, a state is produced where Ni_{1-y}M_{y}Si₂ tends to abnormally grow from the crystal grains substantially formed of the single crystal in the Ni_{1-y}M_{y}Si phase toward the semiconductor substrate 1.

It is difficult to control the crystal orientation of each of the crystal grains forming the metal silicide layers 11b, and the crystal grains having various crystal orientations can be formed in the metal silicide layers 11b. As a result, in the metal silicide layers 11b, crystal grains having such crystal orientations that allow easy abnormal growth of Ni_{1-y}M_{y}Si₂ toward the semiconductor substrate 1 are generated with a given probability. That is, when the plurality of (numerous) MISFETs are formed in the main surface the semiconductor substrate 1, in a given proportion of the plurality of (numerous) MISFETs, in the metal silicide layers 11b formed over the source/drain regions thereof, the crystal grains having such crystal orientations that allow easy abnormal growth of Ni_{1-y}M_{y}Si₂ toward the semiconductor substrate 1 are generated.

When the crystal grains having such crystal orientations that allow easy abnormal growth of Ni_{1-y}M_{y}Si₂ toward the semiconductor substrate 1 are present in any of the metal silicide layers 11b, there is a probability that Ni_{1-y}M_{y}Si₂ abnormally grows from the crystal grains toward the semiconductor substrate 1. In particular, when crystal grains having such crystal orientations that allow easy abnormal growth of Ni_{1-y}M_{y}Si₂ toward the channel portion are present in the metal silicide layer 11b, there is a possibility that Ni_{1-y}M_{y}Si₂ abnormally grows from the crystal grains toward the channel portion. When the abnormal growth of Ni_{1-y}M_{y}Si₂ toward the channel portion has occurred, the leakage current between the source/drain of the MISFET is increased (which leads to the occurrence of the foregoing leakage current defect) to greatly affect the performance.

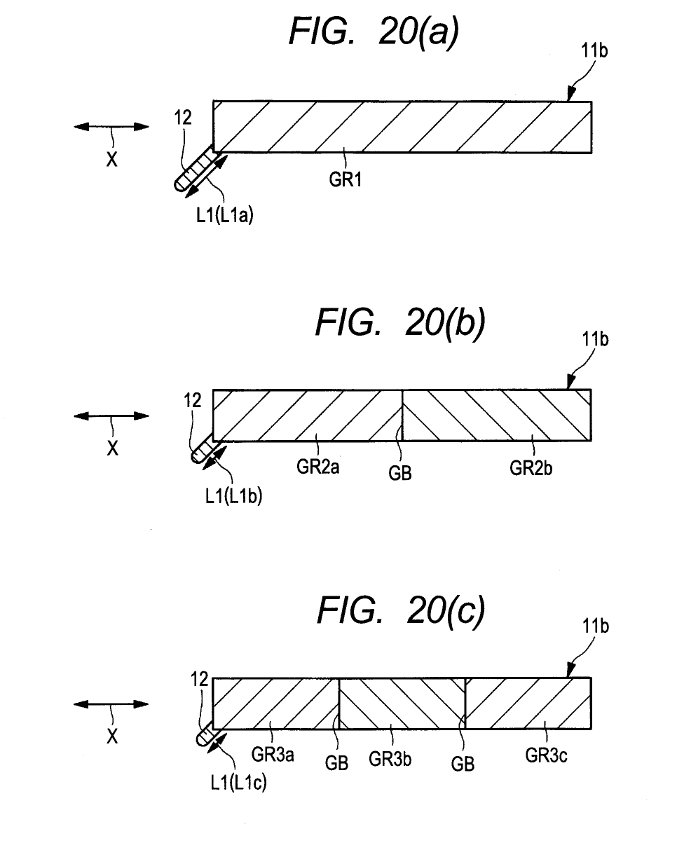

FIGS. 20(a), 20(b), and 20(c) are illustrative views each schematically showing a state where the abnormal growth of Ni_{1-y}M_{y}Si₂ has occurred in any of the metal silicide layers 11b. A drawing obtained by adding an abnormally, grown portion (abnormally grown area) 12 of Ni_{1-y}M_{y}Si₂ to FIGS. 19(a) to 19(c) described above corresponds to FIGS. 20(a) to 20(c). Accordingly, FIGS. 20(a), 20(b), and 20(c) correspond to FIGS. 19(a), 19(b), and 19(c), respectively. FIGS. 19(a) and 20(a) correspond to the case where the foregoing second condition is not satisfied (where G1≧W1 is satisfied), while FIGS. 19(b), 19(c), 20(b), and 20(c) correspond to the case where the foregoing second condition is satisfied (where G1<W1 is satisfied).

When the crystal grains having such crystal orientations that allow easy abnormal growth of Ni_{1-y}M_{y}Si₂ toward the semiconductor substrate 1 are present in the metal silicide layer 11b, the crystal grains serve as a supply source of the abnormally grown portion of Ni_{1-y}M_{y}Si₂ so that the abnormal growth of Ni_{1-y}M_{y}Si₂ occurs. In the cases of FIGS. 20(a) to 20(c), it is assumed that the crystal grain GR1 shown in FIG. 20(a), the crystal grain GR2a of the crystal grains GR2a and GR2b shown in FIG. 20(b), and the crystal grain GR3a of the crystal grains GR3a, GR3b, and GR3c shown in FIG. 20(c) have such crystal orientations that allow easy abnormal growth of Ni_{1-y}M_{y}Si₂ toward the semiconductor substrate 1. Accordingly, in the case of FIG. 20(a), the abnormally grown portion 12 of Ni_{1-y}M_{y}Si₂ has grown from the crystal grain GR1. In the case of FIG. 20(b), the abnormally grown portion 12 of Ni_{1-y}M_{y}Si₂ has grown from the crystal grain GR2a. In the case of FIG. 20(c), the abnormally grown portion 12 of Ni_{1-y}M_{y}Si₂ has grown from the crystal grain GR3a. The abnormally grown portion 12 of Ni_{1-y}M_{y}Si₂ tends to grow in the <110> orientation of Si forming the semiconductor substrate 1.

When the crystal grains (the crystal grains GR1, GR2a, and GR3a in the cases of FIGS. 20(a) to 20(c)) having such crystal orientations that allow easy abnormal growth of Ni_{1-y}M_{y}Si₂ have large grain sizes, it follows that the supply source of the abnormally grown portion of Ni_{1-y}M_{y}Si₂ is large. Accordingly, the amount of the abnormal growth of Ni_{1-y}M_{y}Si₂ increases to increase a length L1 of the abnormally grown portion 12. On the other hand, when the crystal grains (the crystal grains GR1, GR2a, and GR3a in the cases of FIGS. 20(a) to 20(c)) having such crystal orientations that allow easy abnormal growth of Ni_{1-y}M_{y}Si₂ have small grain sizes, it follows that the supply source of the abnormally grown portion of Ni_{1-y}M_{y}Si₂ is small. Accordingly, the amount of the abnormal growth of Ni_{1-y}M_{y}Si₂ decreases to reduce the length L1 of the abnormally grown portion 12. As the length L1 of the abnormally grown portion 12 of Ni_{1-y}M_{y}Si₂ from the metal silicide layer 11b toward the channel portion is longer, the leakage current between the source/drain of the MISFET increases to lead to the occurrence of the foregoing leakage current defect. Therefore, to suppress the occurrence of the foregoing leakage current defect, it is effective to reduce the length L1 of the abnormally grown portion 12 of Ni_{1-y}M_{y}Si₂ from the metal silicide layer 11b toward the channel portion.

Therefore, in the present embodiment, as the foregoing second condition, the grain size in each of the metal silicide layers 11b is controlled, and the grain size G1 in each of the metal silicide layers 11b is set smaller than the width W1 (G1<W1) of each of the source/drain regions (n⁺-type semiconductor regions 5b or p⁺-type semiconductor regions 6b). By satisfying the foregoing second condition, when the metal silicide layer 11b formed over each of the source/drain regions (n⁺-type semiconductor regions 5b or p⁺-type semiconductor regions 6b) is viewed in each of the cross sections shown in FIGS. 19(b) and 19(c), a state is observed where the dimension in the gate length direction is occupied by the plurality of crystal grains (the crystal grains GR2a and GR2b in the case of FIG. 19(b) and the crystal grains GR3a, GR3b, and GR3c in the case of FIG. 19(c)), and the crystal boundary. GB traversing the gate length direction is present. The crystal grains (the crystal grains GR2a and GR2b in the case of FIG. 19(b) and the crystal grains GR3a and GR3b or GR3b and GR3c in the case of FIG. 19(c)) adjacent to each other with the grain boundary GB interposed therebetween have mutually different crystal orientations. As a result, even when the crystal grains having such crystal orientations that allow easy abnormal growth of Ni_{1-y}M_{y}Si₂ toward the semiconductor substrate 1 (the crystal grain GR2a in FIG. 19(b) and the crystal grain GR3a in FIG. 19(c)) are present in the metal silicide layer 11b, it is possible to obtain the effect of suppressing the abnormal growth of Ni_{1-y}M_{y}Si₂ due to the small grain sizes of the crystal grains (crystal grains GR2a and GR3a) serving as the supply source of the abnormally grown portion 12 of Ni_{1-y}M_{y}Si₂. In other words, it is possible to obtain the effects of a reduction in the amount of the abnormal growth of Ni_{1-y}M_{y}Si₂ and a reduction in the length L1 of the abnormally grown portion 12. As a result, compared with the length L1 (which will be referred to as the length L1a) of the abnormally grown portion 12 in the case of FIG. 20(a) (where G1≧W1 is satisfied)), the lengths L1 (which will be referred to as the lengths L1b and L1c) of the abnormally grown portions 12 in the cases of FIGS. 20(b) and 20(c) (where G1<W1 is satisfied)) are reduced (i.e., L1b and L1c<L1a).

When Ni_{1-y}M_{y}Si₂ abnormally grows from any of the metal silicide layers 11b toward the semiconductor substrate 1, what particularly matters is the abnormal growth of Ni_{1-y}M_{y}Si₂ from the metal silicide layer 11b toward the channel portion. Compared with that, even when Ni_{1-y}M_{y}Si₂ abnormally grows from the metal silicide layer 11b in the gate width direction (channel width direction), the resulting adverse effect is small. Therefore, it is needed to suppress the abnormal growth of Ni_{1-y}M_{y}Si₂ from the metal silicide layer 11b toward the channel portion and, to satisfy the need, it is effective that, when the crystal grains having such crystal orientations that allow easy abnormal growth of Ni_{1-y}M_{y}Si₂ toward the semiconductor substrate 1 are present in the metal silicide layer 11b, the dimensions (grain sizes) in the gate length direction of the crystal grains are reduced. That is, to suppress the abnormal growth of Ni_{1-y}M_{y}Si₂ from the metal silicide layer 11b toward the channel portion, it is effective that the metal silicide layer 11b is not in a state where the dimension in the gate length direction is occupied by one crystal grain as in FIGS. 19(a) and 20(a), but in a state where the dimension in the gate length direction is occupied by a plurality of crystal grains (state where the grain boundary GB traversing the gate length direction is present) as in FIGS. 19(b), 19(c), 20(b), and 20(c). Since the grain boundary GB operates to suppress the abnormal growth of Ni_{1-y}M_{y}Si₂, the presence of the grain boundary GB traversing the gate length direction in the metal silicide layer 11b operates to suppress the abnormal growth of Ni_{1-y}M_{y}Si₂ from the metal silicide layer 11b toward the channel portion.

When the foregoing second condition is not satisfied and the grain size G1 in the metal silicide layer 11b is not less than the width W1 of the source/drain region (G1≧W1), the dimension (grain size) in the gate length direction of each of the crystal grains forming the metal silicide layer 11b formed over the source/drain region is substantially equal to the width W1 of the source/drain region. By contrast, by satisfying the foregoing second condition and setting the grain size G1 in the metal silicide layer 11b smaller than the width W1 of the source/drain region (G1<W1), the dimension (grain size) in the gate length direction of each of the crystal grains forming the metal silicide layer 11b formed over the source/drain region can be set smaller than the width W1 of the source/drain region. It follows therefore that whether or not the grain size G1 in the metal silicide layer 11b is set smaller than the width W1 of the source/drain region (n⁺-type semiconductor region 5b or p⁺-type semiconductor region 6b) determines whether the dimension (grain size) in the gate length direction of each of the crystal grains forming the metal silicide layer 11b formed over the source/drain region becomes smaller than or substantially equal to the width W1 of the source/drain region.

In the present embodiment, by satisfying the foregoing second condition, when the metal silicide layer 11b formed over the source/drain region is viewed in each of the cross sections shown in FIGS. 19(b), 19(c), 20(b), and 20(c), a state is achieved where the dimension in the gate length direction is occupied by the plurality of crystal grains (the crystal grains GR2a and GR2b in FIGS. 19(b) and 20(b) and the crystal grains GR3a, GR3b, and GR3c in FIGS. 19(c) and 20(c)), and the crystal boundary GB traversing the gate length direction is present. As a result, compared with the case (where the foregoing second condition is not satisfied) of each of FIGS. 19(a) and 20(a), the abnormal growth of Ni_{1-y}M_{y}Si₂ from the metal silicide layer 11b toward the channel portion can be suppressed.

As the length L1 of the abnormally grown portion 12 of Ni_{1-y}M_{y}Si₂ from the metal silicide layer 11b toward the channel portion is longer, the leakage current between the source/drain of the MISFET is more likely to increase to lead to the occurrence of the foregoing leakage current defect. However, in the present embodiment, by satisfying the foregoing second condition, it is possible to reduce the length L1 of the abnormally grown portion 12 of Ni_{1-y}M_{y}Si₂ from the metal silicide layer 11b toward the channel portion. Therefore, it is possible to suppress or prevent an increase in the leakage current between the source/drain of the MISFET due to the abnormal growth of Ni_{1-y}M_{y}Si₂, and suppress or prevent the occurrence of the foregoing leakage current defect, as also shown in the graph of FIG. 18 described above.

To maximally suppress the abnormal growth of Ni_{1-y}M_{y}Si₂ from the metal silicide layer 11b toward the channel portion, it is effective to increase the number of the grain boundaries GB traversing the gate length direction in the metal silicide layer 11b. In the metal silicide layer 11b, the number of the grain boundaries GB traversing the gate length direction is substantially 0 when G1≧W1 is satisfied, substantially 1 when W1×0.5≦G1<W1 is satisfied, and substantially not less than 2 when G1<W1×0.5 is satisfied. Therefore, under the foregoing second condition, the grain size G1 in the metal silicide layer 11b is set smaller than the width W1 of the source/drain region (G1<W1), and more preferably set less than ½ of the width W1 of the source/drain region (i.e., G1<W1×0.5). This allows more reliable suppression of the abnormal growth of Ni_{1-y}M_{y}Si₂ from the metal silicide layer 11b toward the channel portion.

Thus, in the present embodiment, as the foregoing second condition, the grain size G1 in the metal silicide layer 11b is set smaller than the width W1 of the source/drain region (n⁺-type semiconductor region 5b or p⁺-type semiconductor region 6b) (G1<W1) (more preferably, set less than half the width W1 (G1<W1×0.5) to allow the abnormal growth of Ni_{1-y}M_{y}Si₂ to be suppressed.

In the semiconductor device of the present embodiment, the plurality of MISFETs having the gate electrodes GE and the source/drain regions (n⁺-type semiconductor regions 5b or p⁺-type semiconductor regions 6b) over which the metal silicide layers 11b are formed are formed in the main surface of the semiconductor substrate 1. In the semiconductor substrate 1 forming the semiconductor device, the plurality of MISFETs are formed, but the widths W1 of the source/drain regions (n⁺-type semiconductor regions 5b or p⁺-type semiconductor regions 6b) are not necessarily uniform in all the MISFETs. In other words, the MISFETs of a plurality of types having the source/drain regions (n⁺-type semiconductor regions 5b or p⁺-type semiconductor regions 6b) having the different widths W1 may be mounted in mixed relation in the semiconductor substrate 1.

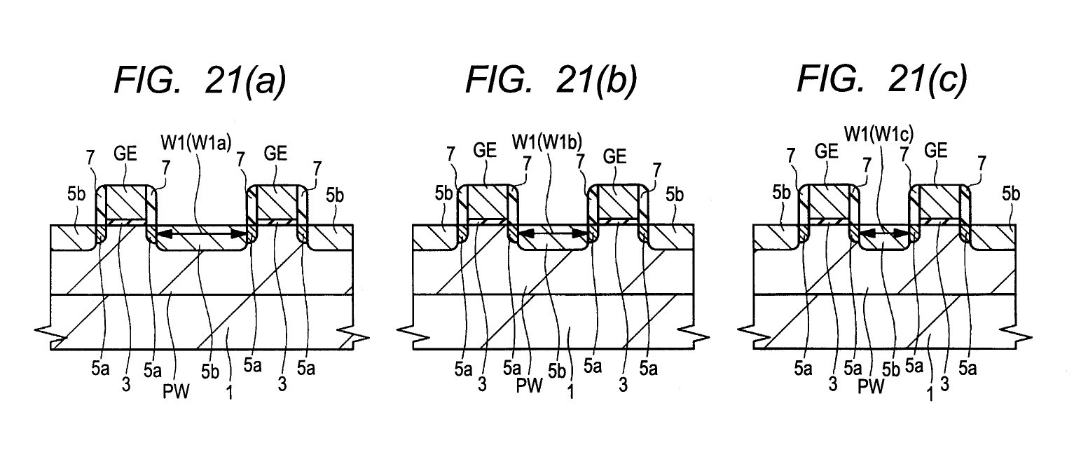

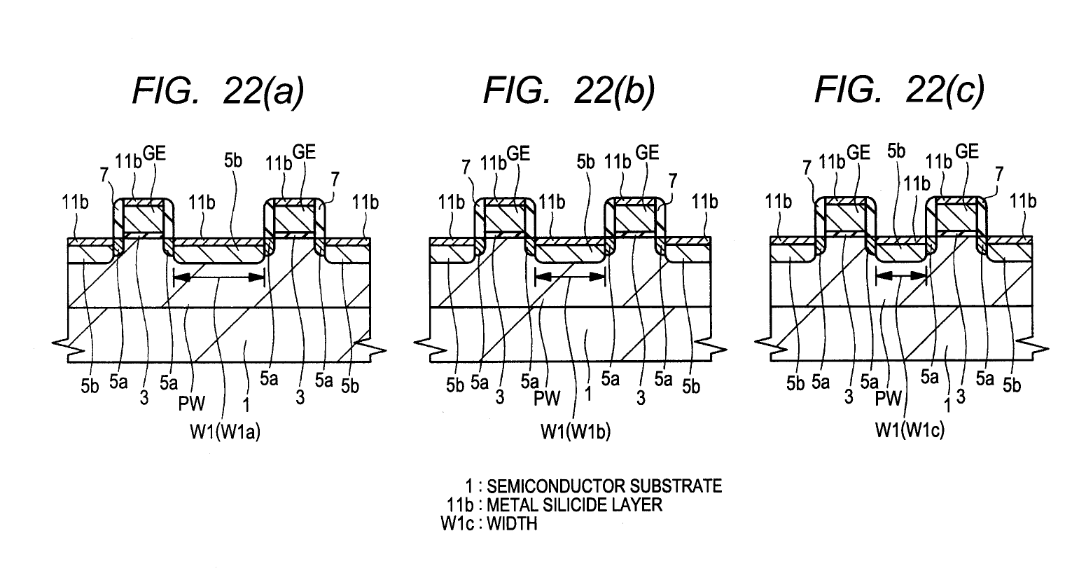

FIGS. 21(a), 21(b), and 21(c) are main-portion cross-sectional views of the semiconductor device at the stage (i.e., the same process stage as in FIGS. 6 and 14 described above) after the n⁺-type semiconductor regions 5b and the p⁺-type semiconductor regions 6b are formed and before the foregoing alloy film 8 is formed in Step S1 described above. FIGS. 22(a), 22(b), and 22(c) are main-portion cross-sectional views of the semiconductor device at the stage (i.e., the same process stage as in FIGS. 10 and 16 described above) after the metal silicide layers 11b are formed by performing Steps S1 to S5 described above and before the foregoing insulating film 21 is formed. FIGS. 21(a) to 22(c) show the same cross-sectional region at the different process stages. In FIGS. 21(a) to 22(c), the region where the n-channel MISFETs are formed is shown. However, in the case where the region where the p-channel MISFETs are formed is shown, in each of FIGS. 21(a) to 22(c), the p-type well PW is replaced with the n-type well NW, the n⁻-type semiconductor regions 5a are replaced with the p⁻-type semiconductor regions 6a, and the n⁺-type semiconductor regions 5b are replaced with the p⁺-type semiconductor regions 6b. In this case, the gate electrodes GE are such that the gate electrodes GE1 are replaced with the gate electrodes GE2.

FIGS. 21(a) and 22(a) show the regions where the MISFETs in which the widths W1 of the source/drain regions (n⁺-type semiconductor regions 5b or p⁺-type semiconductor regions 6b) are relatively large (wide) are formed. FIGS. 21(b) and 22(b) show the regions where the MISFETs in which the widths W1 of the source/drain regions (n⁺-type semiconductor regions 5b or p⁺-type semiconductor regions 6b) are smaller (narrower) than in FIGS. 21(a) and 22(a) are formed. FIGS. 21(c) and 22(c) show the regions where the MISFETs in which the widths W1 of the source/drain regions (n⁺-type semiconductor regions 5b or p⁺-type semiconductor regions 6b) are further smaller (narrower) than in FIGS. 21(a), 21(b), 22(a), and 22(b) are formed. When viewed from a different viewpoint, the foregoing adjacent spacing W3 (shown in FIGS. 14 and 15 described above) is smaller in FIGS. 21(b) and 22(b) than in FIGS. 21(a) and 22(a), and further smaller in FIGS. 21(c) and 22(c) than in FIGS. 21(a), 21(b), 22(a), and 22(b).

Here, the width W1 of each of the source/drain regions (n⁺-type semiconductor regions 5b or p⁺-type semiconductor regions 6b) of the MISFETs shown in FIGS. 21(a) and 22(a) is, referred to as a width W1a. The width W1 of each of the source/drain regions (n⁺-type semiconductor regions 5b or p⁺-type semiconductor regions 6b) of the MISFETs shown in FIGS. 21(b) and 22(b) is referred to as a width W1b. The width W1 of each of the source/drain regions (n⁺-type semiconductor regions 5b or p⁺-type semiconductor regions 6b) of the MISFETs shown in FIGS. 21(c) and 22(c) is referred to as a width W1c. The relations among the widths W1a, W1b, and W1c are such that the width W1b is smaller than the width W1a, and the width W1c is smaller than the width W1b (i.e., W1c<W1b<W1a).

Note that the width (first width) W1c of each of the source/drain regions (n⁺-type semiconductor regions 5b or p⁺-type semiconductor regions 6b) of the MISFETs shown in FIGS. 21(c) and 22(c) corresponds to the width W1 of each of the source/drain regions of the MISFET which is the smallest (narrowest) in the width W1 of each of the source/drain regions (n⁺-type semiconductor regions 5b or p⁺-type semiconductor regions 6b) of all the MISFETs formed in the semiconductor substrate 1 forming the semiconductor device of the present embodiment. As a result, the semiconductor device of the present embodiment includes the MISFET in which the width W1 of each of the source/drain regions (n⁺-type semiconductor regions 5b or p⁺-type semiconductor regions 6b) is equal to the width W1c (i.e., W1=W1c), but does not include the MISFET in which the width W1 of each of the source/drain regions (n⁺-type semiconductor regions 5b or p⁺-type semiconductor regions 6b) is smaller than the width W1c (i.e., W1<W1c). Thus, in the semiconductor device of the present embodiment, the plurality of MISFETs are formed, and the widths W1 of the source/drain regions (n⁺-type semiconductor regions 5b or p⁺-type semiconductor regions 6b) may have various values depending on the use and type of each of the MISFETs. Of the widths W1, the one having the smallest value is the width W1c.

The width W1 of the source/drain region (n⁺-type semiconductor region 5b or p⁺-type semiconductor region 6b) disposed between the gate electrodes GE adjacent to each other in the gate length direction decrease as the adjacent spacing W3 (shown in FIGS. 14 and 15) between the gate electrodes GE is narrower (smaller). Therefore, it can also be said that the source/drain region (n⁺-type semiconductor region 5b or p⁺-type semiconductor region 6b) having the width W1c shown in each of FIGS. 21(c) and 22(c) is the one of the source/drain regions of the plurality of MISFETs formed in the main surface of the semiconductor substrate 1 which is disposed between the gate electrodes GE adjacent in closest proximity to each other (i.e., between which the foregoing adjacent spacing W3 is smallest) in the gate length direction. That is, in the semiconductor device of the present embodiment, the plurality of MISFETs are formed, and the foregoing adjacent spacing W3 may have various values depending on the use and type of each of the MISFETs. Of the source/drain regions of the MISFETs, the one disposed between the gate electrodes GE adjacent to each other with the smallest adjacent spacing W3 therebetween is the source/drain region having the width W1c. The semiconductor device of the present embodiment has a plurality of portions where the gate electrodes GE are adjacent to each other in the gate length direction in the main surface of the semiconductor substrate 1, and the foregoing adjacent spacing W3 is smallest between the gate electrodes GE (i.e., between the gate electrodes GE adjacent to each other with the source/drain region having the width W1c interposed therebetween) shown in each of FIGS. 21(c) and 22(c).

In the semiconductor device of the present embodiment, the plurality of MISFETs are formed and, over the source/drain regions (n⁺-type semiconductor regions 5b or p⁺-type semiconductor regions 6b) of each of the MISFETs, the metal silicide layers 11b are formed by the salicide process. Since the metal silicide layers 11b are formed in the same step, by adjusting heat treatment conditions (conditions for the foregoing first and second heat treatments) or the like, it is possible to equally control the grain sizes (values each corresponding to the foregoing grain size G1) for all the metal silicide layers 11b, but it is difficult to individually control the grain sizes in the metal silicide layers 11b for each of the MISFETs. Therefore, it is difficult to independently control the grain size in the metal silicide layer 11b formed over the source/drain region (n⁺-type semiconductor region 5b or p⁺-type semiconductor region 6b) having the width W1c shown in FIG. 22(c), the grain size in the metal silicide layer 11b formed over the source/drain region having the width W1b shown in FIG. 22(b), and the grain size in the metal silicide layer 11b formed over the source/drain region having the width W1a shown in FIG. 22(a).

Therefore, in the present embodiment, as a third condition, the grain size (crystal grain size) G1 in the metal silicide layer 11b formed over each of the source/drain regions (n⁺-type semiconductor regions 5b or p⁺-type semiconductor regions 6b) is set smaller than the foregoing width W1c (G1<W1c). Specifically, the grain size G1 in the metal silicide layer 11b is set smaller than the width (first width) W1c in the gate length direction of the one (first source/drain region which is the source/drain region (n⁺-type semiconductor region 5b or p⁺-type semiconductor region 6b) shown in each of FIGS. 21(c) and 22(c)) of the source/drain regions of the plurality of MISFETs formed in the main surface of the semiconductor substrate 1 which has the smallest width W1 in the gate length direction (i.e., G1<W1c). The first and second heat treatments in Steps S3 and S5 described above are performed so as to satisfy the third condition. The third condition is applied to all the metal silicide layers 11b formed over the source/drain regions (n⁺-type semiconductor regions 5b or p⁺-type semiconductor regions 6b) irrespective of the widths W1 of the source/drain regions (n⁺-type semiconductor regions 5b or p⁺-type semiconductor regions 6b). That is, the grain sizes G1 in the metal silicide layers 11b of FIG. 22(a), the grain sizes G1 in the metal silicide layers 11b of FIG. 22(b), and the grain sizes G1 in the metal silicide layers 11b of FIG. 22(c) are set smaller than the width W1c of the source/drain region (n⁺-type semiconductor region 5b or p⁺-type semiconductor region 6b) of FIG. 22(c) (G1<W1c). The third condition can also be expressed from a different viewpoint as follows. That is, when the plurality of MISFETs having the source/drain regions (n⁺-type semiconductor regions 5b or p⁺-type semiconductor regions 6b) over which the metal silicide layers 11b are formed are formed in the main surface of the semiconductor substrate 1, the foregoing second condition is sure to be satisfied in each of the metal silicide layers 11b formed over the source/drain regions irrespective of the magnitudes of the widths W1 of the source/drain regions.

When the third condition is satisfied, the MISFET having the metal silicide layers 11b and the source/drain regions which do not satisfy the foregoing second condition (i.e., which satisfy G1≧W1) no more exist in the main surface of the semiconductor substrate 1, and a state is achieved where the foregoing second condition is satisfied in each of the metal silicide layers 11b formed over the source/drain regions. For example, in each of the metal silicide layers 11b formed over the source/drain regions (n⁺-type semiconductor regions 5b or p⁺-type semiconductor regions 6b) of FIGS. 22(a), 22(b), and 22(c), the grain size G1 therein is set smaller than the width W1c of the source/drain region (n⁺-type semiconductor region 5b or p⁺-type semiconductor region 6b) of FIG. 22(c). As a result, in each of FIGS. 22(a), 22(b), and 22(c), a state is achieved where the second condition is satisfied (G1<W1).

If the MISFET having the metal silicide layers 11b and the source/drain regions which do not satisfy either the third condition or the foregoing second condition (i.e., G1≧W1) is formed in the main surface of the semiconductor substrate 1, in the MISFET, Ni_{1-y}M_{y}Si₂ tends to abnormally grow from any of the metal silicide layers 11b over the source/drain regions toward the channel portion, and therefore the leakage current may increase to result in the foregoing leakage current defect.

By contrast, if the third condition is satisfied, the MISFET having the metal silicide layers 11b (i.e., the metal silicide layers 11b from which Ni_{1-y}M_{y}Si₂ tends to abnormally grow) and the source/drain regions which do not satisfy the foregoing second condition (i.e., which satisfy G1≧W1) no more exists in the main surface of the semiconductor substrate 1. As a result, it is possible to suppress or prevent problems (an increased leakage current and the resulting occurrence of the foregoing leakage current defect) resulting from the abnormal growth of Ni_{1-y}M_{y}Si₂ from the metal silicide layer 11 for all the MISFETs having the source/drain regions over which the metal silicide layers 11b are formed. Therefore, the performance of the semiconductor device having the plurality of MISFETs can be reliably improved.

Thus, by satisfying both of the foregoing first condition and the foregoing second condition, it is possible to improve the performance of each of the MISFETs which satisfy the first and second conditions. In addition, by further satisfying the foregoing third condition, the overall performance of the plurality of MISFETs formed in the main surface of the semiconductor substrate 1 can be improved, and the performance of the semiconductor device including the plurality of MISFETs can be improved.

Under the foregoing third condition, the grain size G1 in each of the metal silicide layers 11b is set smaller than the foregoing width W1c (G1<W1c) but, by the same reasoning as used for the foregoing second condition, the grain size G1 in the metal silicide layer 11b is more preferably set less than ½ of the foregoing W1c (i.e., G1<W1c×0.5). This allows the number of the grain boundaries GB traversing the gate length direction to be increased, and therefore the abnormal growth of Ni_{1-y}M_{y}Si₂ from the metal silicide layer 11b toward the channel portion can be more reliably suppressed.

In the present embodiment, the foregoing first condition is satisfied as the prior condition, but the effect (e.g., the effect of suppressing the abnormal growth of the NiSi₂ phase) achieved by the metal silicide layer 11b containing the first metal element M (preferably Pt) increases as the concentration of the first metal element M (preferably Pt) in the metal silicide layer 11b increases. Accordingly, it is desired to increase the concentration of the first metal element M (preferably Pt) in each of the metal silicide layers 11b, and further improve the performance of the semiconductor device. In addition, to satisfy the foregoing third condition, it is desired to reduce the grain size in each of the metal silicide layers 11b. Therefore, it is desired to provide a manufacturing technique which allows an increase in the concentration of the first metal element M (preferably Pt) in each of the formed metal silicide layers 11b and a manufacturing technique which allows a reduction in the grain size in each of the formed metal silicide layers 11b.

Therefore, the present embodiment has devised a method in which the metal silicide layers 11b are formed by the salicide process. Hereinbelow, the first heat treatment in Step S3 described above and the second heat treatment in Step S5 described above will be described in greater detail.

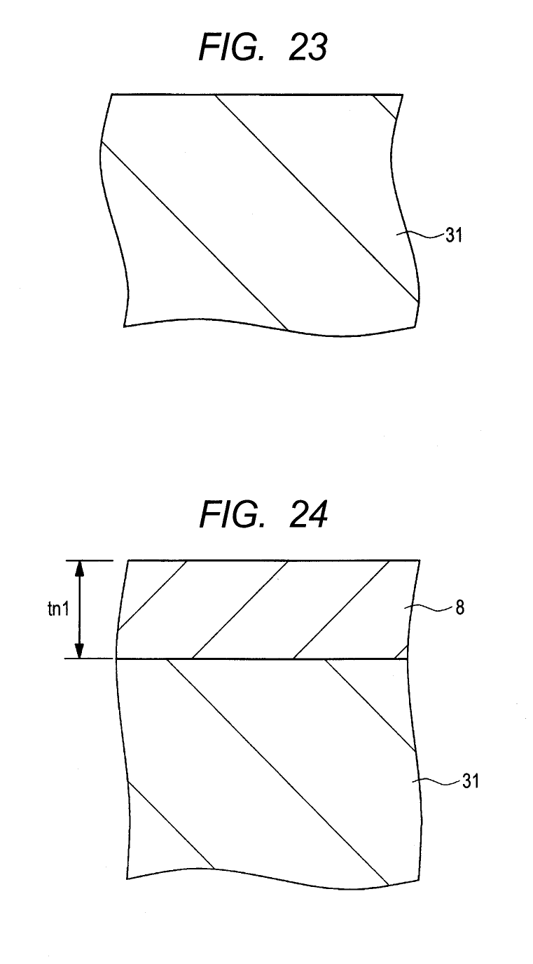

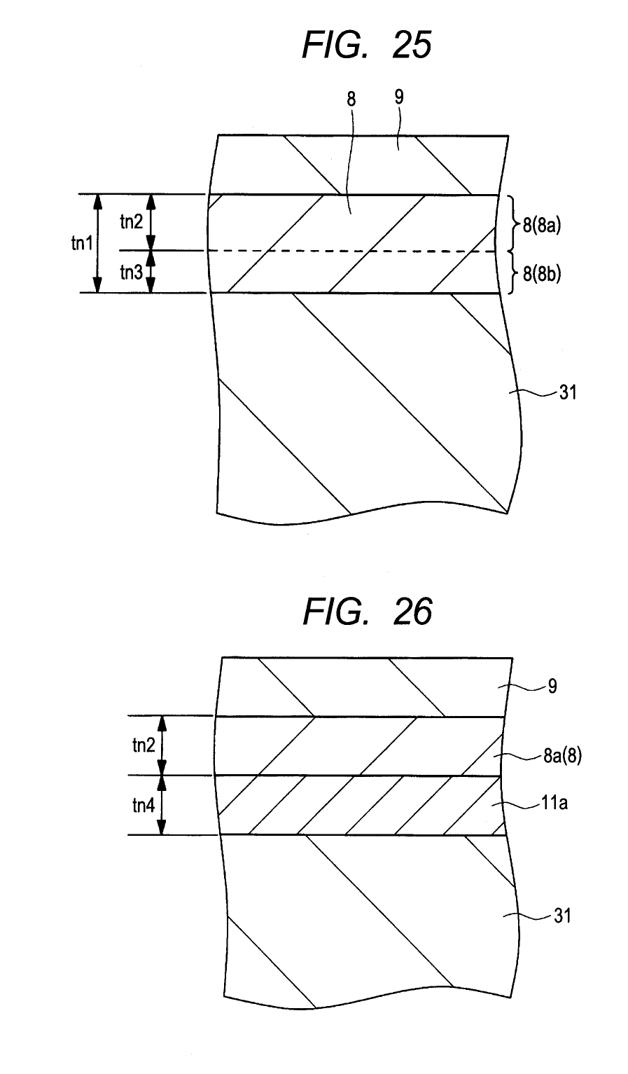

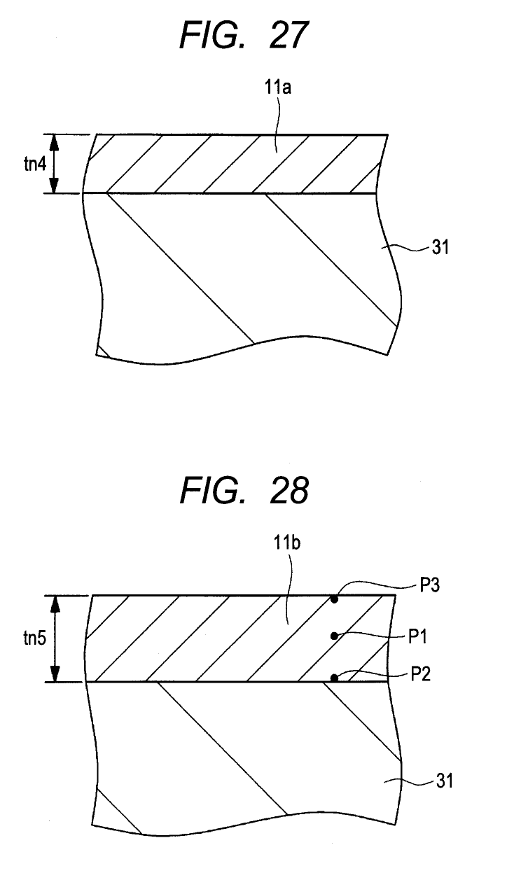

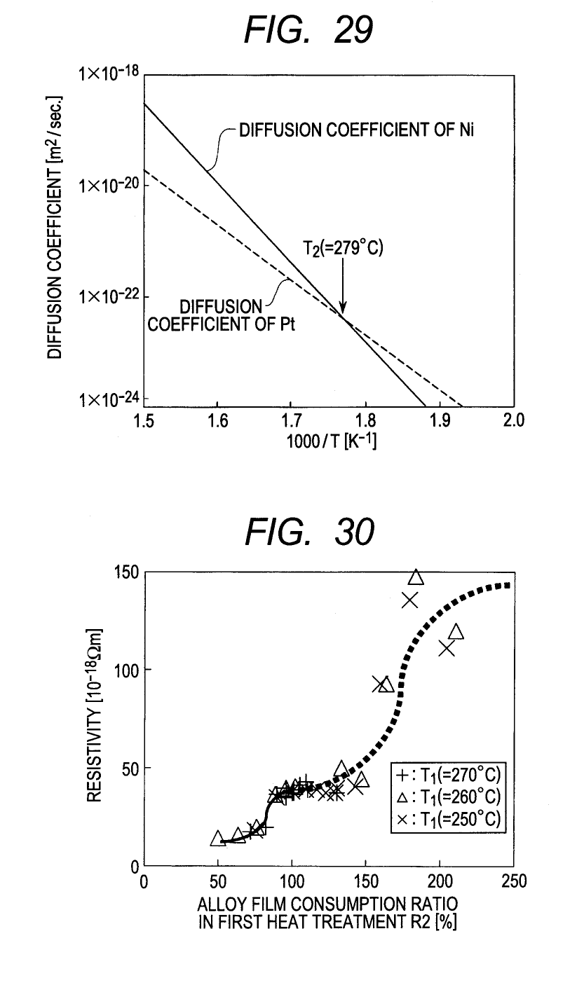

FIGS. 23 to 28 are main-portion cross-sectional views of the semiconductor device during the manufacturing steps at the individual stages in Steps S1, S2, S3, S4, and S5, and show a region in the vicinity of an upper portion of a silicon (Si) region 31. FIG. 29 is a graph showing the diffusion coefficients of Ni and Pt in the Si region (silicon region), and shows the Arrhenius plots of the diffusion coefficients of Ni and Pt in the Si region. The ordinate axis of the graph of FIG. 29 corresponds to the diffusion coefficient of Ni or Pt in the Si region, while the abscissa axis of FIG. 29 corresponds to one thousand times the reciprocal of an absolute temperature T. Of FIGS. 23 to 28, FIG. 23 shows the stage immediately before the alloy film 8 is formed in Step S1, FIG. 24 shows the stage (stage prior to the formation of the barrier film 9 in step S2) at which the alloy film 8 has been formed by performing Step S1, and FIG. 25 shows the stage (stage prior to the first heat treatment in Step S3) at which the barrier film 9 has been formed by performing Step S2. FIG. 26 shows the stage (stage before the step of removing the barrier film 9 and the unreacted alloy film 8 in Step S4 is performed) at which the first heat treatment in Step S3 has been performed. FIG. 27 shows the stage (stage before the second heat treatment in Step S5 is performed) at which the step of removing the barrier film 9 and the unreacted alloy film 8 in Step S4 has been performed. FIG. 28 shows the stage (stage before the insulating film 21 is formed) at which the second heat treatment in Step S5 has been performed.

Note that the source of the Arrhenius plots of FIG. 29 is “O. Madelung, M. Schulz, and H. Weiss eds.,/Landolt-Bornstein//Zahlenwerte und Funktionen aus Naturwissenshaften und Technik/, p. 494, Berlin: Springer-Verlag, 1984”.

Here, the silicon region 31 shown in each of FIGS. 23 to 28 corresponds to any of the gate electrodes GE, the n⁺-type semiconductor regions 5b (source/drain regions), and the p⁺-type semiconductor regions 6b (source/drain regions). This is because each of the gate electrodes GE, the n⁺-type semiconductor regions 5b, and the p⁺-type semiconductor regions 6b is formed of a silicon region (specifically, each of the gate electrodes GE is formed of a polysilicon film, and each of the n⁺-type semiconductor regions 5b and the p⁺-type semiconductor regions 6b is formed of a single-crystal silicon region). If the silicon region 31 is the gate electrode GE, the silicon region 31 is formed of polysilicon. If the silicon region 31 is the source/drain region (n⁺-type semiconductor region 5b or p⁺-type semiconductor region 6b), the silicon region 31 is formed of single-crystal silicon.

To form the metal silicide as described above, as shown in FIGS. 23 and 24, in Step S1, the alloy film 8 is formed over the main surface (entire surface) of the semiconductor substrate 1 including the silicon region 31 (i.e., the gate electrode GE, the n⁺-type semiconductor region 5b, or the p⁺-type semiconductor region 6b). The formed film thickness (deposited film thickness) of the alloy film 8 over the silicon region 31 is a thickness (film thickness) tn1. The thickness tn1 corresponds to the thickness of the alloy film over the silicon region 31 prior to the first heat treatment in Step S3. The formed alloy film 8 is a Ni₁₋ₓMₓ alloy film (where 0<x<1 is satisfied) which is an alloy film in which an atomic ratio between Ni and the first metal element M is 1−x:x.

Then, as shown in FIG. 25, in Step S2, the barrier film is formed over the alloy film 8. Thereafter, when the first heat treatment in Step S3 is performed, as shown in FIG. 26, the silicon region 31 and the alloy film 8 react with each other to form the metal silicide layer 11a in the (Ni_{1-y}M_{y})₂Si phase (where 0<y<1 is satisfied) in the surface (upper layer portion) of the silicon region 31. In the present embodiment, the first heat treatment in Step S3 is performed so as not to cause the entire alloy film 8 over the silicon region 31 to react with the silicon region 31, but to leave the unreacted portion 8a of the alloy film 8 over the metal silicide layer 11a. Here, the unreacted portion 8a corresponds to the portion of the alloy film 8 located over the silicon region 31 before the first heat treatment in Step S3 which has not reacted with the silicon region 31 in the first heat treatment in Step S3.

Of the alloy film 8 located over the silicon region 31 before, the unreacted portion 8a remaining over the silicon region 31 even after the first heat treatment in Step S3 (prior to the step of removing the barrier film 9 and the unreacted alloy film 8 in Step S4) has a thickness (film thickness) tn2, and the formed metal silicide layer 11a has a thickness tn4.

For easier understanding, in FIG. 25, the alloy film 8 is divided into the unreacted portion 8a and the reacted portion 8b using the virtual line shown by the dotted line. The reacted portion 8b corresponds to the portion of the alloy film 8 located over the silicon region 31 before the first heat treatment in Step S3 which has reacted with the silicon region 31 in the first heat treatment in Step S3 to form the metal silicide layer 11a. Accordingly, the combination of the reacted portion 8b and the unreacted portion 8a corresponds to the alloy film 8 located over the silicon region 31 before the first heat treatment in Step S3. The alloy film 8 is actually single-layered, but the lower-layer portion of the alloy film 8 is the reacted portion 8b, and the upper-layer portion of the alloy film 8 is the unreacted portion 8a. The reacted portion 8b and the unreacted portion 8a substantially correspond to regions (including the lower region as the reacted portion 8b and the upper region as the unreacted portion 8a) obtained by halving the alloy film 8 into a generally laminated configuration. When the thickness of the reacted portion 8b is assumed to be tn3, the sum of the thickness tn2 of the unreacted portion 8a and the thickness tn3 of the reacted portion 8b corresponds to the thickness tn1 of the alloy film 8 (i.e., tn1=tn2+tn3).

In the present embodiment, the first heat treatment in Step S3 is performed such that the unreacted portion 8a of the alloy film 8 remains in a laminated configuration over the metal silicide layer 11a. As a result, the thickness tn3 of the reacted portion 8b of the alloy film 8 is smaller than the thickness tn1 of the alloy film 8 over the silicon region 31 prior to the first heat treatment (tn3<tn1), and the thickness tn2 of the unreacted portion 8a of the alloy film 8 remaining over the metal silicide layer 11a after the first heat treatment is larger than zero (tn2>0).

Note that, in the case of forming cobalt silicide, Si (silicon) is a diffusion species and, by the movement of Si into a Co film, cobalt silicide is formed. By contrast, in the case of using the Ni₁₋ₓMₓ alloy film as in the present embodiment, Ni (nickel) and the first metal element M are diffusion species and, by the movement of Ni (nickel) and the first metal element M toward the silicon region 31, the metal silicide 11a is formed.

Then, as shown in FIG. 27, in Step S4, the barrier film 9 and the unreacted alloy film 8 (i.e., the alloy film 8 that has not reacted with the silicon region 31 in the first heat treatment step in Step S3) are removed. At this time, the unreacted portion 8a over the metal silicide layer 11a is also removed. Thereafter, the second heat treatment in Step S5 is performed to further cause reaction between the metal silicide layer 11a in the (Ni_{1-y}M_{y})₂Si phase and the silicon region 31, thereby forming the metal silicide layer 11b in the Ni_{1-y}M_{y}Si phase in the surface (upper layer portion) of the silicon region 31, as shown in FIG. 28. The formed metal silicide layer 11b has a thickness tn5.

The present embodiment is characterized in that the first heat treatment in Step S3 is performed so as to satisfy the following two conditions (fourth and fifth conditions).

As the fourth condition, the first heat treatment in Step S3 is performed such that the unreacted portion 8a of the alloy film 8 remains over the metal silicide layer 11a (i.e., tn1>tn2>0 is satisfied).

That is, in the first heat treatment in Step S3, the entire alloy film 8 located over the silicon region 31 is not caused to react with the silicon region 31, but only a part of the portion of the alloy film 8 located over the silicon region 31 is caused to react with the silicon region 31. In other words, in the first heat treatment in Step S3, the reaction ratio between the alloy film 8 and the silicon region 31 is adjusted to be less than 100%. By doing so, even when the first heat treatment in Step S3 is performed, the upper layer portion of the alloy film 8 located over the silicon region 31 (gate electrode GE, n⁺-type semiconductor region 5b, or p⁺-type semiconductor region 6b) remains unreacted to be left as the unreacted portion 8a over the metal silicide layer 11a. As a result, when the first heat treatment in Step S3 is performed, the unreacted portion 8a of the alloy film 8 remains over the metal silicide layer 11a.

Here, the reaction ratio R1 between the alloy film 8 and the silicon region 31 corresponds to the ratio of the portion (i.e., the reacted portion 8b) of the alloy film 8 located over the silicon region 31 that has reacted with the silicon region 31 in the first heat treatment in Step S3 to form the metal silicide layer 11a. Accordingly, the reaction ratio R1 between the alloy film 8 and the silicon region 31 corresponds to the ratio of the thickness of the alloy film 8 consumed during the first heat treatment in Step S3 to form the metal film 11a, i.e., the thickness tn2 of the reacted portion 8b to the thickness tn1 of the alloy film 8 before the first heat treatment in Step S3 is performed. Therefore, the reaction ratio R1 between the alloy film 8 and the silicon region 31 can be expressed as R1=tn3/tn1, i.e., R1=(tn1−tn2)/tn1. When shown in percentage, the reaction ratio R1 can be expressed as R1=tn3×100/tn1 [%], i.e., R1=(tn1−tn2)×100/tn1 [%].

As the fifth condition, the first heat treatment in Step S3 is performed at a heat treatment temperature T₁ at which the coefficient of diffusion of the first metal element M (preferably Pt) into the silicon region 31 (gate electrode GE, n⁺-type semiconductor region 5b, or p⁺-type semiconductor region 6b) is larger than the coefficient of diffusion of nickel (Ni) into the silicon region 31 (gate electrode GE, n⁺-type semiconductor region 5b, or p⁺-type semiconductor region 6b). In other words, if a comparison is made between the respective coefficients of diffusion of nickel (Ni) and the first metal element M each contained in the alloy film 8 into the silicon region 31 (gate electrode GE, n⁺-type semiconductor region 5b, or p⁺-type semiconductor region 6b) at the heat treatment temperature T₁ in the first heat treatment in Step S3, the coefficient of diffusion of the first metal element M (preferably Pt) is larger than that of nickel (Ni). By doing so, in the first heat treatment in Step S3, the first metal element M (preferably Pt) is more likely to be diffused from the alloy film 8 into the silicon region 31 than Ni (nickel).

FIG. 29 shows the graph of the temperature dependences of the diffusion coefficients of Ni and Pt in the Si region (silicon region). As shown in the graph of FIG. 29, each of the diffusion coefficients of Ni and Pt increases as the temperature rises, but the temperature dependences of the diffusion coefficients of Ni and Pt are different. Therefore, as can be seen from the graph of FIG. 29, at a temperature higher than a temperature T₂, the diffusion coefficient of Ni in the Si region is larger than the diffusion coefficient of Pt in the Si region so that Ni is more likely to be diffused into the Si region than Pt. At the temperature T₂, the diffusion coefficient of Ni in the Si region is equal to the diffusion coefficient of Pt in the Si region so that Ni is as likely as Pt to be diffused into the Si region. At a temperature lower than the temperature T₂, the diffusion coefficient of Pt in the Si region is larger than the diffusion coefficient of Ni in the Si region so that Pt is more likely to be diffused into the Si region than Ni. The temperature T₂ is 279° C. (i.e., T₂=279° C.).

Therefore, when the foregoing first metal element M is Pt (platinum), i.e., when the alloy film 8 is the Ni—Pt alloy film (Ni₁₋ₓPtₓ alloy film), to satisfy the foregoing fifth condition, the heat treatment temperature T₁ in the first heat treatment in Step S3 is set lower than the foregoing temperature T₂ (i.e., T₁<T₂). Specifically, the heat treatment temperature T₁ in the first heat treatment in Step S3 is set less than 279° C. (i.e., T₁<279° C.). If the heat treatment temperature T₁ in the first heat treatment in Step S3 is set lower than the foregoing temperature T₂ (T₁<T₂, specifically T₁<279° C.), at the heat treatment temperature T₁ in the first heat treatment in Step 3, the coefficient of diffusion of Pt (platinum) into the silicon region 31 becomes larger than the coefficient of diffusion of nickel (Ni) into the silicon region 31. As a result, in the first heat treatment in Step S3, Pt (platinum) is more likely to be diffused from the alloy film 8 into the silicon region 31 (gate electrode GE, n⁺-type semiconductor region 5b, or p⁺-type semiconductor region 6b) than Ni (nickel).

Therefore, to satisfy the foregoing fifth condition, it is necessary to set the heat treatment temperature T₁ in the first heat treatment lower than a temperature T₃ (T₁<T₃) at which the coefficient of diffusion of nickel (Ni) into the silicon region 31 is equal to the coefficient of diffusion of the first metal element M into the silicon region 31 (T₃=T₂ is satisfied when the first metal element M is Pt).

A description will be given of an important reason that, in the first heat treatment in step S3, both of the foregoing fourth condition and the foregoing fifth condition are to be satisfied.

In the first heat treatment in Step S3, from the alloy film 8 into the silicon region 31, Ni and the first metal element M each forming the alloy film 8 are diffused to form the metal silicide layer 11a. If the first heat treatment satisfies the foregoing fifth condition, the first metal element M (preferably Pt) is more likely to be diffused into the silicon region 31 than Ni.

If the foregoing fifth condition is not satisfied, and Ni and the first metal element M are equally likely to be diffused into the silicon region 31, the ratio between the respective numbers of atoms of Ni and the first metal element M each diffused from the alloy film 8 into the silicon region 31 is maintained at the atomic ratio between Ni and the first metal element M each forming the alloy film 8, and the ratio between Ni and the first metal element M in the metal silicide layer 11a is also maintained at the atomic ratio between Ni and the first metal element M each forming the alloy film 8.

By contrast, if the first heat treatment is performed so as to satisfy the foregoing fourth condition and the foregoing fifth condition as in the present embodiment, in the first heat treatment, the first metal element M is more likely to be diffused into the silicon region 31 than Ni. Accordingly, in the ratio between the respective numbers of atoms of Ni and the first metal element M each diffused from the alloy film 8 into the silicon region 31, the ratio of the first metal element M is higher than in the atomic ratio between Ni and the first metal element M each forming the alloy film 8. Therefore, in the ratio between Ni and the first metal element M in the metal silicide layer 11a also, the ratio of the first metal element M is higher than in the atomic ratio between Ni and the first metal element M each forming the alloy film 8. That is, if it is assumed that the alloy film 8 is the Ni₁₋ₓMₓ alloy film (where 0<x<1 is satisfied) and the metal silicide layer 11a is in the (Ni_{1-y}M_{y})₂Si phase (where 0<y<1 is satisfied), x<y is satisfied.

However, even when the first heat treatment in Step S3 satisfies the foregoing fifth condition, if the foregoing fourth condition is not satisfied and the foregoing reaction ratio R1 between the alloy film 8 and the silicon region 31 is 100% unlike in the present embodiment, Ni and the first metal element M each forming the alloy film 8 over the silicon region 31 are entirely diffused into the silicon region 31 to contribute to the formation of the metal silicide layer 11a, irrespective of the difference between the diffusion coefficients. As a result, even though the first metal element M is more likely to be diffused into the silicon region 31 than Ni, the total amount of Ni and the first metal element M each forming the alloy film 8 over the silicon region 31 reacts with the silicon region 31 to form the metal silicide layer 11a. Accordingly, the ratio between Ni and the first metal element M in the metal silicide layer 11a is undesirably maintained at the ratio between Ni and the first metal element M in the alloy film 8. That is, if it is assumed that the alloy film 8 is the N₁₋ₓMₓ alloy film (where 0<x<1 is satisfied) and the metal silicide layer 11a is in the (Ni_{1-y}M_{y})₂Si phase (where 0<y<1 is satisfied), x=y is satisfied undesirably.

Also, when the first heat treatment in Step S3 satisfies the foregoing fourth condition, if the foregoing fifth condition is not satisfied and the first heat treatment in Step S3 is performed at a heat treatment temperature at which the coefficient of diffusion of Ni into the silicon region 31 is larger than the coefficient of diffusion of the first metal element M into the silicon region 31 unlike in the present embodiment, Ni is preferentially diffused into the silicon region 31 over the first metal element M. This unexpectedly reduces the ratio of the first metal element M in the metal silicide layer 11a. That is, when the metal silicide layer 11a in the (Ni_{1-y}M_{y})₂Si phase is formed using the Ni₁₋ₓMₓ alloy film as the alloy film 8, y<x is satisfied undesirably.

Therefore, by performing the first heat treatment in Step S3 so as to satisfy both of the foregoing fourth condition and the foregoing fifth condition, it is only possible to increase the ratio of the first metal element M (preferably Pt) in the metal silicide layer 11a. That is, by satisfying both of the foregoing fourth condition and the foregoing fifth condition, the ratio of the first metal element M to the metal elements (Ni and the first metal element M) forming the metal silicide layer 11a can be increased to be higher than the ratio of the first metal element M to the alloy film 8. In other words, by satisfying both of the foregoing fourth condition and the foregoing fifth condition, it is possible to satisfy x<y in forming the metal silicide layer 11a in the (Ni_{1-y}M_{y})₂Si phase using the N₁₋ₓMₓ alloy film (M is preferably Pt) as the alloy film 8. Note that, since the metal silicide layer 11a is formed by causing reaction between the alloy film 8 of Ni and the first metal element M and the silicon region 31, the metal elements forming the metal silicide layer 11a are the same as the metal elements forming the alloy film 8, which are Ni and the first metal element M.

Thereafter, by the second heat treatment in Step S5, the metal silicide layer 11a in the (Ni_{1-y}M_{y})₂Si phase is changed to the metal silicide layer 11b in the Ni_{1-y}M_{y}Si phase. However, since the alloy film 8 has been removed before the second heat treatment in Step S5, the ratio between Ni and the first metal element M (i.e., 1−y:y) is maintained at the same value in each of the metal silicide layer 11a in the (Ni_{1-y}M_{y})₂Si phase and the metal silicide layer 11b in the Ni_{1-y}M_{y}Si phase. That is, y in (Ni_{1-y}M_{y})₂Si forming the metal silicide layer 11a has the same value as that of y in Ni_{1-y}M_{y}Si forming the metal silicide layer 11b.

As described above, in the present embodiment, the metal silicide layer 11b contains the first metal element M (particularly preferably Pt) (i.e., the foregoing first condition is satisfied), and the effect achieved thereby (e.g., the effect of suppressing the abnormal growth of the NiSi₂ phase) increases as the concentration of the first metal element M (particularly preferably Pt) in the metal silicide layer 11b increases. Therefore, it is desired to increase the concentration of the first metal element M (particularly preferably Pt) in the metal silicide layer 11b, and improve the performance of the semiconductor device.

However, in the case of depositing the Ni₁₋ₓ-Mₓ alloy film over the semiconductor substrate, due to the different sputtering angles of Ni and the first metal element, if the concentration of the first metal element M in the Ni₁₋ₓMₓ alloy film is to be increased, the Ni₁₋ₓMₓ alloy film may be non-uniformly deposited over the semiconductor substrate. This phenomenon is particularly pronounced when the first metal element M is Pt. Accordingly, for uniform deposition of the N₁₋ₓMₓ alloy film over the semiconductor substrate, a honeycomb collimator or the like is used to increase the concentration (i.e., x in Ni₁₋ₓMₓ) of the first metal element M in the Ni₁₋ₓMₓ alloy film. However, even when the honeycomb collimator or the like is used to adjust the sputtering angle of the foregoing first metal element M, the Ni₁₋ₓMₓ alloy film is deposited in a large quantity over the collimator, and there is a limit to uniform deposition of the N₁₋ₓMₓ alloy film containing the first metal element M at an increased concentration.

In the present embodiment, by performing the first heat treatment in Step S3 so as to satisfy the foregoing fourth and fifth embodiment, the ratio of the first metal element M (i.e., y when the phase of the metal silicide layer 11a is expressed as (Ni_{1-y}M_{y})₂Si) to the metal elements forming the metal silicide layer 11a can be increased to be higher than the ratio (i.e., x when the alloy film 8 is expressed as the Ni₁₋ₓMₓ alloy film) of the first metal element M to the alloy film 8 (i.e., y>x). In addition, the ratio of the first metal element M (i.e., y when the phase of the metal silicide layer 11b is expressed as Ni_{1-y}M_{y}Si) to the metal elements forming the metal silicide layer 11b can be increased to be higher than the ratio of the first metal element M (i.e., x when the alloy film 8 is expressed as the N₁₋ₓMₓ alloy film) of the first metal element M to the alloy film 8 (i.e., to satisfy y>x). In this manner, it is possible to suppress agglomeration in the metal silicide layers 11a and 11b, suppress the abnormal growth of the high-resistance Ni_{1-y}M_{y}Si₂ phase in the metal silicide layer 11b, and further improve the reliability of the semiconductor device.

FIG. 30 is a graph showing the resistivity (specific resistance) of the metal silicide layer 11b when the metal silicide layer 11b is formed using a Ni_{0.963}Pt_{0.037} alloy film as the alloy film 8. The ordinate axis of the graph of FIG. 30 corresponds to the resistivity (specific resistance) of the metal silicide layer 11b, while the abscissa axis of the graph of FIG. 30 corresponds to an alloy film consumption ratio R2 in the first heat treatment. In the graph of FIG. 30, the respective resistivities when the heat treatment temperature T₁ in the first heat treatment is 250° C., 260° C., and 270° C. are plotted in mixed relation.

Here, the alloy film consumption ratio R2 in the first heat treatment corresponds to a value obtained by dividing a thickness tn6 of the alloy film 8 which can be consumed (caused to react with the silicon region 31) by the first heat treatment by the thickness tn1 of the alloy film 8 prior to the first heat treatment (i.e., R2=tn6/tn1). Note that the thickness tn6 of the alloy film 8 which can be consumed (caused to react with the silicon region 31) by the first heat treatment corresponds to the thickness (i.e., the thickness tn3 of the foregoing reacted portion 8b) of the portion caused to react with the silicon region 31 by the first heat treatment when the thickness tn1 of the alloy film 8 is sufficiently increased (increased to be larger than the thickness tn6). Accordingly, when the alloy film consumption ratio R2 in the first heat treatment is not more than 100%, the thickness tn6 of the alloy film 8 which can be consumed (caused to react with the silicon region 31) by the first heat treatment is equal to the thickness tn3 of the reacted portion 8b of the alloy film 8 in the first heat treatment (i.e., tn6=tn3). Therefore, when the alloy film consumption ratio R2 in the first heat treatment is not more than 100% (R2≦100%), the alloy film consumption ratio R2 in the first heat treatment is equal to the foregoing reaction ratio R1 (R2=R1). On the other hand, when the alloy film consumption ratio R2 in the first heat treatment exceeds 100%, the thickness till of the alloy film 8 is smaller than the thickness tn6 of the alloy film 8 which can be consumed by the first heat treatment (tn1<tn6) so that the thickness tn3 of the reacted portion 8b of the alloy film 8 in the first heat treatment is equal to the thickness tn1 of the alloy film 8 (tn3=tn1<tn6). Therefore, when the alloy film consumption ratio R2 in the first heat treatment is not less than 100% (R2≧100%), the foregoing reaction ratio R1 is constantly 100% (R1=100%) so that the alloy film consumption ratio R2 and the reaction ratio R1 have different values.

For example, when the alloy film 8 having the thickness tn1 of 20 nm is formed and the first heat treatment is performed, if the thickness tn3 of the reacted portion 8b of the alloy film 8 is 10 nm, tn6=tn3=10 nm and tn1=20 nm are satisfied so that each of the alloy film consumption ratio R2 in the first heat treatment and the foregoing reaction ratio R1 is 50%. Also, for example, when the alloy film 8 having the thickness tn1 of 10 nm is formed and the first heat treatment is performed under the same heat treatment conditions as those used when the alloy film 8 having the thickness tn1 of 40 nm is formed, the first heat treatment is performed, and the thickness tn3 of the reacted portion 8b of the alloy film 8 is 20 nm, tn6=20 nm and tn1=10 nm are satisfied so that the alloy film consumption ratio R2 in the first heat treatment is 200% and the foregoing reaction ratio R1 in the first heat treatment is 100%. Here, the same heat treatment conditions include at least the same heat treatment temperature and the same heat treatment period.

In the graph of FIG. 30, the resistivities obtained by varying the heat treatment temperature in the first heat treatment are plotted in mixed relation, but the first heat treatment is performed so as to constantly satisfy the foregoing fifth condition. However, when the alloy film consumption ratio R2 in the first heat treatment is less than 100%, the foregoing fourth condition is satisfied while, when the alloy film consumption ratio R2 in the first heat treatment is not less than 100%, the foregoing fourth condition is not satisfied. This is because, when the alloy film consumption ratio R2 in the first heat treatment is not less than 100%, the entire alloy film 8 over the silicon region 31 reacts with the silicon region 31 (i.e., the foregoing reaction ratio R1 is 100%) while, when the alloy film consumption ratio R2 in the first heat treatment is less than 100%, only the lower region of the alloy film 8 over the silicon region 31 reacts with the silicon region 31 (i.e., the foregoing reaction ratio R1 is less than 100%).

From the graph of FIG. 30, the following can be seen. When the alloy film consumption ratio R2 in the first heat treatment exceeds 150%, the resistivity (specific resistance) of the metal silicide layer 11b significantly increases. This is conceivably because, in the metal silicide layer 11b, agglomeration occurs to result in a partially disconnected state. On the other hand, when the alloy film consumption ratio R2 in the first heat treatment is in the range of 80% to 150%, the resistivity (specific resistance) of the metal silicide layer 11b is on the level of the resistivity of the NiSi₂ phase. However, when the alloy film consumption ratio R2 in the first heat treatment is not more than 80%, the resistivity (specific resistance) of the metal silicide layer 11b has been reduced to the level of the resistivity of the NiSi phase. Here, the NiSi phase has the resistivity lower than that of the NiSi₂ phase. The reason for the resistivity of the metal silicide layer 11b that has been reduced by setting the alloy film consumption ratio R2 in the first heat treatment to 80% or less is conceivably because, by setting the alloy film consumption ratio R2 in the first heat treatment to 80% or less, the production of Ni_{1-y}Pt_{y}Si₂ could be suppressed in the metal silicide layer 11b.

Therefore, by performing the first heat treatment in Step S3 so as to satisfy the foregoing fourth condition and the foregoing fifth condition as in the present embodiment, more preferably by setting the alloy film consumption ratio R2 in the first heat treatment in Step S3 to 80% or less, it is possible to increase the ratio of the first metal element M (preferably Pt) to the formed metal silicide layer 11b, and further reduce the resistance of the metal silicide layer 11b.

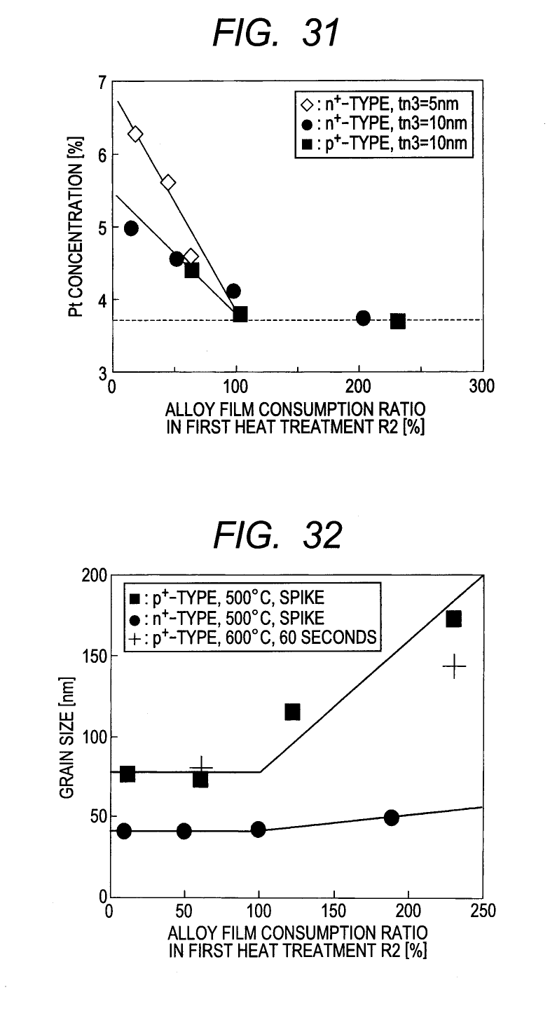

Next, assuming the case where a semiconductor region (impurity diffusion layer) corresponding to the silicon region 31 was formed in the main surface of the semiconductor substrate, the Ni_{0.963}Pt_{0.037} alloy film corresponding to the alloy film 8 was formed thereover, and then a heat treatment corresponding to the first heat treatment and the second heat treatment was performed to form a Ni_{1-y}Pt_{y}Pt_{y}Si layer corresponding to the metal silicide layer 11b, various samples were produced, and the graphs of FIGS. 31, 32, and 33 were obtained.

Among them, FIG. 31 is the graph showing a correlation between “Alloy Film Consumption Ratio R2 in First Heat Treatment” and “Pt Concentration in Formed Ni_{1-y}Pt_{y}Si Layer”. In the graph of FIG. 31, the “Alloy Film Consumption Ratio R2 in First Heat Treatment” was plotted on the abscissa axis, while the “Pt Concentration” was plotted on the ordinate axis. Note that the plots in the graph of FIG. 31 show the cases where the semiconductor region (impurity diffusion layer) corresponding to the silicon region 31 was formed of an n⁺-type semiconductor region and the foregoing thickness tn3 (which is the thickness of the portion of the Ni_{0.963}Pt_{0.037} alloy film that reacted with the silicon region in the first heat treatment to form the metal silicide layer herein) was set to 10 nm (indicated by the solid circle marks () in the graph of FIGS. 31) and to 5 nm (indicated by the hollow diamond-shape marks (⋄) in the graph of FIG. 31). The plots in the graph of FIG. 31 also show the case where the semiconductor region (impurity diffusion layer) corresponding to the silicon region 31 was formed of a p⁺-type semiconductor region and the foregoing thickness tn3 (which is the thickness of the portion of the Ni_{0.963}Pt_{0.037} alloy film that reacted with the silicon region in the first heat treatment to form the metal silicide layer herein) was set to 10 nm (indicated by the solid square marks (▪) in the graph of FIG. 31). Here, in the graph of FIG. 31, the ratio of Pt to the metal elements forming the Ni_{1-y}Pt_{y}Si layer (corresponding to the metal silicide layer 11b) formed by the first and second heat treatments is plotted as the “Pt Concentration”, which corresponds to a value obtained by 100-fold increasing y in Ni_{1-y}Pt_{y}Si (100-fold increased for % representation). The “Pt Concentration” can be measured by ICP-AES (Inductively Coupled Plasma-Atomic Emission Spectrometry) or the like.

As can also be seen from the graph of FIG. 31, when the alloy film consumption ratio R2 in the first heat treatment is not less than 100%, the Pt concentration (value obtained by 100-fold increasing y in Ni_{1-y}Pt_{y}Si for % representation) in the formed Ni_{1-y}Pt_{y}Si layer is substantially equal to the Pt concentration (i.e., 3.7% indicated by the dotted line in the graph of FIG. 31) in the Ni_{0.963}Pt_{0.037} alloy film formed as the alloy film 8. By contrast, when the alloy film consumption ratio R2 in the first heat treatment is less than 100%, the Pt concentration (value obtained by 100-fold increasing y in Ni_{1-y}Pt_{y}Si for % representation) in the formed Ni_{1-y}Pt_{y}Si layer is higher than the Pt concentration (i.e., 3.7%) in the Ni_{0.963}Pt_{0.037} alloy film formed as the alloy film 8. It can be seen that, when the alloy film consumption ratio R2 in the first heat treatment is less than 100%, the Pt concentration in the formed Ni_{1-y}Pt_{y}Si layer increases as the alloy film consumption ratio R2 in the first heat treatment decreases. When the alloy film consumption ratio R2 in the first heat treatment is less than 100%, the first heat treatment satisfies both of the foregoing fourth condition and the foregoing fifth condition, and therefore it can be considered that the Pt concentration in the formed Ni_{1-y}Pt_{y}Si layer becomes higher than the Pt concentration (i.e., 3.7%) in the Ni_{0.963}Pt_{0.037} alloy film formed as the alloy film 8.

Therefore, by performing the first heat treatment in Step S3 so as to satisfy the foregoing fourth condition and the foregoing fifth condition as in the present embodiment, or more preferably setting the alloy film consumption ratio R2 in the first heat treatment in Step S3 to 80% or less, it is possible to set the ratio of the first metal element M (preferably Pt) to the metal elements forming the metal silicide layer 11b higher than the ratio of the first metal element M (preferably Pt) to the alloy film 8.

FIG. 32 is the graph showing a correlation between “Alloy Film Consumption Ratio R2 in First Heat Treatment” and “Grain Size in Formed Ni_{1-y}Pt_{y}Si Layer”. In the graph of FIG. 32, the “Alloy Film Consumption Ratio R2 in First Heat Treatment” was plotted on the abscissa axis, while the “Grain Size” was plotted on the ordinate axis. Note that the plots in the graph of FIG. 32 show the case where the semiconductor region (impurity diffusion layer) corresponding to the silicon region 31 was formed of the n⁺-type semiconductor region and spike anneal at 500° C. was performed as the second heat treatment (indicated by the solid circle marks () in the graph of FIG. 32) and the case where the semiconductor region corresponding to the silicon region 31 was formed of the p⁺-type semiconductor region and spike anneal at 500° C. was performed as the second heat treatment (indicated by the solid square marks (▪) in the graph of FIG. 32). The plots in the graph of FIG. 32 also show the case where the semiconductor region (impurity diffusion layer) corresponding to the silicon region 31 was formed of the p⁺-type semiconductor region and 60-second anneal at 600° C. was performed as the second heat treatment (indicated by the cross-shaped marks (+) in the graph of FIG. 32). The grain size shown herein corresponds to the foregoing grain size G1.

As can also be seen from the graph of FIG. 32, when the alloy film consumption ratio R2 in the first heat treatment is not less than 100%, by an excess heat treatment after the Ni_{0.963}Pt_{0.037} alloy film is entirely consumed in the first heat treatment, the crystal grain of the metal silicide grows to have a large grain size. By contrast, when the alloy film consumption ratio R2 in the first heat treatment is less than 100% (i.e., when the foregoing second condition is satisfied), there is no such excess heat treatment so that the growth of the crystal grain of the metal silicide is suppressed, and the crystal grain size in the metal silicide layer has a substantially constant value. Therefore, by performing the first heat treatment in Step S3 so as to satisfy the foregoing fourth condition as in the present embodiment, it is possible to suppress or prevent the crystal grain in the metal silicide layer 11a from growing to have a large grain size in the first heat treatment, and consequently reduce the grain size (corresponding to the foregoing grain size G1) in the formed metal silicide layer 11b.

As described above, to satisfy the foregoing second condition and the foregoing third condition, the grain size in the metal silicide layer 11b needs to be reduced (G<W1 and G<W1c). Therefore, it is desired to provide a manufacturing technique which allows a grain size reduction in the formed metal silicide layer 11b. If the first heat treatment in Step S3 is performed so as to satisfy the foregoing fourth condition, it is possible to reduce the grain size (corresponding to the foregoing grain size G1) in the metal silicide layer 11b, and therefore reliably form the metal silicide layer 11b that satisfies the foregoing second condition and the foregoing third condition. Hence, it can be said that, to form the metal silicide layer 11b that satisfies the foregoing second condition and the foregoing third condition, it is effective to perform the first heat treatment in Step S3 so as to satisfy the foregoing fourth condition.

As can also be seen from the graph of FIG. 31 described above, when the alloy film consumption ratio R2 in the first heat treatment is not less than 100% (R2≧100%) (i.e., when the foregoing reaction ratio R1=100%), the Pt concentration (value obtained by 100-fold increasing y in Ni_{1-y}Pt_{y}Si) in the formed Ni_{1-y}M_{y}Si layer (corresponding to the metal silicide layer 111b) becomes substantially equal to the Pt concentration (i.e., 3.7%) in the Ni_{0.963}Pt_{0.037} alloy film formed as the alloy film 8. When the alloy film consumption ratio R2 in the first heat treatment is less than 100% (R2<100%), the Pt concentration in the formed Ni_{1-y}M_{y}Si layer increases as the alloy film consumption ratio R2 in the first heat treatment decreases.

Here, a surplus alloy film ratio R3 is defined as a value obtained by dividing the thickness tn2 of the unreacted portion 8a of the alloy film 8 when the first heat treatment is performed by the thickness tn3 of the reacted portion 8b of the alloy film 8 (i.e., R3=tn2/tn3). In this case, the surplus alloy film ratio R3 can also be expressed as R3=(1/R1)−1 derived from R1=tn3/tn1, R3=tn2/tn3, and tn1=tn2+tn3.

The case where the surplus alloy film ratio R3 is zero (where R3=0 is satisfied) corresponds to the case where the foregoing R1=100% or where the foregoing R2≧100% (i.e., where the entire alloy film 8 over the silicon region 31 reacts with the silicon region 31 in the first heat treatment to form the metal silicide layer 11a). Accordingly, the region where R2 on the abscissa axis in FIG. 31 is not less than 100% corresponds to the region where the surplus alloy film ratio R3 is zero and, in the region where R2 on the abscissa axis in FIG. 31 is not more than 100%, the surplus alloy film ratio R3 (i.e., tn2/tn3) decreases as R2 decreases. As a result, when the surplus alloy film ratio R3 is zero (R3=0) (i.e., when the foregoing reaction ratio R1=100% or when the foregoing alloy film consumption ratio R2≧100%), the Pt concentration (value obtained by 100-fold increasing y in Ni_{1-y}Pt_{y}Si) in the formed Ni_{1-y}Pt_{y}Si layer (corresponding to the metal silicide layer 11b) becomes substantially equal to the Pt concentration (i.e., 3.7%) in the Ni_{0.963}Pt_{0.037} alloy film formed as the alloy film 8. It can be said that, as the surplus alloy film ratio R3 increases, the Pt concentration in the formed Ni_{1-y}Pt_{y}Si layer increases.

Therefore, as the foregoing reaction ratio R1 decreases, i.e., as the foregoing alloy film consumption ratio R2 decreases in the region where R2 is not more than 100% or, in other words, as the foregoing surplus alloy film ratio R3 increases, the Pt concentration in the formed Ni_{1-y}Pt_{y}Si layer (corresponding to the metal silicide layer 11b) increases. A conceivable reason for this is as follows.

A case is assumed where the Ni_{0.963}Pt_{0.037} alloy film is used as the alloy film 8. When the foregoing reaction ratio R1=100% is satisfied (i.e., R2≧100% or R3=0), the entire alloy film 8 reacts with the silicon region 31 so that the Pt concentration in the alloy film 8 and the Pt concentration in the metal silicide layer 11a have the same value of 3.7%. Here, the Pt concentration in the metal silicide layer 11a is the ratio of Pt to the metal elements forming the metal silicide layer 11a, and corresponds to the value of y (in the case of percentage representation, a value obtained by 100-fold increasing y) when the phase of the metal silicide layer 11a is expressed as (Ni_{1-y}Pt_{y})₂Si.

On the other hand, when the foregoing reaction ratio R1<100% is satisfied (i.e., R2<100% or R3>0), the unreacted portion 8a of the alloy film 8 remains over the metal silicide layer 11a after the first heat treatment. However, by the satisfaction of the foregoing first condition by the first heat treatment, Pt is diffused preferentially over Ni from the alloy film 8 into the silicon region 31 during the first heat treatment. As a result, the Pt concentration in the unreacted portion 8a of the alloy film 8 decreases from the value (3.7%) at the time of film deposition, and accordingly the Pt concentration in the metal silicide layer 11a increases. This is because a Pt decrement in the unreacted portion 8a of the alloy film 8 results in a Pt increment in the metal silicide layer 11a. In this case, if the thickness of the reacted portion 8b of the alloy film 8 is the same, as the thickness of the unreacted portion 8a of the alloy film 8 is larger, the Pt decrement in the entire unreacted portion 8a increases, and accordingly an increase in Pt concentration in the metal silicide layer 11a increases. As a result, if the thickness of the reacted portion 8b of the alloy film 8 is the same, as the thickness of the unreacted portion 8a of the alloy film 8 is larger (i.e., as the foregoing surplus alloy film ratio R3 in the first heat treatment is higher), the Pt concentration in the metal silicide layer 11a increases. Since the Pt concentration in the metal silicide layer 11b after the second heat treatment is equal to the Pt concentration in the metal silicide layer 11a, the Pt concentration in the metal silicide layer 11b also increases.

Accordingly, as the foregoing surplus alloy film ratio R3 in the first heat treatment is increased (i.e., as the foregoing reaction ratio R1 is reduced), the ratio (y when the phase of the metal silicide layer 11b is expressed as Ni_{1-y}M_{y}Si) of the first metal element M to the metal elements (including Ni and the first metal element M) forming the metal silicide layer 11b can be increased. Therefore, to increase the ratio of the first metal element M to the metal elements forming the metal silicide layer 11b, it is preferable not only to perform the first heat treatment in Step S3 so as to satisfy the fourth and fifth conditions, but also to control the foregoing surplus alloy film ratio R3 (or the foregoing reaction ratio R1) in the first heat treatment.

That is, in the present embodiment, the first heat treatment in Step S3 is performed so as to satisfy the foregoing fourth and fifth conditions. As a result, the foregoing surplus alloy film ratio R3 in the first heat treatment is higher than zero (R3>0), and each of the foregoing reaction ratio R1 and the foregoing alloy film consumption ratio R2 is less than 100% (R1<100% and R2<100%). This allows the ratio (y when the phase of the metal silicide layer 11b is expressed as Ni_{1-y}M_{y}Si) of the first metal element M to the metals (including Ni and the first metal element M) forming the metal silicide layer 11b to be increased to be higher than the ratio (x when the alloy film 8 is expressed as the Ni₁₋ₓMₓ alloy film) of the first metal element M to the alloy film 8 (to satisfy y>x).

Also in the present embodiment, the first heat treatment in Step S3 is preferably performed such that the foregoing surplus alloy film ratio R3 in the first heat treatment is not less than 0.25 (R3≧0.25) (i.e., each of the foregoing reaction ratio R1 and the foregoing alloy film consumption ratio R2 is not more than 80%). More preferably, the first heat treatment in Step S3 is performed such that the foregoing surplus alloy film ratio R3 in the first heat treatment is not less than 1 (R3≧1) (i.e., each of the foregoing reaction ratio R1 and the foregoing alloy film consumption ratio R2 is not more than 50%). This allows the ratio (y when the phase of the metal silicide layer 11b is expressed as Ni_{1-y}M_{y}Si) of the first metal element M to the metal elements forming the metal silicide layer 11b to be reliably increased.

Note that the foregoing surplus alloy film ratio R3 in the first heat treatment which is not less than 0.25 (R3≧0.25) means that, in terms of the relationship given by R3=tn2/tn3, the thickness tn2 of the unreacted portion 8a of the alloy film 8 when the first heat treatment is performed is not less than 0.25 times the thickness tn3 of the reacted portion 8b of the alloy film 8 (i.e., tn2≧tn3×0.25). In this case, the thickness tn1 of the alloy film 8 is not less than 1.25 times the thickness tn3 of the reacted portion 8b of the alloy film 8 (i.e., tn1=tn2+tn3≧tn3×1.25). Also note that the foregoing surplus alloy film ratio R3 in the first heat treatment which is not less than 1 (R3≧1) means that, in terms of the relationship given by R3=tn2/tn3, the thickness tn2 of the unreacted portion 8a of the alloy film 8 when the first heat treatment is performed is not less than the thickness tn3 of the reacted portion 8b of the alloy film 8 (i.e., tn2≧tn3). In this case, the thickness tn1 of the alloy film 8 is not less than double the thickness tn3 of the reacted portion 8b of the alloy film 8 (i.e., tn1=tn2+tn3≧tn3×2).

Therefore, in the present embodiment, it is preferable that not only the foregoing fourth and fifth conditions are satisfied, but also the thickness tn1 of the alloy film 8 is preferably not less than 1.25 times the thickness tn3 of the reacted portion 8b of the alloy film 8 (i.e., tn1≧tn3×1.25), and more preferably not less than double the thickness tn3 of the reacted portion 8b of the alloy film 8 (i.e., tn1 tn3×2). This allows the ratio of the first metal element M to the metal elements forming the metal silicide layer 11b to be reliably increased.

For example, as can also be seen from the graph of FIG. 31, when the Ni_{0.963}Pt_{0.037} alloy film is used as the alloy film 8, by performing the first heat treatment in Step S3 such that the foregoing alloy film consumption ratio R2 in the first heat treatment is less than 80% (i.e., the foregoing reaction ratio R1 is less than 80%, and the foregoing surplus alloy film ratio R3 is not less than 0.25), the Pt concentration in the metal silicide layer 11b can be adjusted to be not less than 4%. In other words, when the phase of the metal silicide layer 11b is expressed as Ni_{1-y}M_{y}Si, y 0.04 can be satisfied.

When the thickness tn5 of the formed metal silicide layer 11b is excessively small, the resistance of the metal silicide layer 11b increases. Accordingly, the thickness tn3 of the reacted portion 8b of the alloy film 8 when the first heat treatment has been performed is preferably not less than 5 nm (tn3≧5 nm), and more preferably not less than 7 nm (tn3≧7 nm). As a result, it is possible to ensure the thickness tn5 of the formed metal silicide layer 11b, and thereby sufficiently benefit from the effect achieved by forming the low-resistivity metal silicide layers 11b over the source/drain and the gate electrode.

If the thickness tn3 of the reacted portion 8b of the alloy film 3 when the first heat treatment is performed is the same, as the thickness tn2 of the unreacted portion 8a of the alloy film 8 is increased, the ratio (y when the phase of the metal silicide layer 11b is expressed as (Ni_{1-y}M_{y})Si) of the first metal element M to the metals forming the metal silicide layer 11b can be increased. However, if the thickness tn2; of the unreacted portion 8a of the alloy film 8 is excessively increased, the thickness tn1 of the alloy film is excessively increased to undesirably increase a time required for depositing the alloy film 8 in Step S1, and also increase the manufacturing cost of the semiconductor device. Since Pt (platinum) is particularly costly, when the alloy film 8 is the Ni—Pt alloy film, if the thickness tn2 of the unreacted portion 8a of the alloy film 8 is excessively increased, the manufacturing cost tends to increase. Accordingly, the thickness tn2 of the unreacted portion 8a of the alloy film 8 when the first heat treatment is performed is preferably not more than 200 nm (tn2≦200 nm), or more preferably not more than 100 nm (tn2≦100 nm). As a result, it is possible to control the time required for depositing the alloy film 8, and control the manufacturing cost of the semiconductor device.

Also, as described above, when the foregoing first metal element M (particularly preferably Pt) is added into the metal silicide layers 11a and 11b, such advantages are obtainable that the formed metal silicide layers 11a and 11b have small agglomeration, and the abnormal growth of the high-resistance (Ni_{1-y}M_{y})Si₂ phase in the metal silicide layers 11a and 11b can be suppressed. Therefore, it is effective to perform the first heat treatment in step S3 such that the ratio (the value of y when the respective phases of the metal silicide layers 11a and 11b are expressed as (Ni_{1-y}M_{y})₂Si and Ni_{1-y}M_{y}Si or, in percentage representation, a value obtained by 100-fold increasing the value of y) of the first metal element M to the metal elements forming the metal silicide layers 11a and 11b is preferably not less than 4% (y 0.04), and more preferably not less than 5% (y≧0.05). This allows the foregoing advantages to be more reliably obtained.

In the present embodiment, to form the metal silicide layer 11b thus containing the first metal element M at a high concentration, the alloy film 8 in which the content of the first metal element M is less than 4% (4 at %) (i.e., x≦0.04 is satisfied when the alloy film 8 is expressed as the Ni_{1-y}M_{y} alloy film). Therefore, if the present embodiment is applied to the case where the alloy film in which the content of the first metal element M is less than 4% (4 at %) is used as the alloy film 8, the effect thereof is significantly large. Note that the content of the first metal element M in the alloy film 8 is synonymous to the ratio of the first metal element M to the alloy film 8.

If the heat treatment period of the first heat treatment is the same, as the heat treatment temperature is increased, the thickness tn3 of the reacted portion 8b of the alloy film 8 increases while, as the heat treatment temperature is reduced, the thickness tn3 of the reacted portion 8b of the alloy film 8 decreases. On the other hand, if the heat treatment temperature in the first heat treatment is the same, as the heat treatment period is increased, the thickness tn3 of the reacted portion 8b of the alloy film 8 increases while, as the heat treatment period is reduced, the thickness tn3 of the reacted portion 8b of the alloy film 8 decreases. Therefore, by adjusting the heat treatment temperature and the heat treatment period of the first heat treatment, the thickness tn3 of the reacted portion 8b of the alloy film 8 can be controlled. The thickness tn2 of the unreacted portion 8a of the alloy film 8 has a value obtained by subtracting the thickness tn3 of the reacted portion 8b of the alloy film 8 from the thickness tn1 of the alloy film 8 at the time of film deposition (i.e. tn2=tn1−tn3). Therefore, by adjusting the thickness tn1 of the alloy film 8 at the time of film deposition and the heat treatment temperature and the heat treatment period of the first heat treatment, it is possible to control the foregoing reaction ratio R1, the foregoing alloy film consumption ratio R2, and the foregoing surplus alloy film ratio R3 in the first heat treatment.

However, if the heat treatment temperature T₁ in the first heat treatment in Step S3 is excessively low, the time required for the first heat treatment increases to increase the manufacturing period of the semiconductor device, and reduce the throughput of the semiconductor device. Therefore, in the present embodiment, it is more preferable to satisfy the foregoing fourth condition and the foregoing fifth condition, and further set the heat treatment temperature T₁ in the first heat treatment in Step S3 to 200° C. or more (T₁≧200° C.). As a result, it is possible to control the time required for the first heat treatment in Step S3, control the manufacturing period of the semiconductor device, and prevent a reduction in the throughput of the semiconductor device.

In addition, as described above, the heat treatment temperature T₁ in the first heat treatment is set lower than the temperature T₃ at which the coefficient of diffusion of Ni into the silicon region 31 is equal to the coefficient of diffusion of the first metal element M into the silicon region 31 (T₁<T₃) (when the first metal element M is Pt, T₃=T₂). As a result, during the first heat treatment, the first metal element M is diffused preferentially over Ni from the alloy film 8 into the silicon region 31. However, to cause the first metal element M to be diffused as preferentially as possible over Ni from the alloy film 8 into the silicon region 31 during the first heat treatment, it is more preferable to ensure the difference of a given magnitude between the foregoing temperature T₃ (when the first metal element M is Pt, T₃=T₂) and the treatment temperature T₁ in the first heat treatment in Step S3. For this purpose, the treatment temperature T₁ in the first heat treatment in Step S3 is preferably set lower than the foregoing temperature T₃ by 5° C. or more (T₁≦T₃−5° C.). More preferably, the treatment temperature T₁ in the first heat treatment in Step S3 is set lower than the foregoing temperature T₃ by 9° C. or more (T₁≧T₃−9° C.). When the alloy film 8 is the Ni—Pt alloy film, the treatment temperature T₁ in the first heat treatment in Step S3 is preferably set lower than the foregoing temperature T₂ by 5° C. or more (T₁≦T₂−5° C.) and, more preferably, the treatment temperature T₁ in the first heat treatment in Step S3 is set lower than the foregoing temperature T₂ by 9° C. or more (T₁≦T₂−9° C.). In this manner, in the first heat treatment, the first metal element M can be diffused preferentially over Ni from the alloy film 8 into the silicon region 31.

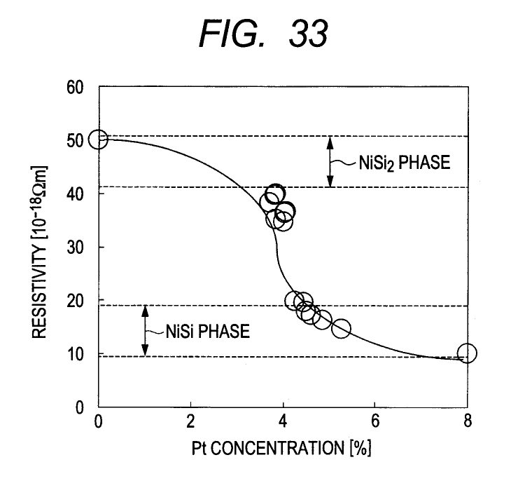

FIG. 33 is a graph showing a correlation between “Pt Concentration in Formed Ni_{1-y}Pt_{y}Si Layer” and “Resistivity of Formed Ni_{1-y}Pt_{y}Si Layer”. In the graph of FIG. 33, the “Pt Concentration” is plotted on the abscissa axis, while the “Resistivity” is plotted on the ordinate axis. The “Pt Concentration” on the abscissa axis of the graph of FIG. 33 corresponds to the “Pt Concentration” on the ordinate axis of the graph of FIG. 31

As can also be seen from FIG. 33, by increasing the Pt concentration in the formed Ni_{1-y}Pt_{y}Si layer, the resistivity can be reduced and, by increasing the Pt concentration to 4% or more, the resistivity (specific resistance) can be reduced to the low level of the resistivity of the NiSi phase. This is conceivably because, by increasing the Pt concentration in the formed Ni_{1-y}Pt_{y}Si layer to 4% or more, the generation of the high-resistivity Ni_{1-y}Pt_{y}Si₂ could be suppressed in the Ni_{1-y}Pt_{y}Si layer.

Therefore, as described above, it is preferable to set the ratio (the value of y when the respective phases of the metal silicide layers 11a and 11b are expressed as (Ni_{1-y}M_{y})₂Si and Ni_{1-y}M_{y}Si or, in percentage representation, a value obtained by 100-fold increasing the value of y) of the first metal element M to the metal elements forming the metal silicide layers 11a and 11b to 4% or more (y≧0.04 or an average in-layer concentration of 4% or more). This allows the generation of Ni_{1-y}M_{y}Si₂ in the metal silicide layer 11b to be suppressed, and thereby allows the resistivity of the metal silicide layer 11b to be reduced. In addition, by allowing the generation of Ni_{1-y}M_{y}Si₂ to be suppressed, it is possible to suppress the abnormal growth of Ni_{1-y}M_{y}Si₂ from the metal silicide layer 11b toward the channel portion, and therefore suppress or prevent an increase in leakage current (the occurrence of the leakage current defect).

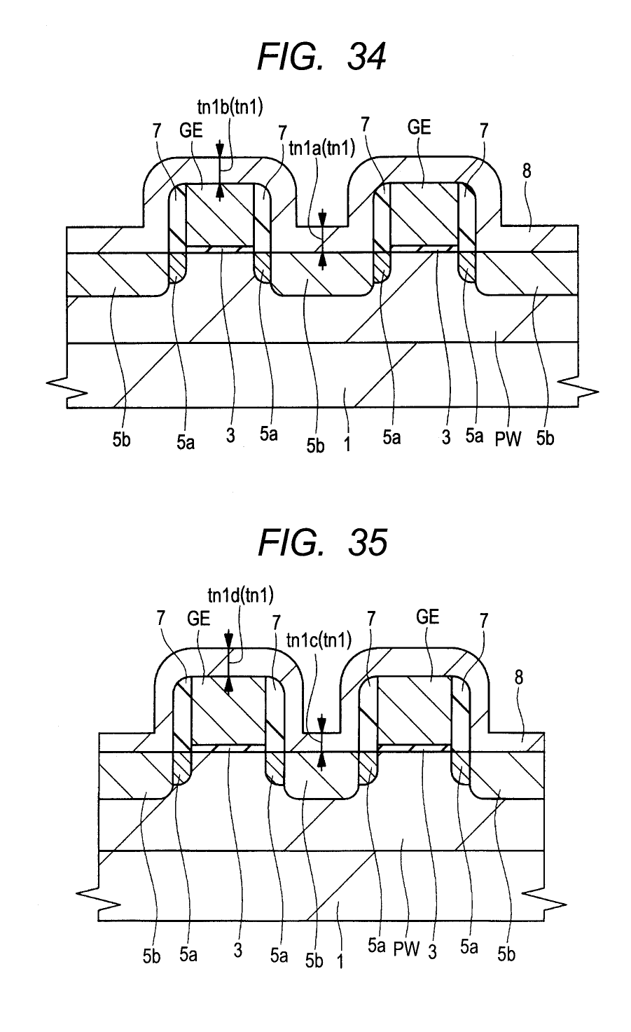

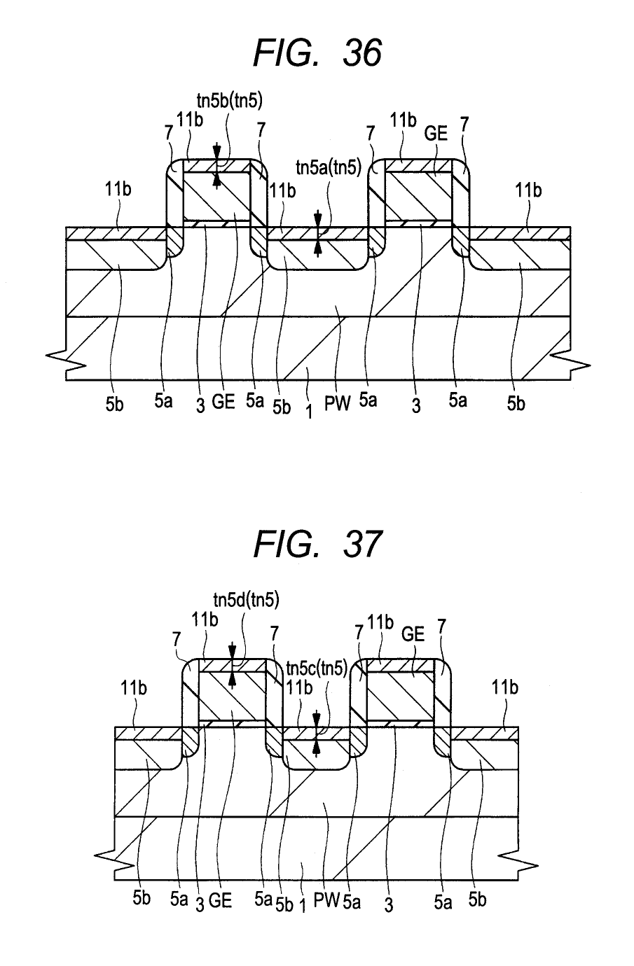

Moreover, by performing the first heat treatment in Step S3 so as to satisfy the foregoing fourth condition, the following effect, which will be described with reference to FIGS. 34 to 37, can also be obtained. FIGS. 34 and 35 are main-portion cross-sectional views each showing the stage at which the alloy film 8 has been formed in Step S1. FIGS. 36 and 37 are main-portion cross-sectional views each showing the stage at which the metal silicide layers 11b have been formed in Step S5. FIGS. 34 and 35 show the different cross-sectional regions of the same semiconductor substrate 1 at different process stages, of which FIG. 34 shows the cross-sectional region corresponding to FIG. 21(a) described above, and FIG. 35 shows the cross-sectional region corresponding to FIG. 21(c) described above. FIG. 36 shows the same cross-sectional region as shown in FIG. 34 at a different process stage. FIG. 37 shows the same cross-sectional region as shown in FIG. 35 at a different process stage. Accordingly, FIG. 36 corresponds to FIG. 22(a) described above, and FIG. 37 corresponds to FIG. 22(c) described above.

The formed film thickness (corresponding to the foregoing thickness tn1) of the alloy film 8, which is a nickel alloy film, has dependence on an underlying pattern. Compared with a wide-pitch pattern having a wide spacing between adjacent patterns, a narrow-pitch pattern having a narrow spacing between adjacent patterns results in poor coverage with the alloy film 8, and the alloy film 8 is deposited thin.

That is, as shown in FIG. 34, in the region where the gate electrodes GE are adjacent to each other with a relatively wide spacing therebetween, the thickness (formed film thickness) tn1 of the alloy film 8 is substantially uniform, and the formed film thickness (deposited film thickness) tn1a of the alloy film 8 in the region (over the source/drain region, which is the n⁺-type semiconductor region 5b herein) between the adjacent gate electrodes GE is substantially equal to the formed film thickness (deposited film thickness) tn1b of the alloy film 8 over each of the gate electrodes GE (i.e., tn1a=tn1b). By contrast, as shown in FIG. 35, in the region where the gate electrodes GE are adjacent to each other with a relatively narrow spacing therebetween, the formed film thickness (deposited film thickness) tn1c of the alloy film 8 in the region (over the source/drain region, which is the n⁺-type semiconductor region 5b herein) between the adjacent gate electrodes GE is undesirably smaller than the formed film thickness (deposited film thickness) tn1d of the alloy film 8 over each of the gate electrodes GE (i.e., tn1c<tn1d). In FIG. 35 (and FIG. 37), the spacing between the adjacent gate electrodes GE is narrower than in FIG. 34 (and FIG. 36), but the formed thicknesses tn1b and tn1d of the alloy films 8 over the gate electrodes GE are substantially equal irrespective of the spacings between the gate electrodes GE (i.e., tn1b=tn1d).

When a heat treatment is performed in such a state to cause silicidation reaction such that the reaction ratio R1 between the alloy film 8 and the n⁺-type semiconductor region 5b is 100%, the formed metal silicide layer also reflects the formed film thickness of the alloy film 8. In the region where the formed film thickness of the alloy film 8 is large, the metal silicide layer is also formed thick while, in the region where the formed film thickness of the alloy film 8 is small, the metal silicide layer is also formed thin. For example, in the region (over the source/drain region, which is the n⁺-type semiconductor region 5b of FIG. 35 herein) between the gate electrodes GE adjacent to each other with a narrow spacing therebetween as in FIG. 35, due to the small formed film thickness of the alloy film 8, the metal silicide layer is undesirably formed thinner than in the other regions (e.g., over the gate electrodes GE and over the n⁺-type semiconductor region 5b of FIG. 34). When the thickness of the metal silicide layer varies, the characteristic of the MISFET may vary so that it is desirable to maximally equalize the thickness of the metal silicide layer. Also, when the metal silicide layer is thin, the Ni_{1-y}M_{y}Si₂ phase tends to abnormally grow to possibly cause variations in the resistance of the metal silicide layer and an increase in leakage current. From the viewpoint also, it is desirable to reduce variations in the thickness of the metal silicide layer.

By contrast, in the present embodiment, the first heat treatment in Step S3 is performed so as to satisfy the foregoing fourth condition. Therefore, the thickness tn3 of the reacted portion 8b of the alloy film 8 does not reflect a difference in the formed film thickness (deposited film thickness) of the alloy film 8, and the thickness tn3 of the reacted portion 8b of the alloy film 8 is the same in the region where the formed film thickness of the alloy film 8 is large and in the region where the formed film thickness of the alloy film 8 is small. That is, in the region (e.g., over the n⁺-type semiconductor region 5b of FIG. 35) between the gate electrodes GE adjacent to each other with a narrow spacing therebetween, the formed film thickness of the alloy film 8 is smaller than in the other regions (e.g., over the gate electrodes GE and over the n⁺-type semiconductor region 5b of FIG. 34). However, since the alloy film 8 is not caused to react throughout the entire thickness thereof, the thickness tn3 of the reacted portion 8b of the first alloy film 8 in the first heat treatment in Step S3 is substantially the same in the region between the gate electrodes GE adjacent to each other with a narrow spacing therebetween and in the other regions.

However, to achieve the substantially same thickness tn3, the alloy film 8 needs to be deposited rather thick in Step S1 such that the formed film thickness (deposited film thickness) of the alloy film 8 is larger than the thickness tn3 of the reacted portion 8b of the alloy film 8 in the first heat treatment in Step S3 (i.e., tn1b>tn3) even in the region where the alloy film 8 is formed thin. In other words, the alloy film 8 is deposited in Step S1 such that, in any region of the main surface of the semiconductor substrate 1, the thickness tn1 of the alloy film 8 over the foregoing silicon region 31 is larger than the thickness tn3 of the reacted portion 8b of the alloy film 8 in the first heat treatment in Step S3 (tn1>tn3). Specifically, the alloy film 8 is deposited in Step S1 such that, even over the narrow-pitch pattern (region between the gate electrodes GE adjacent to each other with a narrow pitch as in FIG. 35) over which the alloy film 8 tends to be formed thin, the thickness tn1 of the alloy film 8 (e.g., tn1c mentioned above) is larger than the thickness tn3 of the reacted portion 8b of the alloy film 8 in the first heat treatment in Step S3 (tn1>tn3, e.g., tn1c>tn3). As a result, in any region of the main surface of the semiconductor substrate 1, the reaction ratio R1 between the alloy film 8 and the silicon region 31 in the first heat treatment in Step S3 is less than 100% (R1<100%).

Thus, in the present embodiment, even when the formed film thickness of the alloy film 8 differs from place to place, the first heat treatment in Step S3 is performed so as to satisfy the foregoing fourth condition. As a result, in the region where the formed film thickness of the alloy film 8 is large and in the region where the formed film thickness of the alloy film 8 is small, the thickness tn4 of the formed metal silicide layer 11a can be equalized, and accordingly the thickness tn5 of the metal silicide layer 11b can be equalized. This allows a reduction in variations in the thickness of the metal silicide layer 11b, and allows a reduction in variations in the characteristic of the MISFET. In addition, since it is possible to reduce variations in the thickness of the metal silicide layer 11b and maximally equalize the thickness of the metal silicide layer 11b, it is possible to suppress the abnormal growth of the Ni_{1-y}M_{y}Si₂ phase, and suppress variations in the resistance of the metal silicide layer 11b and an increase in leakage current. Therefore, the reliability of the semiconductor device can be improved.

For example, the formed film thickness tn1c of the alloy film 8 over the source/drain region (n⁺-type semiconductor region 5b) of FIG. 35 is smaller than the formed film thickness tn1a of the alloy film 8 over the source/drain region (n⁺-type semiconductor region 5b) of FIG. 34 and the formed film thicknesses tn1b and tn1d of the alloy films 8 over the gate electrodes GE of FIGS. 34 and 35 (i.e., t1c<tn1a, tn1b, and tn1d). In such a case also, by performing the first heat treatment in Step S3 so as to satisfy the foregoing fourth condition, it is possible to substantially equalize the thickness tn1 of the formed metal silicide layer 11b, as shown in FIGS. 36 and 37. That is, it is possible to substantially equalize the thickness tn5a of the metal silicide layer 11b formed over the source/drain region (n⁺-type semiconductor region 5b) of FIG. 36, the thickness tn5c of the metal silicide layer 11b formed over the source/drain region (n⁺-type semiconductor region 5b) of FIG. 37, the thickness tn5b of each of the metal silicide layers 11b formed over the gate electrodes GE of FIG. 36, and the thickness tn5d of each of the metal silicide layers 11b formed over the gate electrodes GE of FIG. 37. Therefore, by performing the first heat treatment in Step S3 so as to satisfy the foregoing fourth condition, the thickness tn5 (to which the thicknesses tn5a and tn5c correspond) of each of the metal silicide layers 11b formed over the source/drain regions (n⁺-type semiconductor regions 5b or p⁺-type semiconductor regions 6b) can be adjusted to a value within a range of 0.8 to 1.2 times the thickness tn5 (to which the thicknesses tn5b and tn5d correspond) of each of the metal silicide layers 11b formed over the gate electrodes GE. The relationship is also maintained in any of the MISFETs formed in the main surface of the semiconductor substrate 1.

In the present embodiment, the concentration distribution of the first metal element M (preferably Pt) in the thickness direction (direction generally perpendicular to the main surface of the semiconductor substrate 1) of each of the formed metal silicide layers 11b is as follows. That is, the concentration of the first metal element M (preferably Pt) in the metal silicide layer 11b is higher at the bottom surface (interface between the metal silicide layer 11b and the silicon region 31) of the metal silicide layer 11b than at the middle of the metal silicide layer 11b along the thickness thereof. Also, the concentration of the first metal element M (preferably Pt) in the metal silicide layer 11b is higher at the upper surface (interface between the metal silicide layer 11b and the insulating film 21 in the state of FIG. 11) of the metal silicide layer 11b than at the middle of the metal silicide layer 11b along the thickness thereof. Thus, the concentration of the first metal element M (preferably Pt) in the metal silicide layer 11b is higher at the bottom and upper surfaces of the metal silicide layer 11b than at the middle of the metal silicide layer 11b along the thickness thereof.

That is, referring to FIG. 28 described above, the concentration distribution (concentration distribution in the thickness direction) of the first metal element M in the metal silicide layer 11b is such that the concentration of the first metal element M (preferably Pt) at the bottom surface of the metal silicide layer 11b (e.g., the concentration of the first metal element M at the position P2 of FIG. 28) is higher than the concentration of the first metal element M (preferably Pt) at the middle of the metal silicide layer 11b along the thickness thereof (e.g., the concentration of the first metal element M at the position P1 of FIG. 28). Also, the concentration distribution (concentration distribution in the thickness direction) of the first metal element M in the metal silicide layer 11b is such that the concentration of the first metal element M (preferably Pt) at the upper surface of the metal silicide layer 11b (e.g., the concentration of the first metal element M at the position P3 of FIG. 28) is higher than the concentration of the first metal element M (preferably Pt) at the middle of the metal silicide layer 11b along the thickness thereof (e.g., the concentration of the first metal element M at the position P1 of FIG. 28). Such a concentration distribution was recognized by EDX (Energy Dispersive X-ray spectroscopy) analysis.

Such a concentration distribution of the first metal element M in the metal silicide layer 11b can be obtained by performing the first heat treatment in Step S3 so as to satisfy the foregoing fourth and fifth conditions to increase the concentration of the first metal element M, and suppress excessive growth of crystal grains. A conceivable reason for this is as follows.

The first metal element M (preferably Pt) added to the metal silicide layer 11b tends to be segregated rather on grain boundaries (surfaces of crystal grains) than in crystal grains, and the concentration thereof tends to be higher on the grain boundaries (surfaces of the crystal grains) than in the crystal grains. When the crystal grains have excessively grown, the segregation of the first metal element M on the grain boundaries disappears. The thickness of the metal silicide layer 11b is smaller than the foregoing grain size (crystal grain size) G1 so that, in the metal silicide layer 11b, a state is achieved where the dimension in the thickness direction is occupied by substantially one crystal grain. Therefore, by performing the first heat treatment in Step S3 so as to satisfy the foregoing fourth and fifth conditions to increase the concentration of the first metal element M, and suppress excessive growth of crystal grains, the concentration of the first metal element M at each of the positions P2 and P3 each substantially corresponding to the surface of the crystal grain can be set higher than the concentration of the first metal element M at the position P1 substantially corresponding to the vicinity of the middle of the crystal grain.

With a concentration distribution of the first metal element M in the metal silicide layer 11b as described above, it is possible to suppress the abnormal growth of Ni_{1-y}M_{y}Si₂ from the metal silicide layer 11b toward the semiconductor substrate 1. This is because, as a result of increasing the concentration of the first metal element M (preferably Pt) at the bottom surface (interface between the metal silicide layer 11b and the semiconductor substrate 1) of the metal silicide layer 11b, the bottom surface (bottom surface of the metal silicide layer 11b) at which the first metal element M (preferably Pt) is distributed or segregated at a high concentration serves as a barrier against the abnormal growth of Ni_{1-y}M_{y}Si₂. To suppress the abnormal growth of Ni_{1-y}M_{y}Si₂ from the metal silicide layer 11b toward the semiconductor substrate 1, it is particularly effective to increase the concentration of the first metal element M (preferably Pt) at the bottom surface of the metal silicide layer 11b (e.g., the concentration of the first metal element M at the position P2 of FIG. 28). Therefore, with a concentration distribution as described above (a concentration distribution such that the concentration of the first metal element M at each of the positions P2 and P3 is higher than the concentration of the first metal element M at the position P1, in which what is most important is that the concentration of the first metal element M at the position P2 is higher than the concentration of the first metal element M at the position P1), it is possible to further suppress the abnormal growth of Ni_{1-y}M_{y}Si₂ from the metal silicide layer 11b toward the semiconductor substrate 1, and further improve the performance of the semiconductor device.

In the present embodiment, in Step S2, the barrier film 8 is formed over the alloy film 8 and, at the time of the first heat treatment in Step S3, the unreacted portion 8a of the alloy film 8 remains over the metal silicide layer 11a, and can function as a protective film (antioxidant film). That is, since the unreacted portion 8a of the alloy film 8 remains during the first heat treatment, even when the surface of the alloy film 8 is exposed during the first heat treatment, the reaction between the alloy film 8 and the silicon region 31 is not adversely affected thereby. Therefore, it is also possible to omit the step of forming the barrier film 9 in Step S2. In this case, after the alloy film 8 is formed in Step S1, the first heat treatment in Step S3 is performed without the formation of the barrier film 8. Thereafter, the unreacted alloy film 8 is removed in Step S4, and then the second heat treatment is performed in Step S5.

For the first heat treatment in Step S3 to satisfy the foregoing fifth condition, when the alloy film 8 is formed of, e.g., the Ni—Pt alloy film, the temperature needs to be set less than 279° C. Therefore, it is more preferable to use a heater device for the first heat treatment in Step S3, which allows temperature control at such a temperature, and allows reliable formation of the metal silicide layer 11a by the first heat treatment.

In the first heat treatment in Step S3, a temperature increasing speed is preferably set to 10° C./second or more, and more preferably 30 to 250° C./second. By setting the temperature increasing speed in the first heat treatment in Step S3 at preferably 10° C./second or more, and more preferably 30 to 250° C./second to rapidly increase the temperature, silicide reaction uniformly occurs in a wafer plane, and it is possible to suppress the application of an excess amount of heat in the temperature rising process of the silicide reaction. Therefore, it is possible to more reliably form the metal silicide layer 11a in only the (Ni_{1-y}M_{y})₂Si phase not including the Ni_{1-y}M_{y}Si₂ phase, the Ni_{1-y}M_{y}Si phase, a (Ni_{1-y}M_{y})₃Si phase, a (Ni_{1-y}M_{y})₅Si phase, or the like. That is, it is possible to form the metal silicide layer 11a in the (Ni_{1-y}M_{y})₂Si phase in which composition variations are suppressed. It is also possible to suppress or prevent excessive growth of grains.

Additionally, to improve the heat conductivity of an atmosphere in the first heat treatment in Step S3, the first heat treatment is preferably performed under ordinary pressure in an inert gas having heat conductivity higher than that of nitrogen, e.g., helium (He) gas or neon (Ne) gas or in an atmospheric gas obtained by adding an inert gas having heat conductivity higher than that of nitrogen gas to the nitrogen gas. For example, the respective heat conductivities of the nitrogen gas, the neon gas, and the helium gas at 100° C. are 3.09×10⁻² Wm⁻¹K⁻¹, 5.66×10⁻² Wm⁻¹K⁻¹, and 17.77×10⁻² Wm⁻¹K⁻¹. By improving the heat conductivity of the atmosphere in the first heat treatment in Step S3, the foregoing temperature increasing speed can be easily achieved.

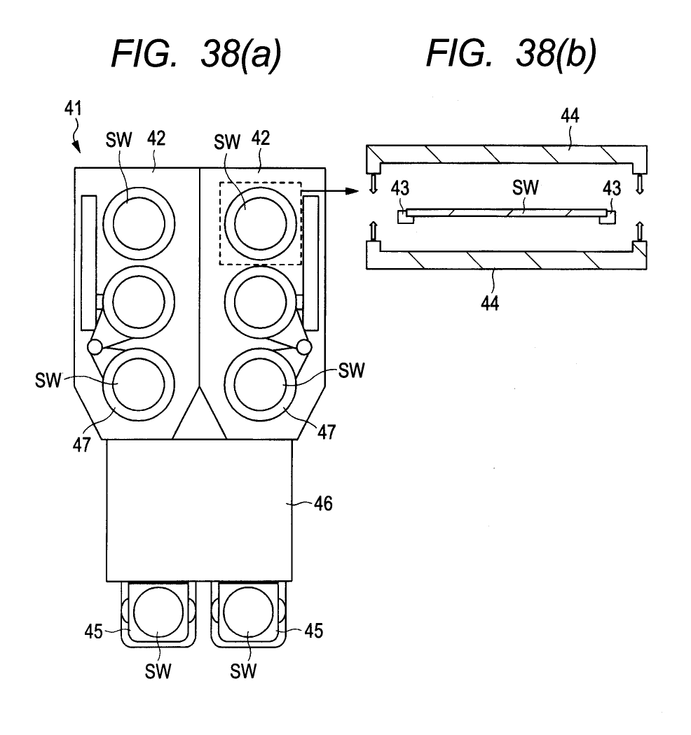

FIGS. 38(a) and 38(b) are illustrative views each showing an example of a heat treatment device (a heater device 41 herein) used in the first heat treatment in Step S3, of which FIG. 38(a) shows an overall structural plan view of the heat treatment device, and FIG. 38(b) shows a main-portion cross-sectional view of the inside of a chamber.

When the first heat treatment in Step S3 is performed, each of semiconductors wafers SW (hereinafter simply referred to as the wafers SW) is placed over each of susceptors 43 in treatment chambers 42 of the heater device (heat treatment device) 41. The wafer SW corresponds to the foregoing semiconductor substrate 1. The inside of each of the chambers 42 is constantly filled with an inert gas (e.g., a nitrogen gas atmosphere containing neon gas added thereto). Over and under (over the top surface and back surface of) the wafer SW, resistor heaters 44 are disposed. By heat conduction from the resistor heaters 44 between which the wafer SW is spacedly interposed at predetermined distances therefrom, the wafer SW is heated. The distances between the wafer SW and the resistor heaters 44 are, e.g., not more than 1 mm. The temperature of each of the resistor heaters 44 is measured using a thermo couple so that the resistor heater 44 is controlled at a predetermined temperature. In the resistor heaters 44, holes for gas introduction are formed. An atmospheric gas for the first heat treatment is supplied through the holes to over and under (the top surface and back surface of) the wafer SW. The flow of the atmospheric gas for the first heat treatment and a pressure in the chamber 42 are individually adjusted to equalize the pressures exerted on the top surface and back surface of the wafer SW, thereby causing the wafer SW to float. Also, by holding the amount of heat transmitted to the wafer SW constant, temperature variations in the plane of the wafer SW are suppressed.

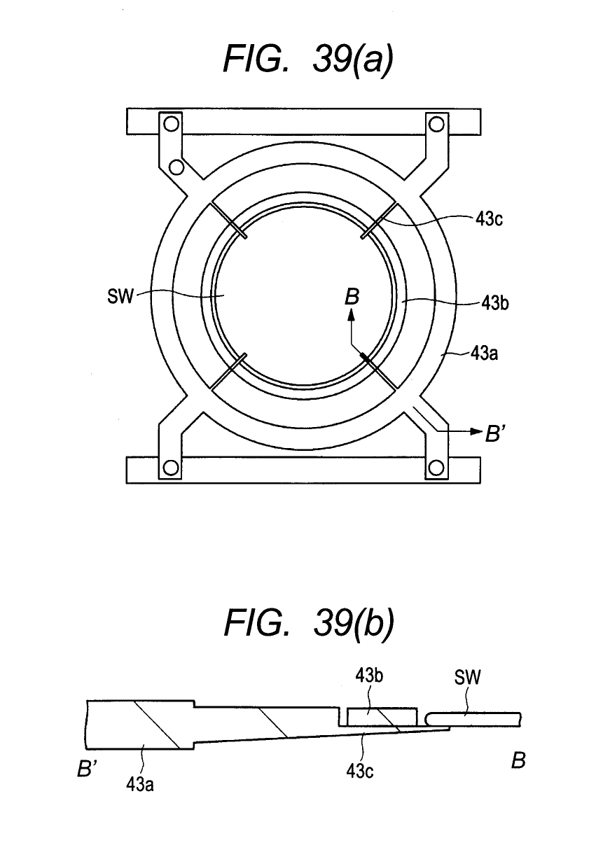

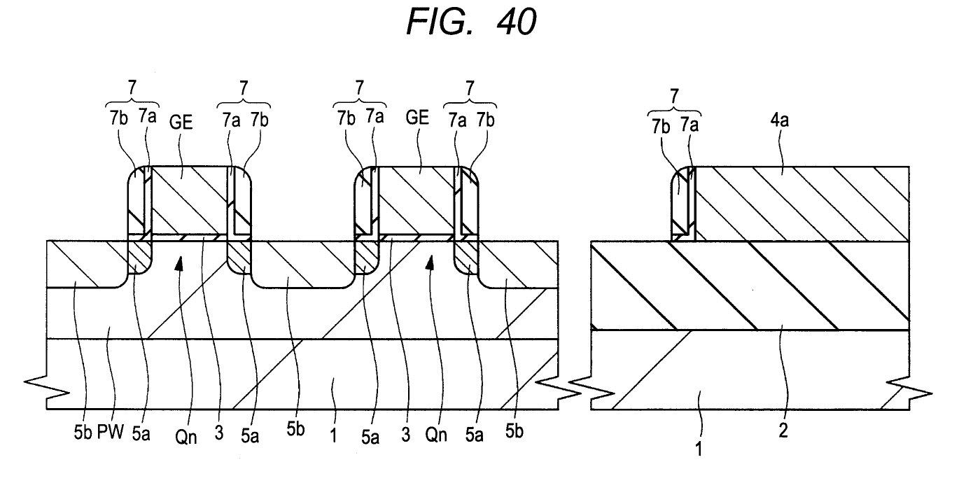

FIGS. 39(a) and 39(b) are illustrative views of each of the susceptors 43 provided in the heater device 41. FIGS. 39(a) and 39(b) show a main-portion plan view and a main-portion cross-sectional view of the susceptor 43 provided in the heater device 41. The cross section along the line B-B′ of FIG. 39(a) substantially corresponds to FIG. 39(b). In FIGS. 39(a) and 39(b), the reference numerals 43a, 43b, and 43c denote a carrier plate, a guard ring, and support pins, respectively. The susceptor 43 is in contact with the wafer SW only at four points using the four support pins 43c provided in the susceptor 43. Since the number of the contact points between the susceptor 43 and the wafer SW is small, a temperature reduction in the plane of the wafer due to the susceptor 43 can be suppressed.

The procedure of the first heat treatment in Step S3 using the heater device 41 will be described below. First, hoops 45 are docked with the heater device 41, and then the wafers SW are transported from the hoops 45 onto load locks in the treatment chambers 42 via a wafer delivery/reception chamber 46. To prevent outside air (mainly oxygen) from being mixed in the atmosphere in each of the treatment chambers 42, an inert gas (e.g., nitrogen gas) is allowed to flow in an atmospheric pressure state in each of the load locks 47 to exclude the outside air. Subsequently, the wafers SW are transported from the load locks 47, and placed over the susceptors 43. Subsequently, the wafers SW are interposed between the resistor heaters 44, and heated. Thereafter, the cooled wafers SW are returned to the load locks 47, and then returned to the hoops 45 via the wafer delivery/reception chamber 46.

In the heater device 41, heating is performed by heat conduction using the gas between each of the wafers SW and the resistor heaters 44 as a medium. The temperature of the wafer SW can be increased to the same temperature as those of the resistor heaters 44 at a temperature increasing speed of 10° C./second or more (e.g., 30 to 250° C./second), and the application of an excess amount of heat to the wafer SW can be suppressed.

Also, in the second heat treatment in Step S5 described above, to prevent an excess amount of heat from being applied to the metal silicide layers 11a and 11b, the temperature increasing speed is preferably set to 10° C./second or more, and more preferably 10 to 250° C./second. Moreover, an amount of heat required to change the metal silicide layer 11a in the (Ni_{1-y}M_{y})₂Si phase formed by the first heat treatment in Step S3 to the metal silicide layer 11b in the phase is applied in the second heat treatment. This can suppress the application of an excess amount of heat to the wafer and, consequently, uniform silicide reaction and stabilization reaction occur to allow the formation of the metal silicide layer 11b in the phase having reduced defects in the surface thereof and suppressed composition variations. In addition, because the grain size in the metal silicide layer 11b can be easily reduced, the metal silicide layer 11b having a grain size which satisfies the foregoing second condition and the foregoing third condition can be easily formed. Note that, in the second heat treatment in Step S5, as long as the temperature increasing speed of 10° C./second or more can be achieved, either a lamp heating device or the heater device can be used. Since the heat treatment temperature in the second heating treatment in Step S5 is higher than the heat treatment temperature in the first heat treatment in Step S3, and a temperature range of not more than 280° C. in which temperature control in the lamp heating device is difficult is not used, a heating device using a lamp, a laser, a radio frequency, or the like can also be used for the second heat treatment in Step S5.

Also, to improve heat conductivity in the heat treatment atmosphere in the second heat treatment in Step S5, the second heat treatment is preferably performed under ordinary pressure in an inert gas having heat conductivity higher than that of nitrogen, e.g., helium (He) gas or neon (Ne) gas or in an atmospheric gas obtained by adding an inert gas (He or Ne) having heat conductivity higher than that of nitrogen gas to the nitrogen gas. By improving the heat conductivity of the atmosphere in the second heat treatment in Step S5, the foregoing temperature increasing speed can be easily achieved.

the second heat treatment in step S5, a RTA treatment can be used, and either a soak anneal treatment or a spike anneal treatment can be used. Here, the soak anneal treatment is a heat treatment method which increases the temperature of the wafer to a heat treatment temperature, holds the wafer at the heat treatment temperature for a given time, and then reduces the temperature of the wafer. The spike anneal treatment is a heat treatment which increases the temperature of the wafer to a heat treatment temperature in a short time, and then reduces the temperature of the wafer without holding the wafer at the heat treatment temperature (a holding time is 0 seconds). In the spike anneal treatment, the amount of heat applied to the wafer can be reduced more greatly than in the soak anneal treatment. If the spike anneal is performed as the second heat treatment in Step S5, it is possible to suppress excessive growth of crystal grains in the metal silicide layers 11a and 11b by the second heat treatment, and further reduce variations in the resistance of the metal silicide layer 11b. In addition, the metal silicide layer 11b having a grain size which satisfies the foregoing second condition and the foregoing third condition tends to be formed. On the other hand, in the first heat treatment in Step S3, the thickness tn3 of the reacted portion 8b of the alloy film 8 can be controlled with the heat treatment period, and therefore the soak anneal treatment is preferred.

In the present embodiment, before the n⁺-type semiconductor regions 5b and the p⁺-type semiconductor regions 6b are formed, it is also possible to ion-implant carbon (C) and germanium (Ge) into respective areas where the n⁺-type semiconductor regions 5b are to be formed and where the p⁺-type semiconductor regions 6b are to be formed, and then ion-implant an n-type impurity (e.g., phosphorus (P) or arsenic (As)) for forming the n⁺-type semiconductor regions 5b and a p-type impurity (e.g., boron (B)) for forming the p⁺-type semiconductor regions 6b. By preliminarily ion-implanting carbon (C) and germanium (Ge), it is possible to suppress the diffusion of the n-type impurity for forming the n⁺-type semiconductor regions 5b and the p-type impurity for forming the p⁺-type semiconductor regions 6b, which are subsequently ion-implanted.

Also in the present embodiment, the case has been described where the metal silicide layers 11a and 11b are formed over the semiconductor regions for sources or drains (n⁺-type semiconductor regions 5b or p⁺-type semiconductor regions 6b) and over the gate electrodes GE. As another configuration, it is also possible to form the metal silicide layers 11a and 11b over the semiconductor regions for sources or drains (which are the n⁺-type semiconductor regions 5b or the p⁺-type semiconductor regions 6b herein) without forming the metal silicide layers 11a and 11b over the gate electrodes GE.

### Second Embodiment

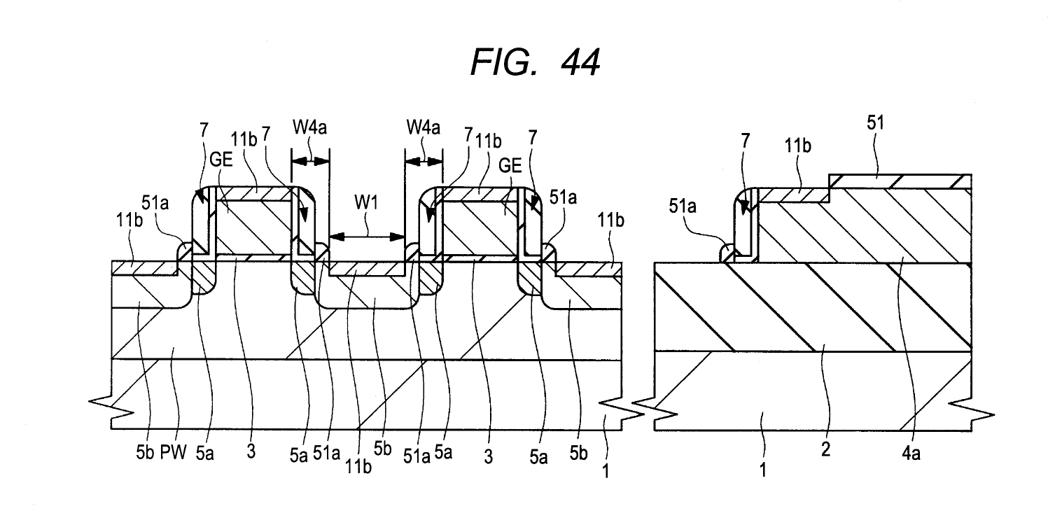

FIGS. 40 to 44 are main-portion cross-sectional views of a semiconductor device of the present embodiment during manufacturing steps. FIG. 40 corresponds to the same process stage as in FIGS. 6 and 14 described above. FIG. 44 corresponds to the same process stage as in FIGS. 10 and 16 described above.

By performing the same steps as described using FIGS. 1 to 16 in the foregoing first embodiment, the structure of FIG. 40 corresponding to FIGS. 6 and 14 described above is obtained. Here, the structure of each of the n-channel MISFETs Qn shown in FIG. 40 is substantially the same as described in the foregoing first embodiment so that a description thereof is omitted here. Note that, in the present embodiment also, not only the n-channel MISFETs Qn, but also the foregoing p-channel MISFETs Qp are formed in the same manner as in the foregoing first embodiment, but the depiction and description of the foregoing p-channel MISFETs Qp are omitted for simplification.

Also, in the present embodiment, by patterning the foregoing silicon film 4 by a photolithographic method and a dry etching method, not only the gate electrodes GE, but also a silicon film pattern 4a for a resistor element (polysilicon resistor element) is formed. Accordingly, the silicon film pattern 4a is formed of the silicon film in the same layer as that of the gate electrodes GE, and the gate electrodes GE and the silicon film pattern 4a are formed over the main surface of the same semiconductor substrate 1. The silicon film pattern 4a is formed over, e.g., the isolation regions 2, and electrically insulated from the semiconductor substrate 1. The sidewalls 7 are formed by successively forming a silicon oxide film 7a and a silicon nitride film 7b over the semiconductor substrate 1 so as to cover the gate electrodes GE and the silicon film pattern 4a, and anisotropically etching a laminate film (in which the silicon oxide film 7a is in the lower layer and the silicon nitride film 7b is in the upper layer) of the silicon oxide film 7a and the silicon nitride film 7b by a RIE method or the like. The sidewalls 7 are formed not only over the side walls of the gate electrodes GE, but also over the side walls of the silicon film pattern 4a.

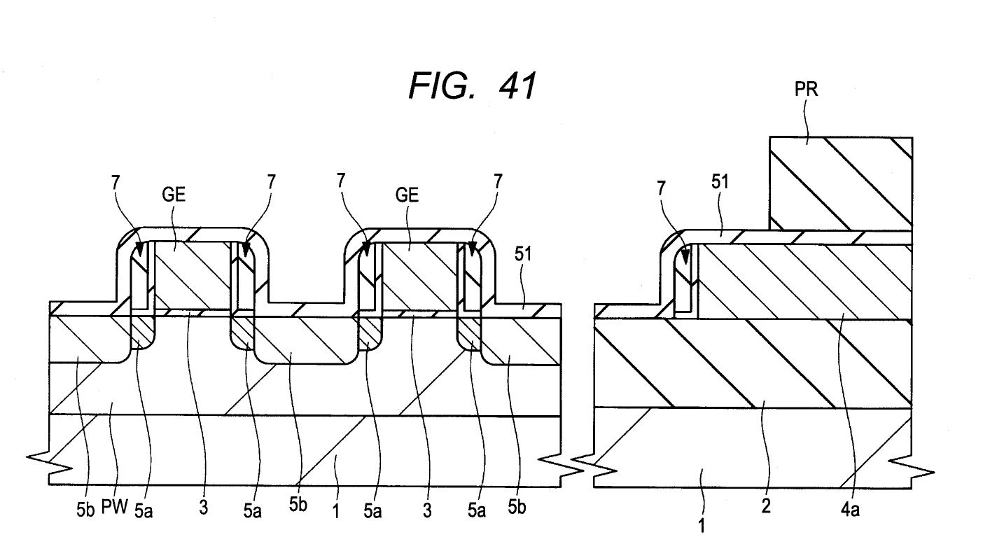

After the structure of FIG. 40 corresponding to FIGS. 6 and 14 described above is obtained, in the present embodiment, as shown in FIG. 41, over the semiconductor substrate 1, an insulating film (second insulating film) 51 is formed so as to cover the gate electrodes GE, the silicon film pattern 4a, and the sidewalls 7 over the side walls thereof. The insulating film 51 is formed of a silicon oxide film, and can be formed using, e.g., TEOS. The film thickness (deposition thickness) of the insulating film 51 can be adjusted to, e.g., about 10 to 50 nm. The insulating film 51 is formed such that, in a salicide step, the metal silicide layers 11a and 11b are not formed in regions where the metal silicide layers 11a and 11b are not needed.

After the formation of the insulating film 51, over the insulating film 51, a photoresist pattern (resist pattern, photoresist film, or resist film) PR is formed as a resist pattern by a photolithographic technique. The photoresist pattern PR is formed in the regions where the metal silicide layers 11a and 11b are prevented from being formed in the salicide step. Examples of the regions where the metal silicide layers 11a and 11b are prevented from being formed in the salicide step include the region of the silicon film pattern 4a where the metal silicide layers 11a and 11b are not formed. Over the gate electrodes GE, the n⁺-type semiconductor regions 5b, and the p⁺-type semiconductor regions 6b, the metal silicide layers 11a and 11b are formed later. Therefore, over the gate electrodes GE, the sidewalls 7 provided over the side walls of the gate electrodes GE, the n⁺-type semiconductor regions 5b (source/drain regions), and the p⁺-type semiconductor regions 6b (source/drain regions), the photoresist pattern PR is not formed (placed).

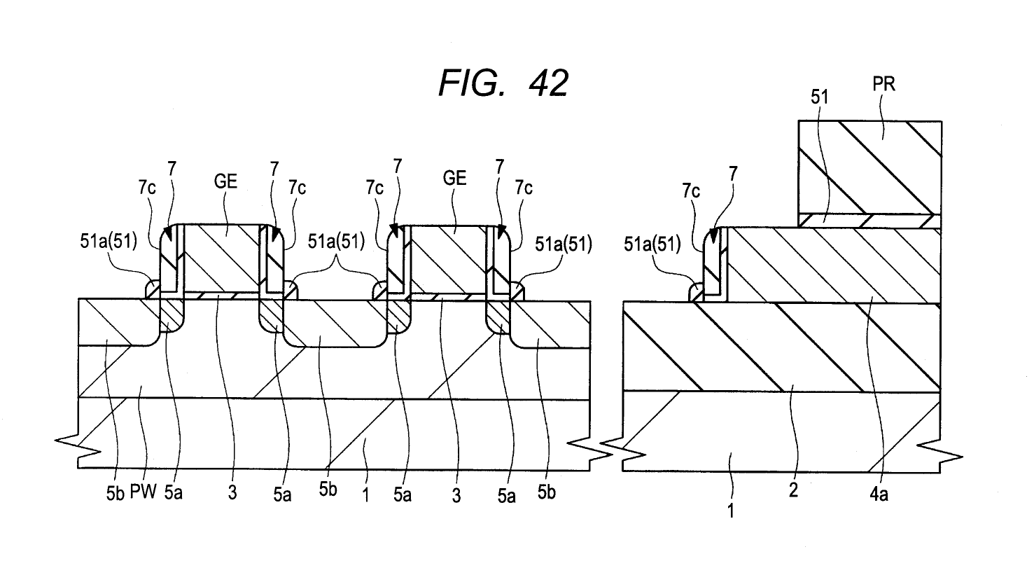

Next, as shown in FIG. 42, using the photoresist pattern PR as an etching mask, the insulating film 51 is subjected to dry etching. As a result, the insulating film 51 in the region covered with the photoresist pattern PR is not etched and remains, while the insulating film 51 in the region uncovered with the photoresist pattern PR is removed. However, since the insulating film 51 is etched by anisotropic etching, over the lower portions of side surfaces 7c of the sidewalls 7, small portions of the insulating film 51 remain in the form of sidewalls (sidewall insulating films or sidewall spacers) to form sidewalls (sidewall insulating films or sidewall spacers) 51a smaller than the sidewalls 7. Here, the side surfaces 7c of the sidewalls 7 are side surfaces opposite to those thereof opposing the gate electrodes GE and the silicon film pattern 4a.

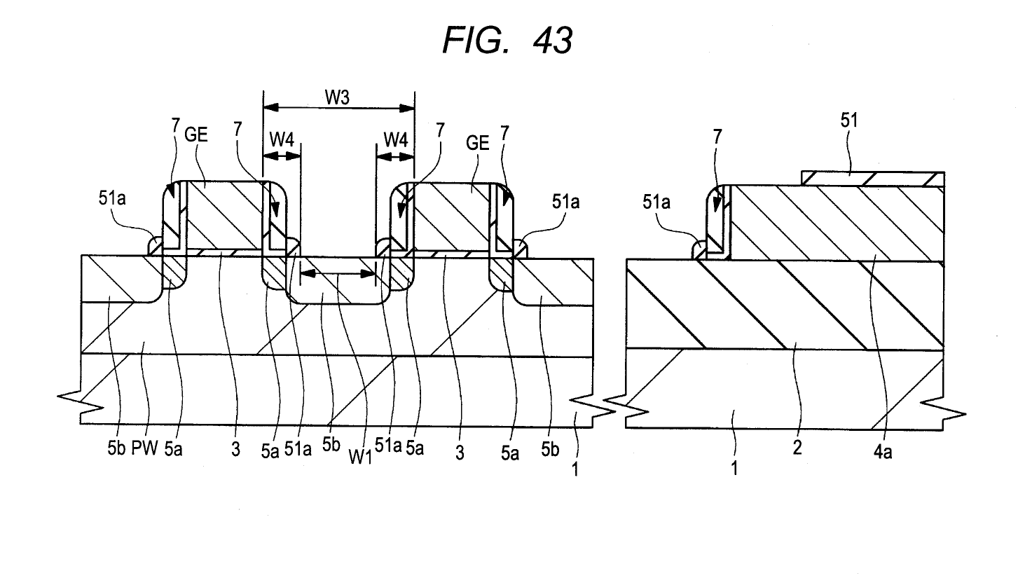

Next, as shown in FIG. 43, the photoresist pattern PR is removed by ashing or the like. At this stage, over the lower portions of the side surfaces 7c of the sidewalls 7, the small sidewalls 51a each formed of the remaining insulating film 51a are present.

The subsequent steps are the same as in the foregoing first embodiment. That is, with the sidewalls 51a being present over the lower portions of the side surfaces 7c of the sidewalls 7, the alloy film 8 is formed in Step S1 described above. Then, in Step S2 described above, the barrier film 9 is formed and, in Step S3 described above, the first heat treatment is performed. In Step S4 described above, the barrier film 9 and the unreacted alloy film 8 are removed and, in Step S5 described above, the second heat treatment is performed. Steps S1 to S5 performed in the present embodiment are also the same as in the foregoing first embodiment, and described in detail in the foregoing first embodiment so that the depiction and description thereof is omitted here. In this manner, as shown in FIG. 44, the metal silicide layers 11b are formed over the gate electrodes GE, the n⁺-type semiconductor regions 5b (and the p⁺-type semiconductor regions 6b not shown), and the silicon film pattern 4a.

Over the regions of the upper surface of the silicon film pattern 4a to be coupled to the foregoing plugs PG, the metal silicide layers 11b are formed, but the other region thereof is covered with the insulating film 51. By thus preventing the metal silicide layer 11b from being formed therein, the silicon film pattern 4a is caused to function as the resistor element.

Also, with the sidewalls 51a being present over the side walls of the sidewalls 7, it is possible to suppress or prevent the formation of the metal silicide layers 11b under the sidewalls 51a. This allows the metal silicide layers 11b to be spaced apart from the n⁻-type semiconductor regions 5a (and the p⁻-type semiconductor regions 6a not shown) by a distance corresponding to the thickness of the sidewall 51a. Accordingly, a junction leakage can be further reduced, and the reliability of the semiconductor device can further be improved.

When the sidewalls 51a remain, the sidewalls 51a may react with the alloy film 8 to accelerate the abnormal growth of Ni_{1-y}M_{y}Si₂. However, in the present embodiment, by satisfying the foregoing first, second, and third conditions in the same manner as in the foregoing first embodiment, the abnormal growth of Ni_{1-y}M_{y}Si₂ can be suppressed. This allows the suppression or prevention of an adverse effect due to the remaining sidewalls 51a. Therefore, it is possible to benefit from the foregoing advantage (the effect of reducing the junction leakage) resulting from the remaining sidewalls 51a, while suppressing or preventing the adverse effect due to the remaining sidewalls 51a.

The structure of the present embodiment is otherwise the same as that of the foregoing first embodiment so that a description thereof is omitted here.

Here, a description will be given of how to define the foregoing width W1 for determining whether or not the foregoing second and third conditions are satisfied when the sidewalls 51a are present over the side walls of the sidewalls 7 as in the present embodiment.

The low-impurity-concentration extension regions in the LDD structure (to which the n⁻-type semiconductor regions 5a and the p⁻-type semiconductor regions 6a correspond) have the sidewalls 7 thereover so that the metal silicide layers 11b are not formed thereover. Therefore, in the same manner as in the foregoing first embodiment, in the present embodiment also, the width of each of the extension regions (n⁻-type semiconductor regions 5a or p⁻-type semiconductor regions 6a) is not included in the width W1 of the source/drain region. Also in the present embodiment, the portions of the n⁺-type semiconductor region 5b (or the p⁺-type semiconductor region 6b) covered with the sidewalls 51a have the sidewalls 51a thereover so that the metal silicide layer 11b is not formed thereover. Therefore, the width of each of the portions of the n⁺-type semiconductor region 5b and the p⁺-type semiconductor region 6b covered with the sidewalls 51a is not included in the width W1 of the source/drain region.

That is, in the present embodiment, the combination of the sidewalls 7 and the sidewalls 51a are regarded as the sidewall insulating films. It is assumed that, in principle, the width W1 of the source/drain region does not include the widths of the portions (the low-concentration extension regions under the sidewalls 7 and the high-concentration regions under the sidewalls 51a) located under the sidewall insulating films (sidewalls 7 and sidewalls 51a), and indicates the width (width in the gate length direction) of the high-concentration region (n⁺-type semiconductor region 5b or p⁺-type semiconductor region 6b) in the portion uncovered with the sidewall insulating films (sidewalls 7 and sidewalls 51a). In the foregoing first embodiment and the present embodiment, it is commonly assumed that the source/drain region when the width W1 of the source/drain region is defined does not include the regions covered with the sidewall insulating films (which are the sidewalls 7 in the foregoing first embodiment and the combination of the sidewalls 7 and the sidewalls 51a in the present embodiment), and indicates the high-concentration region (n⁺-type semiconductor region 5b or p⁺-type semiconductor region 6b) in the portion uncovered with the sidewall insulating films. Therefore, it can also be said that the source/drain region when the width W1 of the source/drain region is defined is a region which is uncovered with the sidewall insulating films (which are the sidewalls 7 in the foregoing first embodiment and the combination of the sidewalls 7 and the sidewalls 51a in the present embodiment) and over which the metal silicide layer 11b is formed or to be formed.

### Third Embodiment

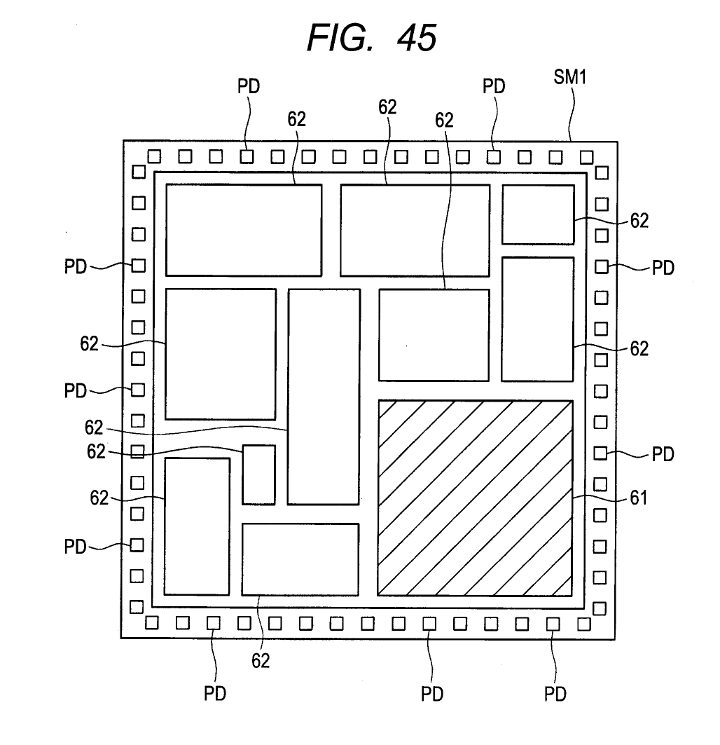

FIG. 45 is a plan view showing an example of a semiconductor device (semiconductor chip) SM1 of the present embodiment. Note that FIG. 45 is a plan view but, for clarity of illustration, a memory region 61 is hatched.

The semiconductor device SM1 of the present embodiment has the memory region (memory circuit region, memory cell array region, or SRAM region) 61 where a memory cell array of a SRAM (Static Random Access Memory) or the like is formed, and peripheral circuit regions 62 where circuits (peripheral circuits) other than the memory are formed. The peripheral circuit regions 62 include, e.g., an analog circuit region where an analog circuit is formed, a CPU region where a control circuit is formed, and the like. Between the memory region 61 and the peripheral circuit region 62 and between the individual peripheral circuit regions 62, electrical coupling is provided as necessary via the internal interconnect layers (the foregoing interconnects M1 and upper-layer interconnects thereover) of the semiconductor device SM1. Over the peripheral portion of the main surface (top surface) of the semiconductor device SM1, a plurality of pad electrodes PD are formed along the four sides of the main surface of the semiconductor device SM1. The pad electrodes PD are each electrically coupled to the memory region 61, the peripheral circuit regions 62, and the like via the internal interconnect layers of the semiconductor device SM1.

Similarly to the semiconductor device of the foregoing first embodiment, the semiconductor device of the present embodiment is also a semiconductor device in which a plurality of MISFETs having the gate electrodes GE and the source/drain regions (n⁺-type semiconductor regions 5b or p⁺-type semiconductor regions 6b) over which the metal silicide layers 11b are formed are formed in the main surface of the semiconductor substrate 1. In the memory region 61 and the peripheral circuit regions 62, the various MISFETs are formed, but the foregoing adjacent spacing W3 in each of the MISFETs forming the memory cells in the memory region 61 is narrower (smaller) than the foregoing adjacent spacing W3 in each of the MISFETs in the other regions (such as the peripheral circuit regions 62). This because, in the memory region 61, the plurality of memory cells are arranged as an array to form the memory cell array but, to increase the memory capacity and reduce the size (area) of the semiconductor device, it is effective to reduce the adjacent spacing W3 in each of the MISFETs forming the memory cells in the memory region 61.

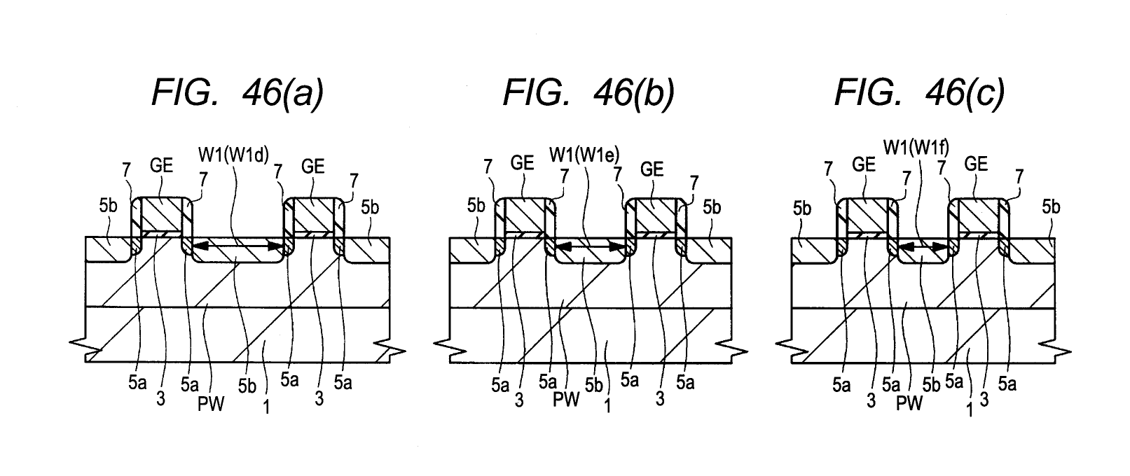

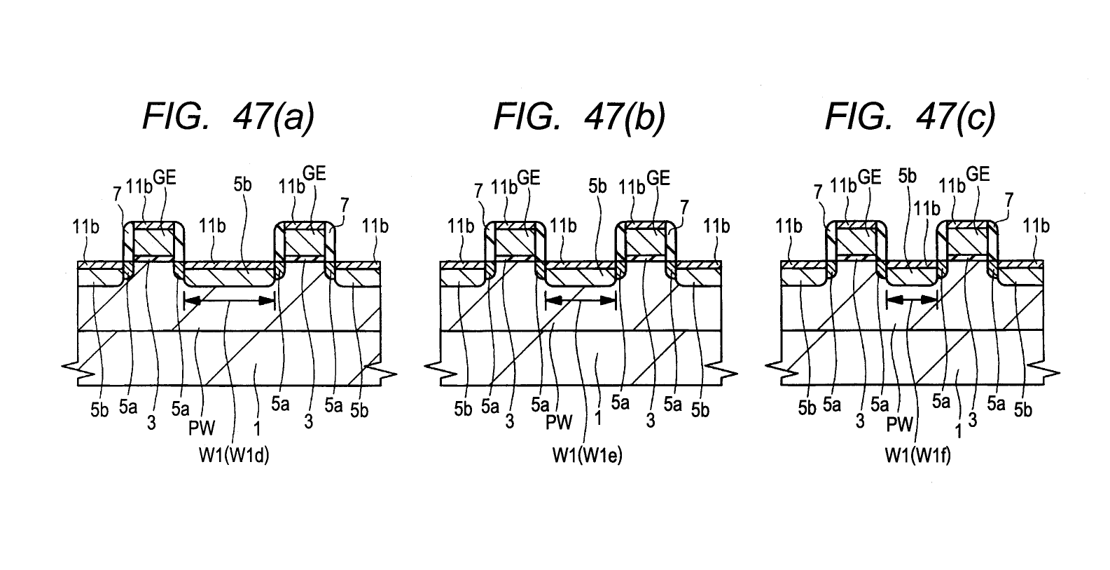

FIGS. 46(a), 46(b), and 46(c) are main-portion cross-sectional views of the semiconductor device at the stage after the n⁺-type semiconductor regions 5b and the p⁺-type semiconductor regions 6b are formed and before the foregoing alloy film 8 is formed in Step S1 described above (i.e., the same process stage as in FIGS. 6, 14, and 21 described above). FIGS. 47(a), 47(b), and 47(c) are main-portion cross-sectional views of the semiconductor device at the stage after the metal silicide layers 11b are formed by performing Steps S1 to S5 described above and before the foregoing insulating film 21 is formed (i.e., the same process stage as in FIGS. 10, 16, and 22 described above). FIGS. 46(a) to 47(c) show the same cross-sectional region at the different process stages. In FIGS. 46(a) to 47(c), the region where the n-channel MISFETs are formed is shown. However, in the case where the region where the p-channel MISFETs are formed is shown, in each of FIGS. 46(a) to 47(c), the p-type well PW is replaced with the n-type well NW, the n⁻-type semiconductor regions 5a are replaced with the p⁻-type semiconductor regions 6a, and the n⁺-type semiconductor regions 5b are replaced with the p⁺-type semiconductor regions 6b.

FIGS. 46(c) and 47(c) show the regions where the MISFETs forming the memory cells (more specifically, the memory cells of the SRAM) in the memory region 61 are formed. FIGS. 46(a), 46(b), 47(a), and 47(b) show the regions where the MISFETs (e.g., the MISFETs forming the peripheral circuit regions 62) other than the MISFETs forming the memory cells are formed.

Here, the width W1 of each of the source/drain regions (n⁺-type semiconductor regions 5b or p⁺-type semiconductor regions 6b) of the MISFETs shown in FIGS. 46(a) and 47(a) is referred to as a width W1d. Also, the width W1 of each of the source/drain regions (n⁺-type semiconductor regions 5b or p⁺-type semiconductor regions 6b) of the MISFETs shown in FIGS. 46(b) and 47(b) is referred to as a width W1e. Also, the width W1 of each of the source/drain regions (n⁺-type semiconductor regions 5b or p⁺-type semiconductor regions 6b) of the MISFETs shown in FIGS. 46(c) and 47(c) is referred to as a width W1f. The relations among the widths W1d, W1e, and W1f are such that the width W1e is smaller than the width W1d, and the width W1f is smaller than the width W1e (i.e., W1f<W1e<W1d).

In the memory region 61, the memory cells are arranged as the array to form the memory cell array so that the MISFETs forming the memory cells are also the MISFETs forming the memory cell array. The gate electrodes GE shown in FIGS. 46(c) and 47(c) are the gate electrodes GE of the MISFETs forming the memory cell array (memory cells), and also the gate electrodes GE adjacent to each other in the gate length direction. The source/drain regions (n⁺-type semiconductor regions 5b or p⁺-type semiconductor regions 6b) shown in FIGS. 46(c) and 47(c) are the source/drain regions disposed between the gate electrodes GE of the MISFETs forming the memory cell array (memory cells), and adjacent to each other in the gate length direction, and have widths (widths in the gate length direction) each corresponding to the width W1f.

The foregoing adjacent spacing W3 between the MISFETs forming the memory cells in the memory region 61 is narrower (smaller) than the foregoing adjacent spacing W3 of the MISFETs in the other regions (such as the peripheral circuit regions 62). Accordingly, the width W1f of each of the source/drain regions of the MISFETs (MISFETs shown in FIGS. 46(c) and 47(c)) forming the memory cells (more specifically, the memory cells of the SRAM) is smaller than the widths W1d and W1e of the source/drain regions of the MISFETs (MISFETs shown in FIGS. 46(a), 46(b), 47(a), and 47(b)) other than the MISFETs forming the memory cells.

In the semiconductor device of the present embodiment, the plurality of MISFETs are formed and, over the source/drain regions (n⁺-type semiconductor regions 5b or p⁺-type semiconductor regions 6b) of the individual MISFETs, the metal silicide layers 11b are formed by the salicide process. Since the metal silicide layers 11b are formed in the same step, by adjusting heat treatment conditions (conditions for the foregoing first and second heat treatments), and so forth, it is possible to equally control the grain sizes (values each corresponding to the foregoing grain size G1) for all the metal silicide layers 11b, but it is difficult to individually control the grain sizes in the metal silicide layers 11b for each of the MISFETs. Accordingly, it is difficult to independently control the grain sizes in the metal silicide layers 11b formed over the source/drain regions (n⁺-type semiconductor regions 5b or p⁺-type semiconductor regions 6b) shown in FIG. 47(a), the grain sizes in the metal silicide layers 11b formed over the source/drain regions shown in FIG. 47(b), and the grain sizes in the metal silicide layers 11b formed over the source/drain regions shown in FIG. 47(c).

Therefore, in the foregoing embodiment, as the third condition, the grain size G1 in each of the metal silicide layers 11b formed over the source/drain regions (n⁺-type semiconductor regions 5b or p⁺-type semiconductor regions 6b) is set smaller than the foregoing width W1c (G1<W1c). By contrast, in the present embodiment, as a sixth condition as a replacement for the foregoing third condition, the grain size (crystal grain size) G1 in each of the metal silicide layers 11b formed over the source/drain regions (n⁺-type semiconductor regions 5b or p⁺-type semiconductor regions 6b) is set smaller than the width W1f of each of the source/drain regions (n⁺-type semiconductor regions 5b or p⁺-type semiconductor regions 6b) of the MISFETs forming the memory cells (memory cell array) (G1<W1f). Here, the width W1f of each of the source/drain regions of the MISFETs forming the memory cells (memory cell array) corresponds to the width (first width) W1f in the gate length direction of each of the source/drain regions (the source/drain regions (n⁺-type semiconductor regions 5b or p⁺-type semiconductor regions 6b) shown in FIGS. 46(c) and 47(c)) disposed between the gate electrodes GE of the MISFETs forming the memory cells (memory cell array), and adjacent to each other in the gate length direction.

The first heat treatment and the second heat treatment in Steps S3 and S5 described above are performed so as to satisfy the sixth condition. The sixth condition is applied to all the metal silicide layers 11b formed over the source/drain regions (n⁺-type semiconductor regions 5b or p⁺-type semiconductor regions 6b) of the MISFETs irrespective of whether or not the MISFETs are the MISFETs forming the memory cells (more specifically, the memory cells of the SRAM). That is, in each of the metal silicide layers 11b of FIG. 47(a), FIG. 47(b), and FIG. 47(c), the grain size G1 therein is controlled to be smaller than the width W1f of each of the source/drain regions (n⁺-type semiconductor regions 5b or p⁺-type semiconductor regions 6b) of FIG. 47(c). If the sixth condition is to be expressed from another viewpoint, when the plurality of MISFETs having the source/drain regions (n⁺-type semiconductor regions 5b or p⁺-type semiconductor regions 6b) over which the metal silicide layers 11b are formed are formed in the main surface of the semiconductor substrate 1, the grain size G1 is controlled to be smaller than the width W1f of each of the source/drain regions (n⁺-type semiconductor regions 5b or p⁺-type semiconductor regions 6b) of the MISFETs forming the memory cells irrespective of whether or not the MISFETs are the MISFETs forming the memory cells.

When the sixth condition is satisfied, the memory cells formed of the MISFETs having the metal silicide layers 11b and the source/drain regions which do not satisfy the foregoing second condition (which satisfy G1≧W1f) no more exist in the memory region 61. As a result, the foregoing second condition is satisfied in each of the metal silicide layers 11b formed over the source/drain regions (n⁺-type semiconductor regions 5b or p⁺-type semiconductor regions 6b) of the MISFETs forming the memory cells. For example, in each of the metal silicide layers 11b formed over the source/drain regions (n⁺-type semiconductor regions 5b or p⁺-type semiconductor regions 6b) in FIGS. 47(a), 47(b), and 47(c), by setting the grain size G1 thereof smaller than the width W1f of the source/drain region (n⁺-type semiconductor region 5b or p⁺-type semiconductor region 6b) of FIG. 47(c), the second condition is constantly satisfied (G1<W1) in FIG. 47(c).

Conditions in the present embodiment are substantially the same as those in the foregoing first embodiment except that the sixth condition is satisfied instead of the foregoing third condition of the foregoing first embodiment. Therefore, a description thereof is omitted here.

As described above, when the foregoing second condition is not satisfied (G1≧W1), the abnormal growth of Ni_{1-y}M_{y}Si₂ tends to occur. On the other hand, if the foregoing second condition is satisfied (G1<W1), the abnormal growth of Ni_{1-y}M_{y}Si₂ can be suppressed, and therefore an increase in leakage current can be suppressed or prevented. If the memory cells are formed of the MISFETs having the metal silicide layers 11b and the source/drain regions which do not satisfy either the sixth condition or the foregoing second condition (i.e., which satisfy G1≧W1), Ni_{1-y}M_{y}Si₂ tends to abnormally grow from the metal silicide layers 11b over the source/drain regions 11b of the MISFETs forming the memory cells toward the channel portions. As a result, a leakage current may increase to cause an erroneous operation.

On the other hand, when the sixth condition is satisfied, the memory cells are no more formed of the MISFETs having the metal silicide layers 11b (i.e., metal silicide layers 11b from which Ni_{1-y}M_{y}Si₂ tends to abnormally grow) and the source/drain regions which do not satisfy the foregoing second condition (i.e., which satisfy G1≧W1). This allows the suppression or prevention of problems (an increased leakage current and the resulting occurrence of the foregoing leakage current defect) resulting from the abnormal growth of Ni_{1-y}M_{y}Si₂ from the metal silicide layers 11 in each of the MISFETs forming the memory cells. Therefore, it is possible to reliably improve the performance of the semiconductor device having the memory region (61) where the memory (memory cells) is formed.

To increase the memory capacity and reduce the size (area) of the semiconductor device, it is effective to reduce the adjacent spacing W3 between the memory cells. Accordingly, the width W1f of each of the source/drain regions of the MISFETs forming the memory cells is preferably set smaller than the widths (corresponding to the foregoing widths W1d and W1e) of the source/drain regions of the MISFETs other than the MISFETs forming the memory cells. It follows that, when the sixth condition is satisfied, not only the MISFETs forming the memory cells, but also the MISFETs other than the MISFETs forming the memory cells satisfy the foregoing second condition (i.e., satisfy G1<W1). Therefore, when the sixth condition is satisfied, not only in the MISFETs forming the memory cells, but also in a majority of the plurality of MISFETs formed in the main surface of the semiconductor substrate, problems (an increased leakage current and the resulting occurrence of the foregoing leakage current defect) resulting from the abnormal growth of Ni_{1-y}M_{y}Si₂ from the metal silicide layers 11b can be suppressed or prevented. As a result, in the semiconductor device having the memory region (61) where the memory (memory cells) is formed, it is possible to improve the characteristics of not only the memory region (61), but also the regions other than that (such as the peripheral circuit regions 62), and improve the performance of the entire semiconductor device.

Under the foregoing sixth condition, the grain size G1 in each of the metal silicide layers 11b is set smaller than the foregoing width W1f (G1<W1f). However, by the same reasoning as used for the foregoing second and third conditions, it is more preferable if the grain size G1 in each of the metal silicide layers 11b is set less than ½ of the foregoing width W1f (G1<W1f×0.5). As a result, it is possible to increase the number of the grain boundaries GB traversing the gate length direction in the metal silicide layer 11b, and therefore more reliably suppress the abnormal growth of Ni_{1-y}M_{y}Si₂ from the metal silicide layer 11b toward the channel portion.

The other effects of the present embodiment are substantially the same as described in the foregoing first embodiment so that a description thereof is omitted here. Also, the manufacturing process of the semiconductor device of the present embodiment is basically the same as that of the foregoing first embodiment so that a description thereof is omitted. It is also possible to apply the foregoing second embodiment to the present embodiment.

The technical idea of each of the foregoing first and second embodiments and the present third embodiment is as follows. When the MISFET elements formed in the semiconductor substrate 1 are scaled down, the width W1 of each of the source/drain regions is narrowed (reduced) but, at this time, not only the width W1 of each of the source/drain regions is narrowed (reduced), but also the grain size G1 in the metal silicide layer 11b formed over the source/drain region is also reduced to maintain the relationship given by W1>G1. That is, the technical idea is to control and reduce the grain size G1 in the metal silicide layer 11b with the scaling down of the MISFET elements. Therefore, the foregoing first and second embodiments and the present third embodiment achieve large effects when applied to the case where the MISFET elements formed in the semiconductor substrate 1 are scaled down, and the width W1 of each of the source/drain regions is narrowed (reduced). For example, the foregoing first embodiment achieves a large effect when applied to the case where the foregoing width W1c is not more than 140 nm (i.e., W1c≦140 nm), and achieves an extremely large effect when applied to the case where the foregoing width W1c is not more than 120 nm W1c≦120 nm). The present third embodiment achieves a large effect when applied to the case where the foregoing width W1f is not more than 140 nm (i.e., W1f≦140 nm), and achieves an extremely large effect when applied to the case where the foregoing width W1f is not more than 120 nm (i.e., W1f≦120 nm). Even when the foregoing widths W1c and W1f have such small values, by forming the metal silicide layer 11b such that the grain size G1 in the metal silicide layer 11b is smaller than the foregoing widths W1c and W1f (i.e., G1<W1c or G1<W1f is satisfied), it is possible to reliably benefit from effects as described in the foregoing first to third embodiments.

While the invention achieved by the present inventors has been specifically described heretofore based on the embodiments thereof, the present invention is not limited thereto. It will be appreciated that various changes and modifications can be made in the invention within the scope not departing from the gist thereof.

The present invention is effective when applied to a semiconductor device and a manufacturing technique therefor.

What is claimed is:

1. A semiconductor device, comprising:
a plurality of MISFETs formed in a main surface of a semiconductor substrate, and each having a gate electrode, and source/drain regions over each of which a metal silicide layer is formed,
wherein the metal silicide layer is formed of a silicide of nickel and a first metal element including at least one selected from the group consisting of Pt, Pd, V, Er, and Yb, and
wherein a grain size in the metal silicide layer is smaller than a first width in a gate length direction of a first source/drain region included in the source/drain regions of the MISFETs, and having the smallest width in the gate length direction.

2. A semiconductor device according to claim 1,
wherein the first source/drain region is included in the source/drain regions of the MISFETs, and disposed between the gate electrodes adjacent in closest proximity to each other in the gate length direction.

3. A semiconductor device, comprising:
a plurality of MISFETs formed in a main surface of a semiconductor substrate, and each having a gate electrode, and source/drain regions over each of which a metal silicide layer is formed,
wherein the metal silicide layer is formed of a silicide of nickel and a first metal element including at least one selected from the group consisting of Pt, Pd, V, Er, and Yb,
wherein the MISFETs include a plurality of first MISFETs forming a memory cell array, and
wherein a grain size in the metal silicide layer is smaller than a first width in a gate length direction of a first source/drain region included in the source/drain regions of the MISFETs, and disposed between the gate electrodes of the first MISFETs adjacent to each other in the gate length direction.

4. A semiconductor device according to any one of claims 1 to 3,
wherein the first metal element is Pt.

5. A semiconductor device according to claim 4,
wherein a ratio of the Pt element to the metal elements in the metal silicide layer is not less than 4%.

6. A semiconductor device according to claim 5,
wherein the metal silicide layer is in a Ni_{1-y}Pt_{y}Si phase.

7. A semiconductor device according to claim 6,
wherein a Pt concentration in the metal silicide layer is higher at a bottom surface of the metal silicide layer than at a middle of the metal silicide layer along a thickness thereof.

8. A semiconductor device according to claim 7,
wherein the Pt concentration in the metal silicide layer is higher at the bottom surface and an upper surface of the metal silicide layer than at the middle of the metal silicide layer along the thickness thereof.

9. A semiconductor device according to claim 6,
wherein sidewall insulating films are formed over side walls of the gate electrodes, and
wherein the source/drain regions are formed by self-alignment with respect to the sidewall insulating films formed over the side walls of the gate electrodes.

10. A semiconductor device according to claim 6,
wherein the grain size in the metal silicide layer is less than ½ of the first width.

11. A semiconductor device according to claim 6,
wherein the first width is not more than 140 nm.

12. A method of manufacturing a semiconductor device having a plurality of MISFETs each having source/drain regions over each of which a metal silicide layer is formed, comprising the steps of:
(a) preparing a semiconductor substrate;
(b) after the step (a), forming gate electrodes of the MISFETs over the semiconductor substrate via gate insulating films;
(c) after the step (b), forming sidewall insulating films over side walls of the gate electrodes;
(d) after the step (c), forming the source/drain regions of the MISFETs in the semiconductor substrate by an ion implantation method;
(e) after the step (d), forming an alloy film of nickel and a first metal element over the semiconductor substrate including the source/drain regions so as to cover the gate electrodes;
(f) after the step (e), performing a first heat treatment to cause the alloy film to react with the source/drain regions to form the metal silicide layers each formed of a silicide of nickel and the first metal element;
(g) after the step (e), removing the alloy film which has not reacted with the source/drain regions in the step (e) from over the metal silicide layers;
(h) after the step (f), performing a second heat treatment at a heat treatment temperature higher than that in the first heat treatment; and
(i) after the step (g), forming a first insulating film over the semiconductor substrate including the metal silicide layers,
wherein the first metal element includes at least one selected from the group consisting of Pt, Pd, V, Er, and Yb, and
wherein the first heat treatment and the second heat treatment are performed such that a grain size in each of the metal silicide layers after the second heat treatment is performed in the step (h) is smaller than a first width in a gate length direction of a first source/drain region included in the source/drain regions of the MISFETs, and having the smallest width in the gate length direction.

13. A method of manufacturing the semiconductor device according to claim 12,
wherein the first source/drain region is included in the source/drain regions of the MISFETs, and disposed between the gate electrodes adjacent in closest proximity to each other in the gate length direction.

14. A method of manufacturing a semiconductor device having a plurality of MISFETs each having source/drain regions over each of which a metal silicide layer is formed, comprising the steps of:
(a) preparing a semiconductor substrate;
(b) after the step (a), forming gate electrodes of the MISFETs over the semiconductor substrate via gate insulating films;
(c) after the step (b); forming sidewall insulating films over side walls of the gate electrodes;
(d) after the step (c), forming the source/drain regions of the MISFETs in the semiconductor substrate by an ion implantation method;
(e) after the step (d), forming an alloy film of nickel and a first metal element over the semiconductor substrate including the source/drain regions so as to cover the gate electrodes;
(f) after the step (e), performing a first heat treatment to cause the alloy film to react with the source/drain regions to form the metal silicide layers each formed of a silicide of nickel and the first metal element;
(g) after the step (e), removing the alloy film which has not reacted with the source/drain regions in the step (e) from over the metal silicide layers;
(h) after the step (f), performing a second heat treatment at a heat treatment temperature higher than that in the first heat treatment; and
(i) after the step (g), forming a first insulating film over the semiconductor substrate including the metal silicide layers,
wherein the first metal element includes at least one selected from the group consisting of Pt, Pd, V, Er, and Yb,
wherein the MISFETs include a plurality of first MISFETs forming a memory cell array, and
wherein the first heat treatment and the second heat treatment are performed such that a grain size in each of the metal silicide layers after the second heat treatment is performed in the step (h) is smaller than a first width in a gate length direction of a first source/drain region included in the source/drain regions of the MISFETs, and disposed between the gate electrodes of the first MISFETs adjacent to each other in the gate length direction.

15. A method of manufacturing the semiconductor device according to any one of claims 12 to 14,
wherein, in the step (f), the first heat treatment is performed such that an unreacted portion of the alloy film remains over each of the metal silicide layers.

16. A method of manufacturing the semiconductor device according to claim 15,
wherein, in the step (f), the first heat treatment is performed at a heat treatment temperature at which coefficient of diffusion of the first metal element into the source/drain regions is larger than a coefficient of diffusion of nickel into the source/drain regions.

17. A method of manufacturing the semiconductor device according to claim 16,
wherein a ratio of the first metal element to the metal elements forming each of the metal silicide layers is higher than a ratio of the first metal element to the alloy film.

18. A method of manufacturing the semiconductor device according to claim 17,
wherein the first metal element is Pt.

19. A method of manufacturing the semiconductor device according to claim 18,
wherein the heat treatment temperature in the first heat treatment is less than 279° C.

20. A method of manufacturing the semiconductor device according to claim 19,
wherein the heat treatment temperature in the first heat treatment is not less than 200° C.

21. A method of manufacturing the semiconductor device according to claim 20,
wherein, in the step (e), the alloy film is formed over the source/drain regions to have a first thickness, and
wherein each of portions of the alloy film formed over the source/drain regions in the step (e) which have reacted with the source/drain regions in the step (f) has a second thickness smaller than the first thickness.

22. A method of manufacturing the semiconductor device according to claim 21,
wherein, in the step (f), the metal silicide layers each in a (Ni_{y-1}Pt_{y})₂Si phase are formed by the first heat treatment.

23. A method of manufacturing the semiconductor device according to claim 22,
wherein, in the step (h), the metal silicide layers each in a Ni_{1-y}Pt_{y}Si phase are formed by the second heat treatment.

24. A method of manufacturing the semiconductor device according to claim 23,
wherein the alloy film formed in the step (e) is a Ni₁₋ₓPtₓ alloy film, and the y in the (Ni_{1-y}Pt_{y})₂Si is larger than the x in the Ni₁₋ₓPtₓ.

25. A method of manufacturing the semiconductor device according to claim 24,
wherein the first thickness is not less than 1.25 times the second thickness.

26. A method of manufacturing the semiconductor device according to claim 25,
wherein the first metal element is Pt, and
wherein a ratio of the Pt element to the metal elements in each of the metal silicide layers is not less than 4%.

27. A method of manufacturing the semiconductor device according to claim 26,
wherein the first width is not more than 140 nm.

28. A method of manufacturing the semiconductor device according to any one of claims 12 to 14, further comprising, after the step (d), the steps of:
(d1) forming a second insulating film over the semiconductor substrate so as to cover the gate electrodes and the sidewall insulating films;
(d2) forming a resist pattern over the second insulating film;
(d3) dry-etching the second insulating film using the resist pattern as an etching mask; and
(d4) removing the resist pattern,
wherein, in the step (d2), the resist pattern is not formed over the source/drain regions, the gate electrodes, and the sidewall insulating films,
wherein, in the step (d3), over lower portions of side surfaces of the sidewall insulating films opposite to the side surfaces thereof opposing the gate electrodes, portions of the second insulating film remain,
wherein, after the step (d4), the step (e) is performed, and
wherein, in the step (e), the alloy film is formed in a state where the portions of the second insulating film remain over the lower portions of the side surfaces of the sidewall insulating films opposite to the side surfaces thereof opposing the gate electrodes.
